(19) United States
(12) Patent Application Publication
(10) Pub. No.: US 2017/0162745 A1
(43) Pub. Date: Jun. 8, 2017

(54) SEMICONDUCTOR LIGHT-EMITTING DEVICE AND METHOD FOR MANUFACTURING SAME

(71) Applicant: USHIO DENKI KABUSHIKI KAISHA, Tokyo (JP)

(72) Inventors: Kengo MORIYASU, Tokyo (JP); Masanori YAMAGUCHI, Tokyo (JP); Kensuke FUKUSHIMA, Tokyo (JP); Akihiko SUGITANI, Tokyo (JP); Masashi TSUKIHARA, Tokyo (JP); Saori KANAHASHI, Tokyo (JP)

(73) Assignee: USHIO DENKI KABUSHIKI KAISHA, Tokyo (JP)

(21) Appl. No.: 15/366,685

(22) Filed: Dec. 1, 2016

(30) Foreign Application Priority Data
Dec. 4, 2015 (JP) 2015-238060
Dec. 10, 2015 (JP) 2015-241051

(51) Int. Cl. H01L 33/00; H01L 33/38; H01L 33/32; H01L 33/14; H01L 33/54; H01L 33/40

(52) U.S. Cl. CPC H01L 33/0079; H01L 33/54; H01L 33/40; H01L 33/32; H01L 33/145; H01L 33/38; H01L 33/0075; H01L 2933/0016

(57) ABSTRACT

The purpose of the present invention is to provide a semiconductor light-emitting device having good life characteristics and higher light extraction efficiency than conventional devices. This semiconductor light-emitting device includes a substrate; semiconductor layers including a first semiconductor layer, an active layer, and a second semiconductor layer; a first electrode; and a second electrode. The opposite surface of the first semiconductor layer from the active layer comprises a smooth surface portion and a roughened surface portion, the smooth surface portion is provided in a region where the first electrode is formed, the roughened surface portion is provided at least in a part of a region where the first electrode is not formed, and the second semiconductor layer and the second electrode are in contact with each other at a position outside an outer edge of the first electrode.

### BACKGROUND OF THE INVENTION

Field of the Invention

The invention relates to semiconductor light-emitting devices and methods for manufacturing the same.

Description of the Related Art

Recent years have seen the increasing development of light-emitting devices using nitride semiconductors. Such light-emitting devices have a structure including an n-type semiconductor layer, a p-type semiconductor, and an active layer provided between the n-type and p-type semiconductor layers. When a potential difference is applied between the n-type and p-type semiconductor layers, a current is allowed to flow between them, so that electrons and holes recombine in the active layer to emit light. A variety of research and development has been carried out for effective use of the light generated in the active layer.

For example, Patent Document 1 listed below discloses a light-emitting device having what is called a “vertical structure.” A device of a vertical structure refers to a device having an active layer capable of emitting light when a voltage is applied to the active layer in a direction perpendicular to the substrate.

FIG. 11 is a cross-sectional view schematically showing the semiconductor light-emitting device disclosed in Patent Document 1. Such a conventional semiconductor light-emitting device 290 has a conductive layer 292, a reflective film 293, an insulating layer 294, a reflective electrode 295, semiconductor layers 299, and an n-side electrode 300, which are formed on a substrate 291. The semiconductor layers 299 include a p-type semiconductor layer 296, an active layer 297, and an n-type semiconductor layer 298, which are stacked in this order from the substrate 291 side.

Although made of a metal material, the reflective film 293 formed under the insulating layer 294 has no ohmic property and does not function as an electrode. On the other hand, the reflective electrode 295, which is made of a metal material and forms an ohmic contact with the p-type semiconductor layer 296, functions as an electrode (p-side electrode).

The reflective electrode 295 also aims to increase the light extraction efficiency by reflecting light emitted in the direction toward the substrate 291 (downward in the drawing), which is a part of the light generated by the active layer 297, so that the reflected light can be extracted from the n-type semiconductor layer 298 side (upward in the drawing). The reflective film 293 is also formed for the same purpose. The reflective film 293 increases the light extraction efficiency by reflecting the light traveling downward through a part not provided with the reflective electrode 295 so that the direction of travel of the light is changed to the n-type semiconductor layer 298 side.

### PRIOR ART DOCUMENT

### Patent Document

Patent Document 1: Japanese Patent No. 4207781

### SUMMARY OF THE INVENTION

### Problems to be Solved by the Invention

It is an object of the invention to provide a semiconductor light-emitting device having good life characteristics and higher light extraction efficiency than conventional devices.

### Means for Solving the Problem

A semiconductor light-emitting device according to the present invention includes

a substrate;

semiconductor layers formed on the substrate and including an n-type or p-type first semiconductor layer, an active layer, and a second semiconductor layer of a conductivity type different from that of the first semiconductor layer;

a first electrode formed in contact with an opposite surface of the first semiconductor layer from the active layer; and

a second electrode that is in contact with an opposite surface of the second semiconductor layer from the active layer and formed in a region including a position facing the first electrode in a direction perpendicular to a surface of the substrate, wherein

the opposite surface of the first semiconductor layer from the active layer comprises a smooth surface portion and a roughened surface portion,

the smooth surface portion is provided in a region where the first electrode is formed,

the roughened surface portion is provided at least in a part of a region where the first electrode is not formed, and

the second semiconductor layer and the second electrode are in contact with each other at a position outside an outer edge of the first electrode.

In the conventional semiconductor light-emitting device 290 shown in FIG. 11, the light emitted downward from the active layer 297 passes twice through the insulating layer 294, before and after reflection by the reflective film 293, until it is extracted upward after reflected by the reflective film 293. Although formed as a transparent film, the insulating layer 294 can absorb several % of the light passing through the insulating layer 294. More specifically, about 3 to 4% of the light is absorbed until it travels from the active layer 297 to the reflective film 293 through the insulating layer 294, and 3 to 4% of the light reflected by the reflective film 293 is further absorbed until it is transmitted through the insulating layer 294 and then extracted to the outside from the n-type semiconductor layer 298.

Therefore, the conventional structure is not considered to have sufficiently increased extraction efficiency because the light is partially absorbed in the insulating layer 294 although the reflection of the light emitted downward, which is a part of the light emitted from the active layer 297, increases the extraction efficiency.

To increase the light extraction efficiency, the inventors have also conducted a study of the formation of a roughened surface on the n-type semiconductor layer 298. In this study, the inventors have found that continuous operation for at least a certain period of time causes some light-emitting devices to burn out.

According to the above feature, at least a part of the opposite surface of the first semiconductor layer from the active layer has a roughened surface portion. This feature can reduce the amount of the light reflected toward the active layer side by the surface of the first semiconductor layer, among the light emitted from the active layer toward the first semiconductor layer, so that the light extraction efficiency can be improved.

To cause the active layer to emit light, a potential difference is applied between the first and second electrodes so that a current is allowed to flow between the first and second electrodes through the active layer. In this process, the electric field tends to concentrate at the outer edges of the first and second electrodes. It can be expected that if the portions where the electric field tends to concentrate are close to each other, local heating can occur between them to degrade the semiconductor layer. In addition, the temperature rise associated with the heating may cause the migration of the material from the electrode, which may form a short circuit between the first and second electrodes. If these phenomena occur, the light-emitting device can no longer emit light. In other words, the life characteristics of the light-emitting device can decrease.

The distance between the first and second electrodes (the distance in a direction perpendicular to the surface of the substrate) is relatively short, particularly when, as described above, the second electrode is formed in contact with the opposite surface of the second semiconductor layer from the active layer and formed in a region including a position facing the first electrode in the direction perpendicular to the surface of the substrate. Thus, the life characteristics of the light-emitting device with this feature may be more likely to be degraded than those of conventional light-emitting devices.

According to the feature described above, therefore, the second electrode is formed to extend to a position further outside the outer edge of the first electrode, so that a sufficient distance is kept between the outer edges of the first and second electrodes. According to this feature, a sufficient distance is kept between the regions where the electric field is more likely to concentrate, so that the progress of degradation of the semiconductor layer and the progress of the migration can be suppressed and the life characteristics can be improved. Alternatively, the outer edge of the second electrode can be positioned inside the outer edge of the first electrode so that a sufficient distance can be kept between them. In this case, however, the propagation of the current through the active layer is sacrificed in directions parallel to the surface of the substrate. The feature described above makes it possible to improve both the light extraction efficiency and the life characteristics.

According to the feature described above, the opposite surface of the first semiconductor layer from the active layer has a smooth surface portion in the region where the first electrode is formed. If the surface of the first semiconductor layer has a roughened surface portion in this region, the material used to form the first electrode may flow into a valley part of the roughened surface in the process of forming the first electrode on the upper surface of the first semiconductor layer. If so, the distance between the first and second electrodes will decrease, which may lead to the degradation of the life characteristics. When the surface of the first semiconductor layer has a smooth surface portion in the region where the first electrode is formed, the material used to form the first electrode is prevented from flowing into the roughened surface portion of the first semiconductor layer.

The current blocking layer may include, for example, an insulating material such as SiO₂, SiN, Zr₂O₃, AlN, or Al₂O₃.

One of surfaces of the second electrode may be entirely in contact with the second semiconductor layer.

According to this feature, the absorption of light by other layers can be made substantially zero between the second semiconductor layer and the second electrode during a period when the light emitted from the active layer to the second electrode is reflected by the second electrode and then travels to the first semiconductor layer, so that the light extraction efficiency can be made higher than a conventional efficiency.

The opposite surface of the first semiconductor layer from the active layer may have a smooth surface portion in a region outside an outer edge of the first electrode.

As described above, the outer edge of the second electrode is located outside the outer edge of the first electrode. In this case, if the roughened surface portion of the first semiconductor layer surface is formed in a region outside the outer edge of the first electrode to be formed, the material used to form the first electrode may flow into a valley part of the roughened surface of the first semiconductor layer in the process of forming the first electrode on the upper surface of the first semiconductor layer. If so, heat can be generated between the second electrode and the valley part, because the valley part is close to the outer edge of the second electrode, so that the life characteristics can be degraded. When, according to the above feature, the surface of the first semiconductor layer has a smooth surface portion in a region outside the outer edge of the first electrode, the material used to form the first electrode can be prevented from flowing into a position close to the outer edge of the second electrode even if it flows into the roughened surface portion of the first semiconductor layer.

In addition, the area of the region outside the outer edge of the first electrode is far smaller than that of the region inside the outer edge of the first electrode. Therefore, whether the surface of the first semiconductor layer is smooth or roughened in the region outside the outer edge of the first electrode will not cause a significant difference in the amount of extracted light. Therefore, the above feature makes it possible to provide a light-emitting device having improved life characteristics with the amount of extracted light maintained at a high level.

The second electrode may have an outer edge located outside the outer edge of the first electrode and inside an outer edge of the semiconductor layers.

When the second electrode is arranged to have an outer edge inside the outer edge of the semiconductor layers, the second electrode can be fixed in the interior of the device without being exposed to the open air. This is effective in preventing the material of the second electrode from diffusing to the first electrode side due to migration.

The second electrode having a second semiconductor layer-side surface and a surface opposite to the second semiconductor layer may be such that the area of the second semiconductor layer-side surface is larger than that of the opposite surface. More specifically, the second electrode may also be formed to have an outer edge in the shape of a knife edge.

When the second electrode is tapered (particularly, knife edge-shaped) as described above, the second electrode can have improved adhesion to the current blocking layer and be more reliably prevented from migration.

The semiconductor light-emitting device may also include a current blocking layer formed at a position facing the first electrode in a direction perpendicular to the surface of the substrate, the current blocking layer being in direct contact with an opposite surface of the second electrode from the second semiconductor layer or being attached to the opposite surface of the second electrode with another conductive layer interposed between the current blocking layer and the second electrode.

According to this feature, the current flow between the first and second electrodes is prevented from concentrating in a direction perpendicular to the surface of the substrate. This is effective in allowing the current flowing through the active layer to propagate in directions parallel to the surface of the substrate, so that the luminous efficiency can be improved. This can eliminate the need to provide an insulating layer between the second electrode and the second semiconductor layer, which means prevention of the absorption of light into such an insulating layer, so that the light extraction efficiency can be further improved.

The outer edge of the first electrode may have a frame shape when viewed in a direction perpendicular to the surface of the substrate. In this case, the second electrode and the second semiconductor layer may be in contact with each other at a position outside the frame shape when the light-emitting device is viewed in the direction perpendicular to the surface of the substrate.

The active layer may comprise a nitride semiconductor capable of emitting light with a peak wavelength of 400 nm or less.

In the light-emitting device configured to emit light with a peak wavelength of 400 nm or less, the first and second semiconductor layers should be made as thin as possible so that the absorption of light in these semiconductor layers can be kept low.

For example, the semiconductor layers should have a thickness of 5 μm or less. In this case, the distance between the first and second electrodes is relatively short in a direction perpendicular to the surface of the substrate, which can make the above problem of the degradation of the semiconductor layers more likely to occur. According to the above feature, however, a sufficient distance can be kept between the outer edges of the first and second electrodes because the second electrode and the second semiconductor layer are in contact with each other at a position outside the outer edge of the first electrode. This can reduce the degradation of the semiconductor layer and improve the life characteristics.

A method for manufacturing the semiconductor light-emitting device according to the present invention includes the steps of:

(a) preparing a growth substrate;

(b) forming semiconductor layers on the growth substrate, the semiconductor layers including an n-type or p-type first semiconductor layer, an active layer, and a second semiconductor layer of a conductivity type different from that of the first semiconductor layer;

(c) forming a second electrode on an upper surface of the second semiconductor layer;

(d) bonding a support substrate to an upper part of the second electrode with a bonding layer interposed between the support substrate and the second electrode, wherein the support substrate is independent of the growth substrate;

(e) separating the growth substrate to expose the first semiconductor layer;

(f) processing an exposed surface of the first semiconductor layer to form a roughened surface portion and a smooth surface portion;

(g) forming a first electrode on a part of the smooth surface portion of the surface of the first semiconductor layer, wherein in the step (g), the first electrode is formed in such a manner that a material used to form the first electrode is prevented from flowing into the roughened surface portion.

The step (g) specifically can be carried out as below.

The step (g) may comprise the steps:

(g1) preparing a resist mask having an opening region with an opening area smaller than the area of the smooth surface portion;

(g2) forming the resist mask on an upper surface of the first semiconductor layer while a partial region of the smooth surface portion is exposed through the opening region;

(g3) depositing a conductive material on an upper surface of the resist mask and on an upper surface of the first semiconductor layer exposed through the opening region, wherein the conductive material is for forming the first electrode; and

(g4) removing the resist mask to form the first electrode on a part of the smooth surface portion.

In the step (c), the second electrode may be formed in such a manner that the second electrode and an upper surface of the second semiconductor layer are in contact with each other at a position inside an outer edge of the second semiconductor layer.

In the step (f), the surface may be processed in such a manner that the exposed surface of the first semiconductor layer has the smooth surface portion at least in a region adjacent to an outer edge of the first semiconductor layer.

In the step (g), the first electrode may be formed at a position inside a position where the second semiconductor layer is in contact with the second electrode.

In the step (c), the second electrode may be formed to have a tapered shape that increases in cross-sectional area as it extends away from the surface in contact with the second semiconductor layer. More specifically, in the step (c), the second electrode may be formed to have an outer edge in the shape of a knife edge.

In the step (g), the first electrode may be formed to have an outer edge in a frame shape when viewed in a direction perpendicular to a surface of the support substrate.

The active layer formed in the step (b) may comprise a nitride semiconductor capable of emitting light with a peak wavelength of 400 nm or less.

In the step (b), the semiconductor layers may be formed to have a thickness of 5 μm or less.

A semiconductor light-emitting device according to the present invention includes

a substrate;

semiconductor layers formed on the substrate and including an n-type or p-type first semiconductor layer, an active layer, and a second semiconductor layer of a conductivity type different from that of the first semiconductor layer;

a first electrode formed in contact with an opposite surface of the first semiconductor layer from the active layer; and

a protective layer comprising a material with a thermal expansion coefficient lower than that of the first electrode and formed in contact with an outside surface of the first electrode, wherein

the protective layer is formed on an outside surface of the first electrode, the outside surface including an end where the first electrode is in contact with the first semiconductor layer, and

at least a part of an upper surface of the first electrode is not covered with the protective layer.

When the semiconductor light-emitting device 290 shown in FIG. 11 is emitting light, the electric field tends to concentrate at the end of the n-side electrode 300. Thus, a portion at or near the end of the n-side electrode 300 tends to increase in temperature. If water in the air infiltrates into the portion with the increased temperature, migration of the material from the p-side electrode 295 will become more likely to occur. As a result, continuous light emission can cause the material of the p-side electrode 295 to reach a portion at or near the end of the n-side electrode 300 through threading dislocation in the semiconductor layers 299, so that leakage current can occur to cause lighting failure.

From these points of view, the inventors have designed the light-emitting device 310 shown in FIG. 12, in which a protective layer 301 is provided to cover an area from the upper surface of the n-type semiconductor layer 298 in the vicinity of the n-side electrode 300 to the side and upper surfaces of the n-side electrode 300. In this structure, the protective layer 301 covers a portion at and near the end of the n-side electrode 300, in which the temperature can increase significantly, so that water in the air can be prevented from infiltrating into this portion.

As a result of intensive studies, however, the inventors have found that even the light-emitting device 310 shown in FIG. 12 can be burned out after a certain period of operation. As a result of the analysis of such a burned-out device, the inventors have revealed that the protective layer 301 is cracked.

In the device with the feature described above, the protective layer is formed on the outside surface including the end in contact with the first semiconductor layer. In this structure, water vapor and oxygen in the air are prevented from coming into contact with the upper surface of the first semiconductor layer located at or near the end of the first electrode, at which the electric field can concentrate. In other words, water vapor and oxygen cannot infiltrate into the semiconductor layer formed in the region where the temperature is more likely to increase, so that the material of the second electrode is prevented from diffusing to the first electrode through migration.

As mentioned above, it has been observed that in the light-emitting device 310 shown in FIG. 12, cracking occurs in the protective layer 301 to cause the device to burn out. The inventors have speculated that the reason for this is as follows.

When the device is energized to emit light, the temperature increases particularly at or near the end of the n-side electrode, and when the energization is stopped, the temperature decreases. In the device, the protective layer 301 has a thermal expansion coefficient smaller than that of the n-side electrode 300, which is made of a metal material. Therefore, as the temperature increases during the energization, the n-side electrode 300 tends to expand, but the protective layer 301 covering the circumference of the n-side electrode 300 does not tend to expand as much as the n-side electrode 300, so that the protective layer 301 blocks the expansion of the n-side electrode 300, which causes stress between them. Subsequently, when the energization is stopped, the n-side electrode 300 contracts. Repetition of such an increase/decrease in temperature would cause the n-side electrode 300 to apply a large stress to the protective layer 301, so that the protective layer 301 can crack eventually. If such cracking occurs, water vapor and oxygen in the air can infiltrate from a portion at or near the end of the n-side electrode 300 into the semiconductor layers 299 through the cracks to cause oxidation of the semiconductor layers 299 and migration.

In order to prevent this, at least a part of the upper surface of the first electrode is not covered with the protective layer in the device with the feature described above. Therefore, even when the first electrode expands as the temperature increases during the energization, the stress between the first electrode and the protective layer can be released through the region not covered with the protective layer. As a result, even when the light-emitting device is repeatedly turned on and off, cracking is less likely to occur in the protective layer, in contract to the light-emitting device 310 shown in FIG. 12.

The protective layer may also be formed to extend from a first position on the upper surface of the first semiconductor layer to a second position on the outside surface of the first electrode, in which the first position is outside the first electrode.

In this structure, the protective layer may also be formed to reach a part of the upper surface of the first electrode through the outside surface of the first electrode. More specifically, the protective layer may also be formed to extend from a first position on the upper surface of the first semiconductor layer to a second position on a part of the upper surface of the first electrode through the outside surface of the first electrode, in which the first position is outside the first electrode.

The first electrode may be formed to extend in a predetermined direction on a surface of the first semiconductor layer, and

the protective layer is formed along the predetermined direction and in contact with the outside surface of the first electrode.

In this structure, the protective layer may cover a part of the upper surface of the first electrode, and

the first electrode has an exposed surface not covered with the protective layer, the exposed surface having a slit shape along the predetermined direction.

In particular, these features are effective not only in preventing the protective layer from cracking but also in reducing the probability of holding foreign particles on the upper surface of the protective layer and allowing them to adhere to the upper surface of the first electrode even if they are deposited on the device.

The slit-shaped, exposed surface of the first electrode may have a width that is 10% or more of the width of the first electrode extending along the predetermined direction.

The first electrode may be made of a material including Au. The first electrode is preferably made of a highly-conductive, stable material, such as a material including Au. Au tends to cause the problem described above because it is soft and has a high thermal expansion coefficient. According to the above feature, however, the stress between the first electrode and the protective layer can be relaxed, which is effective in making cracks less likely to occur in the protective layer.

In this structure, the semiconductor light-emitting device may also include

a second electrode formed in contact with an opposite surface of the second semiconductor layer from the active layer; and

a current blocking layer formed at a position facing the first electrode in a direction perpendicular to a surface of the substrate, the current blocking layer being in direct contact with an opposite surface of the second electrode from the second semiconductor layer or being attached to the opposite surface of the second electrode with another conductive layer interposed between the current blocking layer and the second electrode, wherein

one of surfaces of the second electrode is entirely in contact with the second semiconductor layer.

In the light-emitting devices shown in FIGS. 11 and 12, the light emitted downward from the active layer 297 passes twice through the insulating layer 294, before and after reflection by the reflective film 293, until it is extracted upward after reflected by the reflective film 293. Although formed as a transparent film, the insulating layer 294 can absorb several % of the light passing through the insulating layer 294. More specifically, about 3 to 4% of the light is absorbed until it travels from the active layer 297 to the reflective film 293 through the insulating layer 294, and 3 to 4% of the light reflected by the reflective film 293 is further absorbed until it is transmitted through the insulating layer 294 and then extracted to the outside from the n-type semiconductor layer 298.

Therefore, the light-emitting devices shown in FIGS. 11 and 12 are not considered to have sufficiently increased extraction efficiency because the light is partially absorbed in the insulating layer 294 although the reflection of the light emitted downward, which is a part of the light emitted from the active layer 297, increases the extraction efficiency.

On the other hand, in the structure described above, the current blocking layer is formed in such a manner that the current blocking layer and the opposite surface of the second electrode from the second semiconductor layer are in contact with each other at a position facing the first electrode in a direction perpendicular to the surface of the substrate. This prevents the current flow between the first and second electrodes from concentrating in a direction perpendicular to the surface of the substrate. This is effective in allowing the current flowing through the active layer to propagate in directions parallel to the surface of the substrate, so that the luminous efficiency can be improved. This makes it possible to employ a structure in which one of the surfaces of the second electrode is entirely in contact with the second semiconductor layer as in the device described above. This can also eliminate the need to provide an insulating layer between the second electrode and the second semiconductor layer, which means prevention of the absorption of light into such an insulating layer, so that the light extraction efficiency can be improved.

In such a structure, however, the distance between the first and second electrodes (the distance in the direction perpendicular to the surface of the substrate) is shorter than that in the case where the insulating layer is provided between the second electrode and the second semiconductor layer. This may cause concern that if an environment where migration can easily occur is established, the material in the second electrode may easily diffuse to the first electrode side, so that leakage current may easily occur.

However, the device described above is so designed that a portion at and near the end of the first electrode, where the temperature can easily increase, is covered with the protective layer, while at least a part of the upper surface of the first electrode is not covered with the protective layer. This design makes it possible to hinder the infiltration of water vapor from the air into a high-temperature region of the semiconductor layers. Therefore, the device can have both improved light extraction efficiency and improved life characteristics.

In this structure, the active layer may comprise a nitride semiconductor capable of emitting light with a peak wavelength of 400 nm or less.

In the light-emitting device configured to emit light with a peak wavelength of 400 nm or less, the first and second semiconductor layers should be made as thin as possible so that the absorption of light in these semiconductor layers can be kept low. For example, the semiconductor layers should have a thickness of 5 μm or less. In this case, the distance between the first and second electrodes in the direction perpendicular to the surface of the substrate is relatively short, so that the material in the second electrode is more likely to diffuse to the first electrode side as mentioned above. However, the device described above is so designed that a portion at and near the end of the first electrode, where the temperature can easily increase, is covered with the protective layer, while at least a part of the upper surface of the first electrode is not covered with the protective layer. This design makes it possible to hinder the infiltration of water vapor from the air into a high-temperature region of the semiconductor layers. Therefore, the device can have both improved light extraction efficiency and improved life characteristics.

The semiconductor light-emitting device may also include an adhesion promoter layer formed at an interface between the first electrode and the protective layer and comprising a material including Ti.

As mentioned above, as the device is repeatedly turned on and off, the first electrode is repeatedly expanded and contracted. During this process, the protective layer may partially peel off from the surface of the first electrode due to the difference in thermal expansion coefficient between the first electrode and the protective layer. When the first electrode and the protective layer are attached to each other with the adhesion promoter layer interposed therebetween as mentioned above, the protective layer can stably bond to the surface of the first electrode even after the repetition of turning on and off, so that the effect of preventing migration can be maintained.

The protective layer may comprise a material transparent to light emitted from the active layer. The protective layer may include, for example, SiO₂, Al₂O₃, Y₂O₃, ZnO, or ZrO₂.

A method for manufacturing the semiconductor light-emitting device according to the present invention includes the steps of:

(h) preparing a growth substrate;

(i) forming semiconductor layers on the growth substrate, the semiconductor layers including an n-type or p-type first semiconductor layer, an active layer, and a second semiconductor layer of a conductivity type different from that of the first semiconductor layer;

(j) forming a second electrode on an upper surface of the second semiconductor layer;

(k) bonding a support substrate to an upper part of the second electrode with a bonding layer interposed between the support substrate and the second electrode, wherein the support substrate is independent of the growth substrate;

(l) separating the growth substrate to expose the first semiconductor layer;

(m) forming a first electrode on a predetermined region of a surface of the first semiconductor layer; and

(n) forming a protective layer on an outside surface of the first electrode, wherein the outside surface includes an end in contact with the first semiconductor layer, and the protective layer comprises a material with a thermal expansion coefficient lower than that of the first electrode.

In the step (m), the first electrode may be formed to extend in a predetermined direction on the surface of the first semiconductor layer,

in the step (n), the protective layer may be formed to reach a part of an upper surface of the first electrode through the outside surface of the first electrode, and

after the step (n), the first electrode may have an exposed surface in a slit shape extending in the predetermined direction.

### Advantageous Effects of the Invention

The invention makes it possible to provide a semiconductor light-emitting device having good life characteristics and higher light extraction efficiency than conventional devices.

### BRIEF DESCRIPTION OF THE DRAWINGS

FIG. 1A is a plan view schematically showing the structure of a semiconductor light-emitting device according to a first embodiment;

FIG. 1B is a cross-sectional view schematically showing the structure of the semiconductor light-emitting device according to the first embodiment;

FIG. 1C is a view obtained by enlarging a part of FIG. 1B;

FIG. 1D is another view obtained by enlarging a part of the FIG. 1B;

FIG. 1E is another cross-sectional view schematically showing the structure of the semiconductor light-emitting device according to the first embodiment;

FIG. 2A is a cross-sectional view schematically showing a step in a method for manufacturing a semiconductor light-emitting device;

FIG. 2B is a cross-sectional view schematically showing a step in a method for manufacturing a semiconductor light-emitting device;

FIG. 2C is a cross-sectional view schematically showing a step in a method for manufacturing a semiconductor light-emitting device;

FIG. 2D is a cross-sectional view schematically showing a step in a method for manufacturing a semiconductor light-emitting device;

FIG. 2E is a cross-sectional view schematically showing a step in a method for manufacturing a semiconductor light-emitting device;

FIG. 2F is a cross-sectional view schematically showing a step in a method for manufacturing a semiconductor light-emitting device;

FIG. 2G is a cross-sectional view schematically showing a step in a method for manufacturing a semiconductor light-emitting device;

FIG. 2H is a cross-sectional view schematically showing a step in a method for manufacturing a semiconductor light-emitting device;

FIG. 2I is a cross-sectional view schematically showing a step in a method for manufacturing a semiconductor light-emitting device;

FIG. 2J is a cross-sectional view schematically showing a step in a method for manufacturing a semiconductor light-emitting device;

FIG. 2K is a cross-sectional view schematically showing a step in a method for manufacturing a semiconductor light-emitting device;

FIG. 2L is a cross-sectional view schematically showing a step in a method for manufacturing a semiconductor light-emitting device;

FIG. 2M is a cross-sectional view schematically showing a step in a method for manufacturing a semiconductor light-emitting device;

FIG. 2N is a cross-sectional view schematically showing a step in a method for manufacturing a semiconductor light-emitting device;

FIG. 2O is a cross-sectional view schematically showing a step in a method for manufacturing a semiconductor light-emitting device;

FIG. 2P is a cross-sectional view schematically showing a step in a method for manufacturing a semiconductor light-emitting device;

FIG. 2Q is a cross-sectional view schematically showing a step in a method for manufacturing a semiconductor light-emitting device;

FIG. 2R is a cross-sectional view schematically showing a step in a method for manufacturing a semiconductor light-emitting device;

FIG. 3A is a cross-sectional view schematically showing the structure of the semiconductor light-emitting device of Reference Example 1-1;

FIG. 3B is a cross-sectional view schematically showing the structure of the semiconductor light-emitting device of Reference Example 1-2;

FIG. 4 is a table showing the results of a comparison between the failure rates after the light-emitting devices of Example 1-1, Reference Example 1-1, and Reference Example 1-2 are each subjected to a continuous lighting test;

FIG. 5A is a plan view schematically showing the structure of a semiconductor light-emitting device according to a second embodiment;

FIG. 5B is a cross-sectional view schematically showing the structure of the semiconductor light-emitting device according to the second embodiment;

FIG. 6A is a cross-sectional view schematically showing a step in a method for manufacturing a semiconductor light-emitting device;

FIG. 6B is a cross-sectional view schematically showing a step in a method for manufacturing a semiconductor light-emitting device;

FIG. 6C is a cross-sectional view schematically showing a step in a method for manufacturing a semiconductor light-emitting device;

FIG. 6D is a cross-sectional view schematically showing a step in a method for manufacturing a semiconductor light-emitting device;

FIG. 6E is a cross-sectional view schematically showing a step in a method for manufacturing a semiconductor light-emitting device;

FIG. 6F is a cross-sectional view schematically showing a step in a method for manufacturing a semiconductor light-emitting device;

FIG. 6G is a cross-sectional view schematically showing a step in a method for manufacturing a semiconductor light-emitting device;

FIG. 6H is a cross-sectional view schematically showing a step in a method for manufacturing a semiconductor light-emitting device;

FIG. 6I is a cross-sectional view schematically showing a step in a method for manufacturing a semiconductor light-emitting device;

FIG. 6J is a cross-sectional view schematically showing a step in a method for manufacturing a semiconductor light-emitting device;

FIG. 6K is a cross-sectional view schematically showing a step in a method for manufacturing a semiconductor light-emitting device;

FIG. 6L is a cross-sectional view schematically showing a step in a method for manufacturing a semiconductor light-emitting device;

FIG. 6M is a cross-sectional view schematically showing a step in a method for manufacturing a semiconductor light-emitting device;

FIG. 6N is a cross-sectional view schematically showing a step in a method for manufacturing a semiconductor light-emitting device;

FIG. 6O is a cross-sectional view schematically showing a step in a method for manufacturing a semiconductor light-emitting device;

FIG. 6P is a cross-sectional view schematically showing a step in a method for manufacturing a semiconductor light-emitting device;

FIG. 6Q is a cross-sectional view schematically showing a step in a method for manufacturing a semiconductor light-emitting device;

FIG. 6R is a cross-sectional view schematically showing a step in a method for manufacturing a semiconductor light-emitting device;

FIG. 6S is a cross-sectional view schematically showing a step in a method for manufacturing a semiconductor light-emitting device;

FIG. 7A is a cross-sectional view schematically showing the structure of the semiconductor light-emitting device of Reference Example 2-1;

FIG. 7B is a cross-sectional view schematically showing the structure of the semiconductor light-emitting device of Reference Example 2-2;

FIG. 8 is a table showing the results of a comparison between the failure rates after the light-emitting devices of Examples 2-1 to 2-5, and Reference Examples 2-1 to 2-2 are each subjected to a continuous lighting test;

FIG. 9 is a cross-sectional view schematically showing another mode of a semiconductor light-emitting device according to a second embodiment;

FIG. 10A is a cross-sectional view schematically showing another mode of a semiconductor light-emitting device according to a second embodiment;

FIG. 10B is a plan view schematically showing another mode of a semiconductor light-emitting device according to a second embodiment;

FIG. 11 is a cross-sectional view schematically showing a conventional semiconductor light-emitting device;

FIG. 12 is a view schematically showing the structure of a semiconductor light-emitting device obtained by providing the semiconductor light-emitting device of FIG. 11 with a protective layer.

### DETAILED DESCRIPTION OF THE PREFERRED EMBODIMENTS

The semiconductor light-emitting device of the invention and the method of the invention for manufacturing the semiconductor light-emitting device will be described with reference to the drawings. Note that the dimensional ratio in each drawing does not necessarily coincide with the actual dimensional ratio. Hereinafter, the term “AlGaN” will be interchangeable with the term AlₘGa₁₋ₘN (0<m<1). Thus, the term “AlGaN” shall be interpreted in such a way that the composition ratios of Al and Ga are simply omitted from the notation and there is no intension to limit the composition ratio between Al and Ga to 1:1. The same applies to other terms such as “InGaN.”

### First Embodiment

A first embodiment of the invention will be described with reference to the drawings.

[Structure]

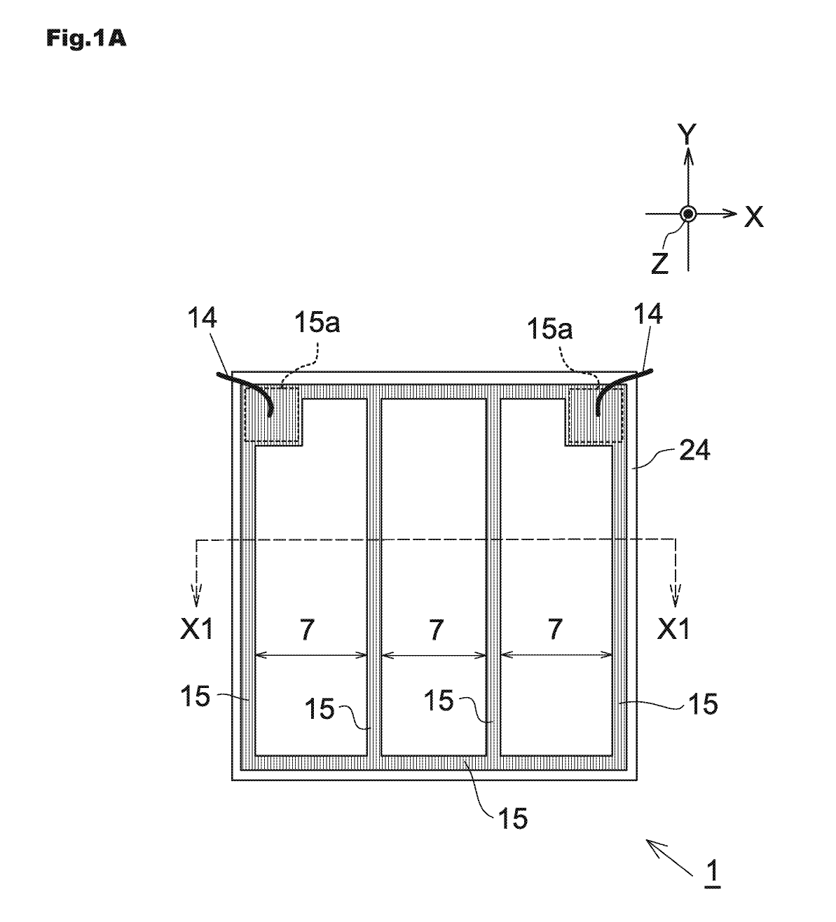

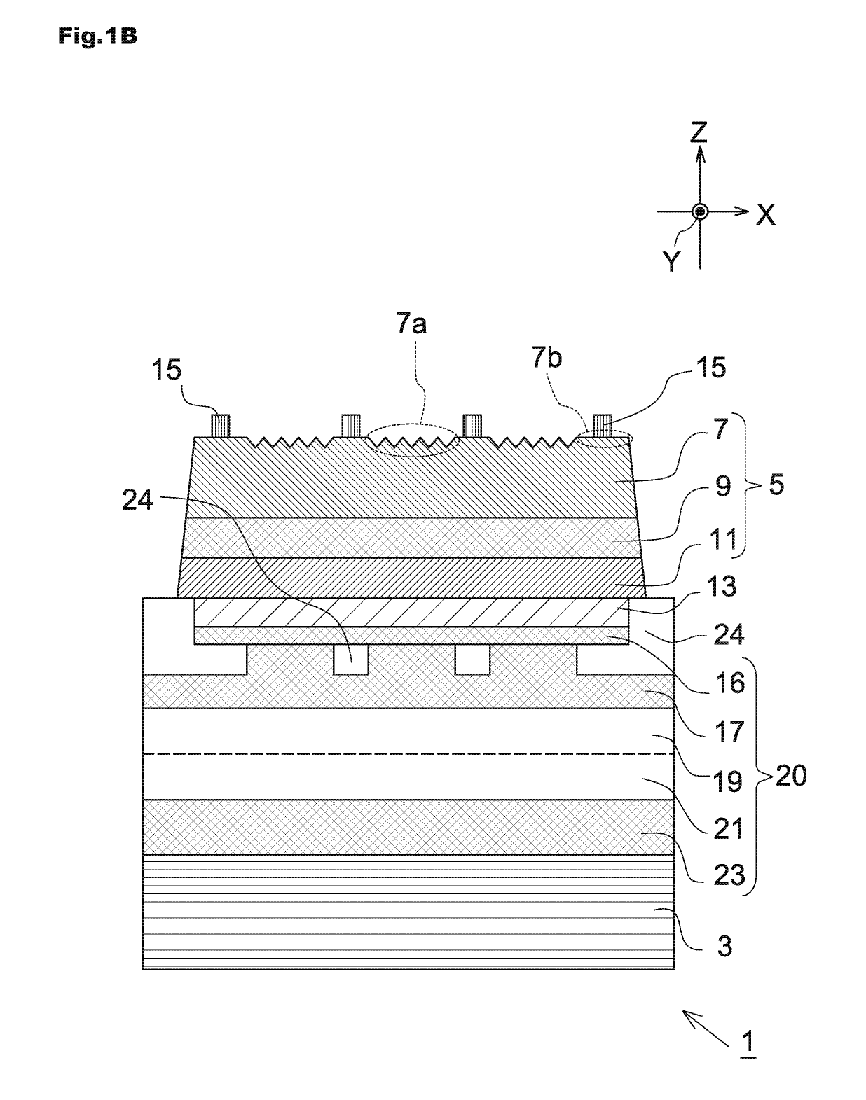

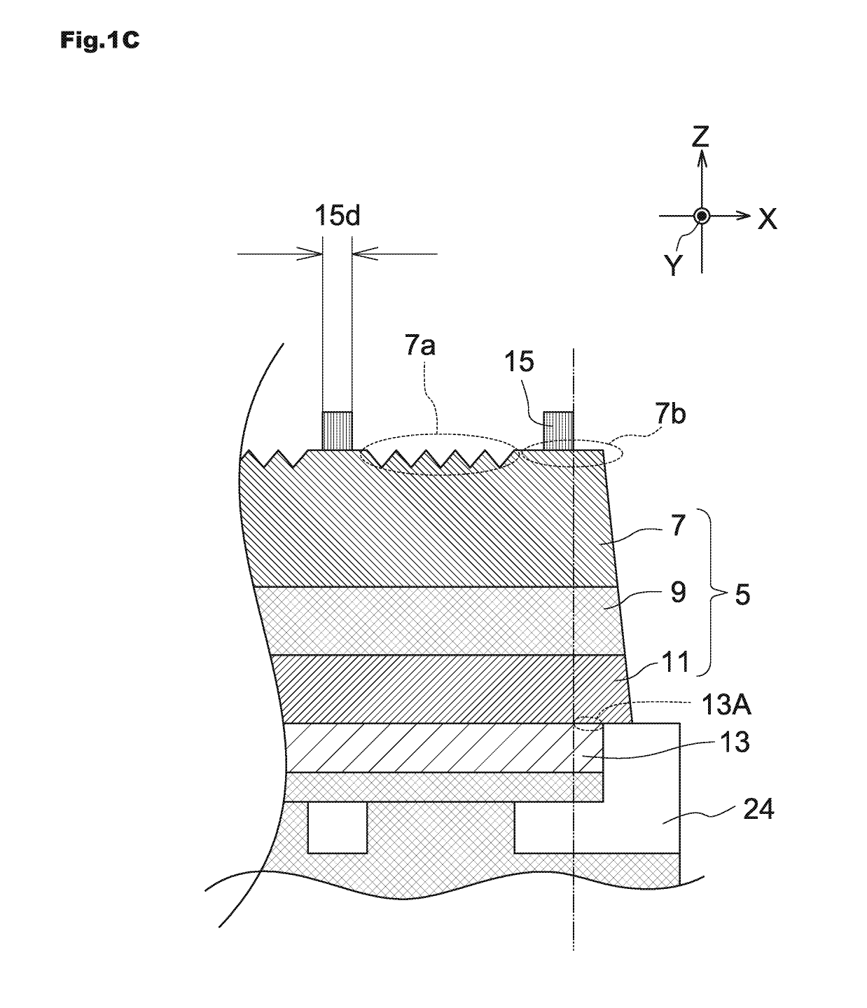

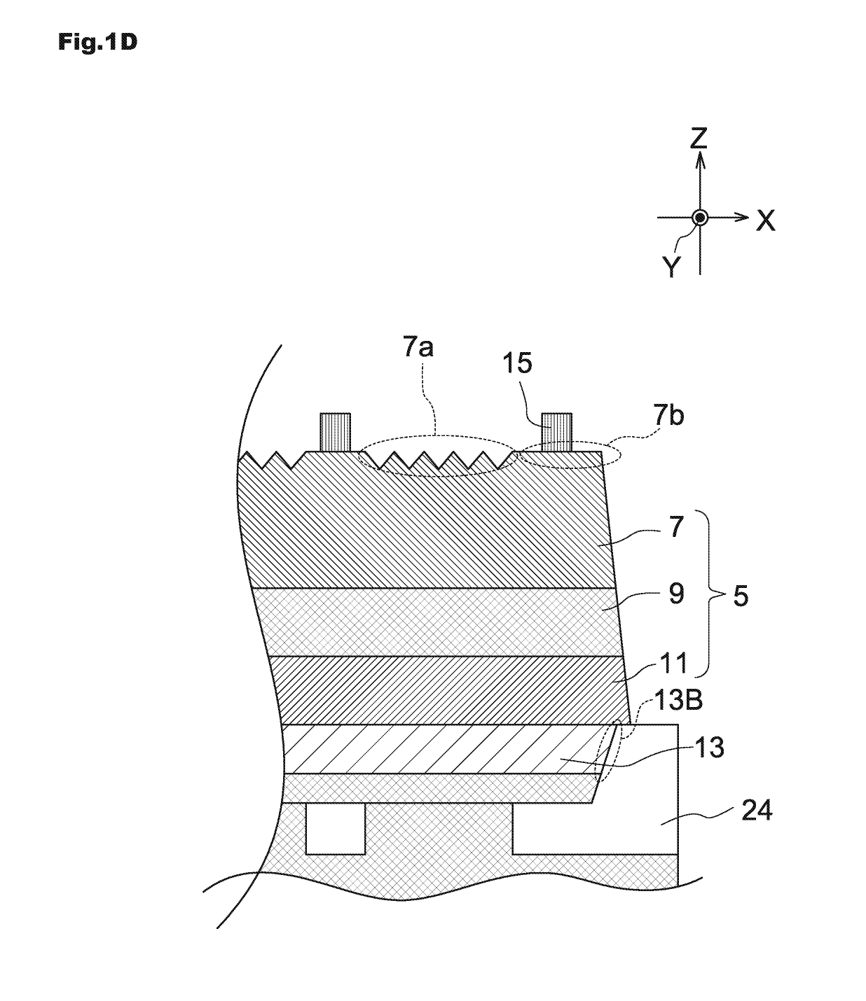

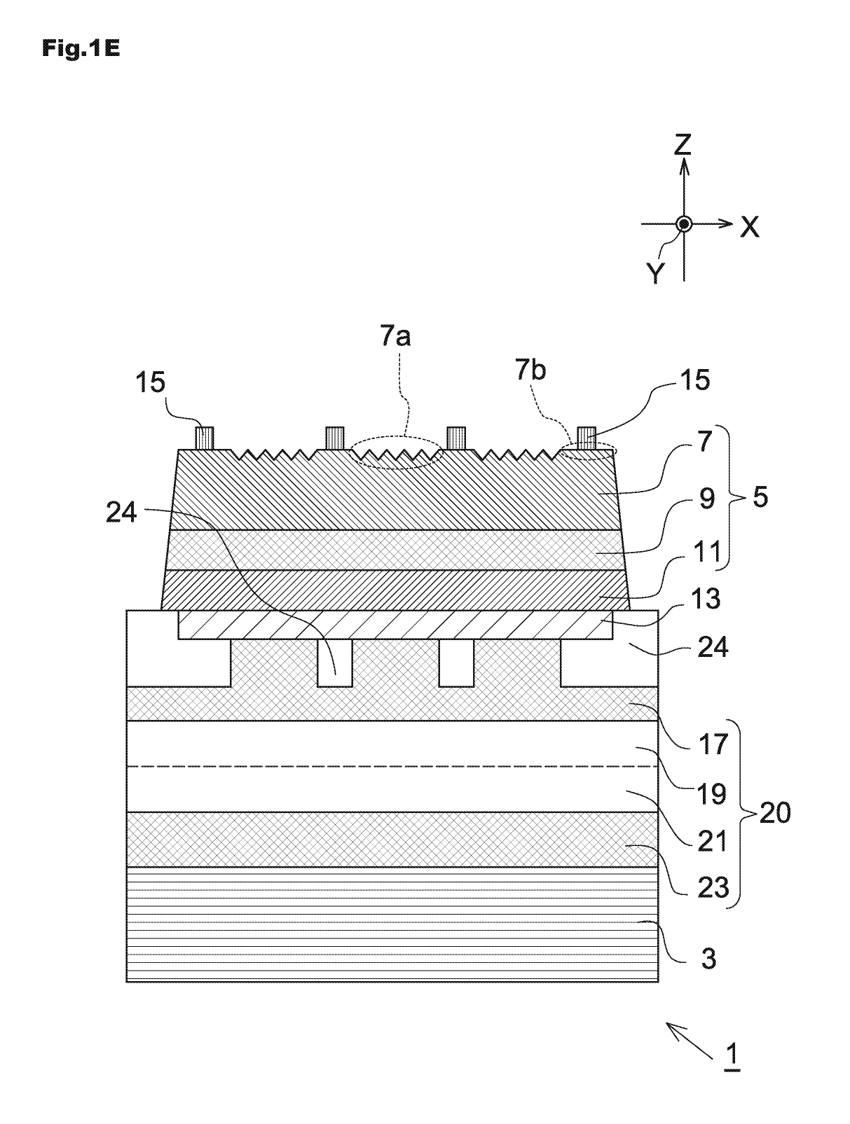

FIGS. 1A and 1B are views schematically showing the structure of a semiconductor light-emitting device according to a first embodiment of the invention. FIG. 1A corresponds to a plan view from the direction of light extraction. FIG. 1B is a cross-sectional view cut along the X1-X1 line in FIG. 1A. Hereinafter, the light extraction surface will be referred to as the X-Y plane, and the direction perpendicular to the X-Y plane will be referred to as the Z direction.

As shown in FIG. 1B, the semiconductor light-emitting device 1 includes a substrate 3, semiconductor layers 5 formed on the substrate 3, a first electrode 15, a second electrode 13, and a current blocking layer 24. Hereinafter, the semiconductor light-emitting device 1 will also be abbreviated simply as the “light-emitting device 1” as needed.

(Substrate 3)

The substrate 3 includes, for example, a conductive substrate such as CuW, W, or Mo or a semiconductor substrate such as Si.

(Semiconductor Layers 5)

In this embodiment, the semiconductor layers 5 include a p-type semiconductor layer 11, an active layer 9, and an n-type semiconductor layer 7, which are formed and stacked in this order from the side close to the substrate 3. In this embodiment, the n-type semiconductor layer 7 corresponds to a “first semiconductor layer,” and the p-type semiconductor layer 11 to a “second semiconductor layer.”

The p-type semiconductor layer 11 includes, for example, a nitride semiconductor layer doped with a p-type impurity such as Mg, Be, Zn, or C. The nitride semiconductor layer may include, for example, GaN, AlGaN, or AlInGaN.

The active layer 9 include semiconductor layers including, for example, a light-emitting layer including InGaN and a barrier layer including n-type AlGaN, which are periodically repeated. These layers may be undoped or p-type or n-type doped. The active layer 9 only has to include a stack of layers including at least two materials with different energy band gaps. The materials used to form the active layer 9 are appropriately selected depending on the wavelength of light to be generated. In the light-emitting device 1 of this embodiment, the active layer 9 generates light with a wavelength of 400 nm or less. For example, when the emission wavelength is 365 nm, the active layer 9 includes a stack of repeated In_{0.05}Ga_{0.95}N and Al_{0.09}Ga_{0.91}N.

The n-type semiconductor layer 7 includes, for example, a nitride semiconductor layer doped with an n-type impurity such as Si, Ge, S, Se, Sn, or Te. The nitride semiconductor layer may include, for example, GaN, AlGaN, or AlInGaN. The n-type semiconductor layer 7 may include a material of a composition different from that of the p-type semiconductor layer 11.

Particularly when the light-emitting device 1 is configured to emit light with a wavelength of 400 nm or less, the n-type semiconductor layer 7, which forms the light extraction surface, should preferably be made as thin as possible so that the absorption of light in the semiconductor layers 5, particularly in the n-type semiconductor layer 7 can be kept low. As an example, the thickness of the n-type semiconductor layer 7 is preferably 4.5 μm or less, more preferably 4 μm or less, even more preferably 3.5 μm or less. In this regard, the total thickness of the semiconductor layers 5 is preferably 5 μm or less, more preferably 4.5 μm or less, even more preferably 4 μm or less. In the semiconductor layers 5, the thickness of the n-type semiconductor layer 7 should be sufficiently larger than that of the p-type semiconductor layer 11 and the active layer 9.

(First Electrode 15)

The first electrode 15 is formed on the opposite surface of the n-type semiconductor layer 7 from the active layer 9. In this embodiment, the first electrode 15 forms an n-side electrode. The first electrode 15 may have, for example, a multilayer structure such as Ni/Al/Ni/Ti/Au, Cr/Au, Ti/Pt/Au, or Ti/Pt/Cr/Au/Cr/Pt/Au.

As shown in FIG. 1A, the first electrode 15 has a frame shape when viewed in the Z direction. More specifically, the first electrode 15 has an outer edge in the shape of a frame along the outer edge of the semiconductor layers 5 (n-type semiconductor layer 7). In addition, the light-emitting device 1 shown in FIG. 1A has two first electrodes 15 that extend in the Y direction and are provided at two positions located inside the outer edge of the first electrode 15 in the shape of a frame and apart in the X direction from the outer edge. However, the number of the first electrodes 15 extending inside the frame-shaped region is not limited to 2 and may be 1 or 3 or more. It will be understood that the shape of the first electrode 15 shown in FIG. 1A is only an example and may be freely changed depending on the design.

The first electrode 15 includes, as its parts, current supply portions 15a to which current supply wires 14 are connected. The current supply portions 15a are regions wider than the other regions of the first electrode 15. The current supply wires 14 include, for example, Au or Cu. The current supply wire 14 has one end connected to the current supply portion 15a and the opposite end connected to, for example, a patterned electric supply portion of a package substrate.

(Second Electrode 13)

As shown in FIG. 1B, the second electrode 13 is formed in contact with the p-type semiconductor layer 11, and forms an ohmic contact with the p-type semiconductor layer 11. In this embodiment, the second electrode 13 forms a p-side electrode.

When a voltage is applied between the first and second electrodes 15 and 13, a current flows in the active layer 9 to allow the active layer 9 to emit light.

The second electrode 13 preferably includes a conductive material with a high reflectance (e.g., 80% or more, more preferably 90% or more) to the light emitted from the active layer 9. More specifically, the second electrode 13 is made of a material including, for example, Ag, Al, or Rh. As mentioned above, the light-emitting device 1 is so designed that the light emitted from the active layer 9 is extracted to the n-type semiconductor layer 7 side. When the second electrode 13 includes a material with a high reflectance, the light emitted from the active layer 9 to the substrate 3 side is reflected to the n-type semiconductor layer 7 side so that the light extraction efficiency is increased.

The second electrode 13 is formed in a region including a position facing the first electrode 15 in a direction perpendicular to the surface of the substrate 3. This feature will be described in detail later with reference to FIG. 1C.

(Conductive Layer 20)

A conductive layer 20 is formed on the substrate 3. In this embodiment, the conductive layer 20 has a multilayer structure including a protective layer 23, a bonding layer 21, a bonding layer 19, a protective layer 17, and a protective layer 16.

The bonding layer 19 and the bonding layer 21 each include, for example, Au—Sn, Au—In, Au—Cu—Sn, Cu—Sn, Pd—Sn, or Sn. As described below, the bonding layers 19 and 21 are formed by a process including forming the bonding layer 21 on the substrate 3, forming the bonding layer 19 on another substrate (the growth substrate 25 described later), opposing the bonding layers 19 and 21 to each other, and then bonding them to each other. The bonding layers 19 and 21 may also be integrated into a single layer.

The protective layers 16 and 17 each include, for example, a multilayer structure such as Ni/Ti/Pt or TiW/Pt, and are provided to prevent the material in the bonding layer (19, 21) from diffusing to the second electrode 13 side, which would otherwise reduce the reflectance of the second electrode 13. However, it is optional whether or not the light-emitting device 1 has the protective layer 16 or 17.

The protective layer 23 includes, for example, the same material as the protective layer 17, and is provided to prevent the material in the bonding layer (19, 21) from diffusing to the substrate 3 side. However, it is optional whether or not the light-emitting device 1 has the protective layer 23.

(Current Blocking Layer 24)

The current blocking layer 24 includes, for example, SiO₂, SiN, Zr₂O₃, AlN, or Al₂O₃. The current blocking layer 24 is formed at a position facing the first electrode 15 in the Z direction. The current blocking layer 24 plays a role in allowing the current through the active layer 9 to propagate in directions parallel to the X-Y plane. In addition, the current blocking layer 24 is also formed at a position outside the semiconductor layers 5 to function also as an etching stopper layer during device separation (step S11) as described below in the section of manufacturing method.

FIG. 1C is a view obtained by enlarging a part of the schematic cross-sectional view of the light-emitting device 1 shown in FIG. 1B. As shown in FIGS. 1B and 1C, the opposite surface of the n-type semiconductor layer 7 from the active layer 9, in other words, the surface that forms the light extraction surface has a roughened surface portion 7a and a smooth surface portion 7b. Particularly in the light-emitting device 1 shown in FIGS. 1B and 1C, the surface of the n-type semiconductor layer 7 has the roughened surface portion 7a in at least a part of the region where the first electrode 15 is not formed, while the surface of the n-type semiconductor layer 7 has the smooth surface portion 7b in the region where the first electrode 15 is formed.

In addition, as shown in FIG. 1C, the width (inner diameter) of the smooth surface portion 7b of the n-type semiconductor layer 7 is larger than the width (inner diameter) 15d of the first electrode 15. In other words, the first electrode 15 is formed in such a manner that the entire bottom surface of the first electrode is in contact with the smooth surface portion 7b of the n-type semiconductor layer 7.

In addition, as shown in FIG. 1C, the second electrode 13 is formed to be disposed at a position facing the first electrode 15 in a direction perpendicular to the surface of the substrate 3, and also formed to extend to a position outside the outer edge of the first electrode 15. Thus, the second electrode 13 has a portion (region 13A) extending to the position outside the outer edge of the first electrode 15 and being in contact with the p-type semiconductor layer 11. Namely, in FIG. 1A, the second electrode 13 and the p-type semiconductor layer 11 are in contact with each other at a position outside the outer edge of the first electrode 15 in the shape of a frame. In this regard, as shown in FIG. 1B, one of the surfaces of the second electrode 13 is entirely in contact with the p-type semiconductor layer 11 in the light-emitting device 1 of this embodiment.

As shown in FIG. 1D, the second electrode 13 may be formed to have a tapered shape 13B. In particular, the second electrode 13 preferably has a knife-edge shape that is sharp at the outer edge and decreases in cross-sectional area as it extends away from the p-type semiconductor layer 11. Similarly to FIG. 1C, FIG. 1D is a view obtained by enlarging a part of the schematic cross-sectional view of the light-emitting device 1 shown in FIG. 1B. In the structure shown in FIG. 1D, the second electrode 13 has such a tapered shape that the area of its p-type semiconductor layer 11-side surface is larger than the area of its surface opposite to the p-type semiconductor layer 11.

As mentioned above, it is optional whether or not the light-emitting device 1 has the protective layer 16. FIG. 1E is a cross-sectional view schematically showing the light-emitting device 1 without the protective layer 16. In this case, the opposite surface of the second electrode 13 from the p-type semiconductor layer 11 is in direct contact with the current blocking layer 24. Alternatively, in the light-emitting device 1 shown in FIG. 1B, the opposite surface of the second electrode 13 from the p-type semiconductor layer 11 is attached to the current blocking layer 24 with the protective layer 17 interposed therebetween.

Hereinafter, a method for manufacturing the light-emitting device 1 will be described, and then the effects of the light-emitting device 1 will be described.

[Manufacturing Method]

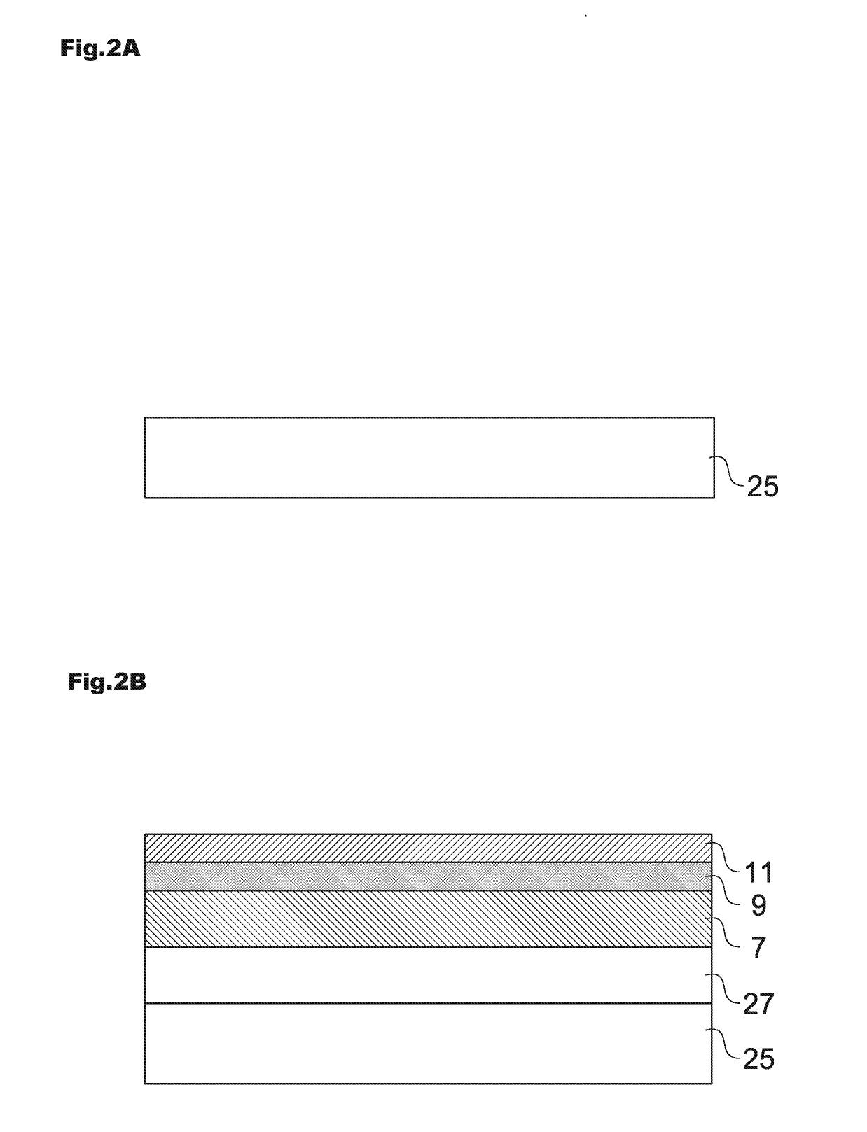

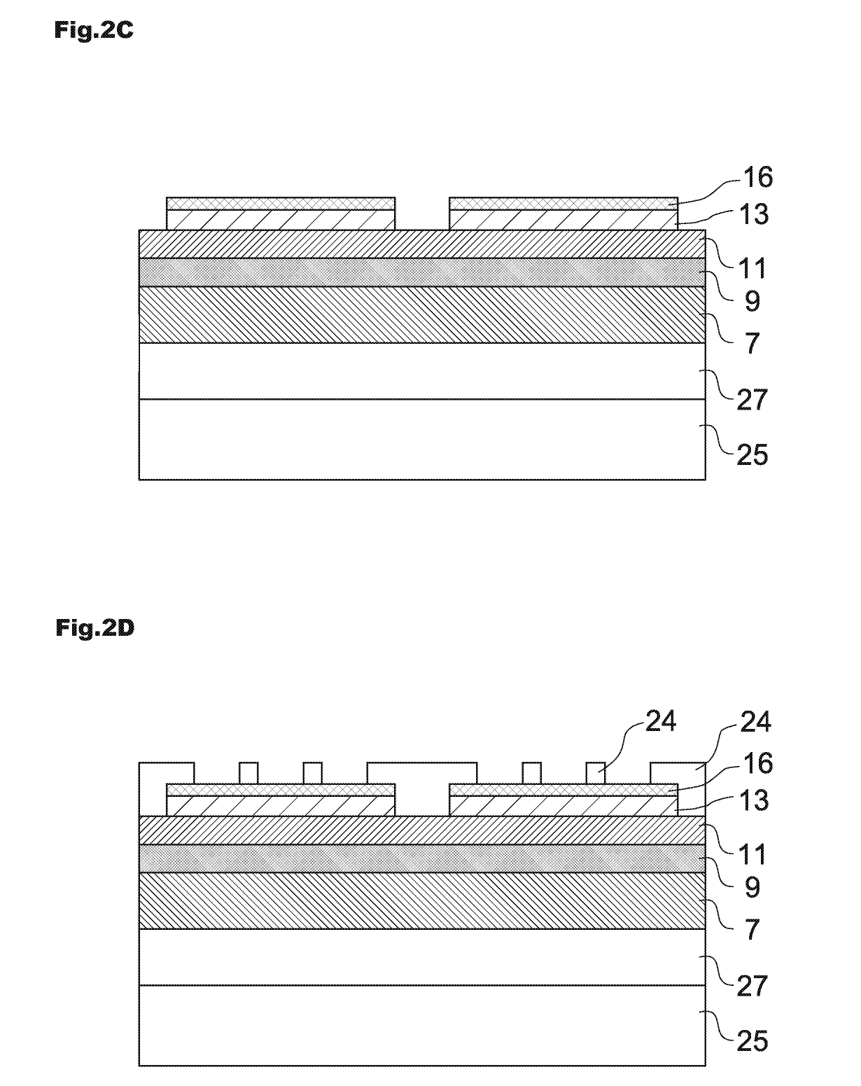

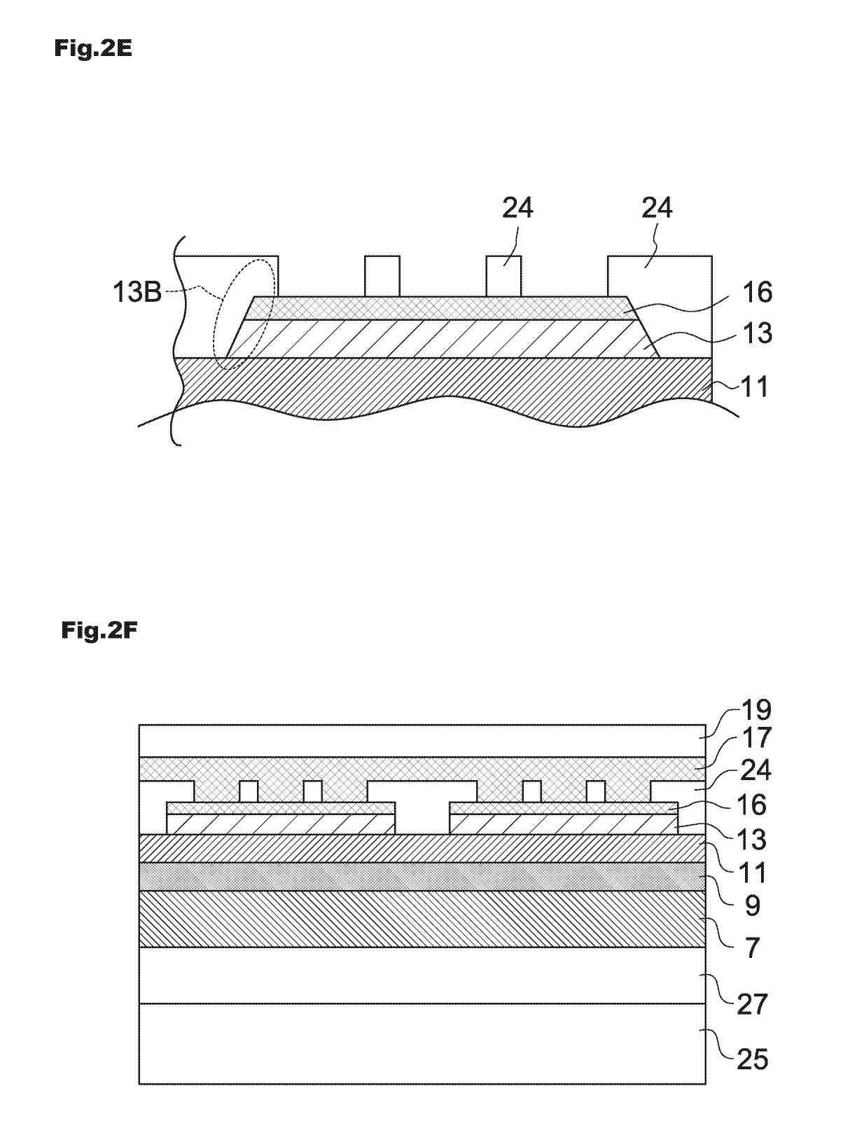

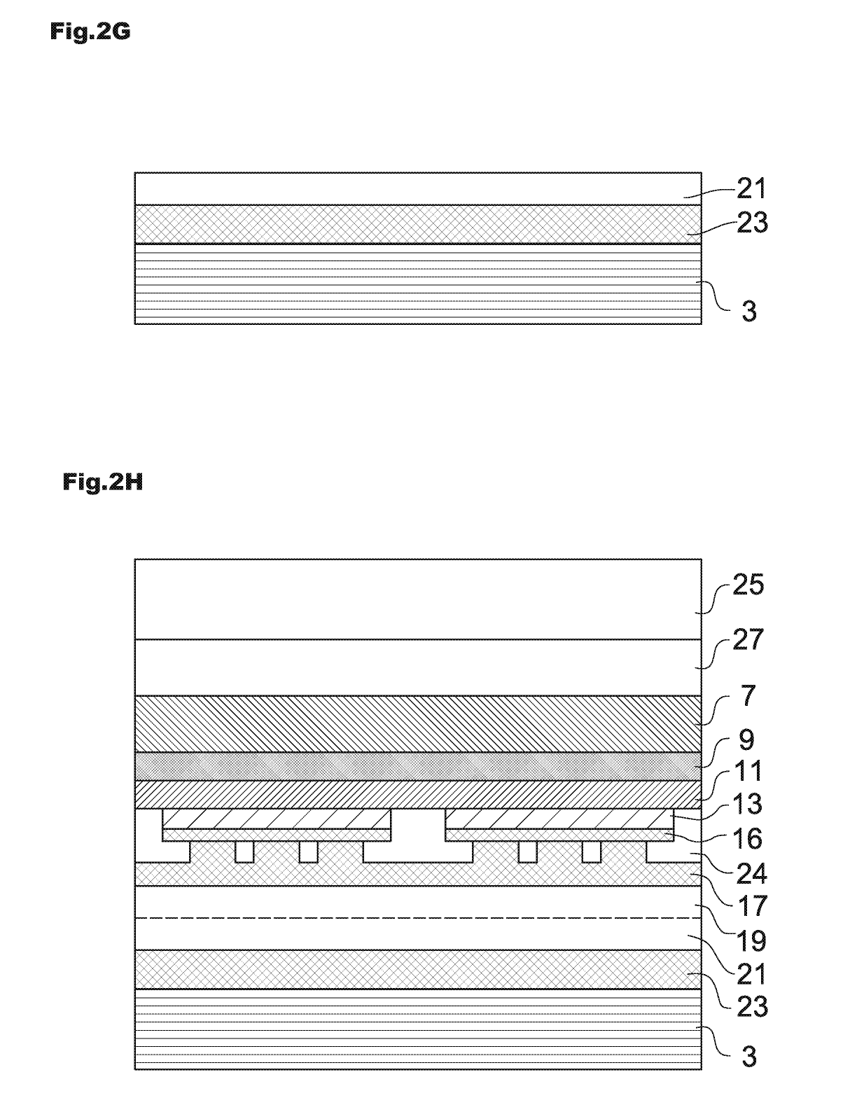

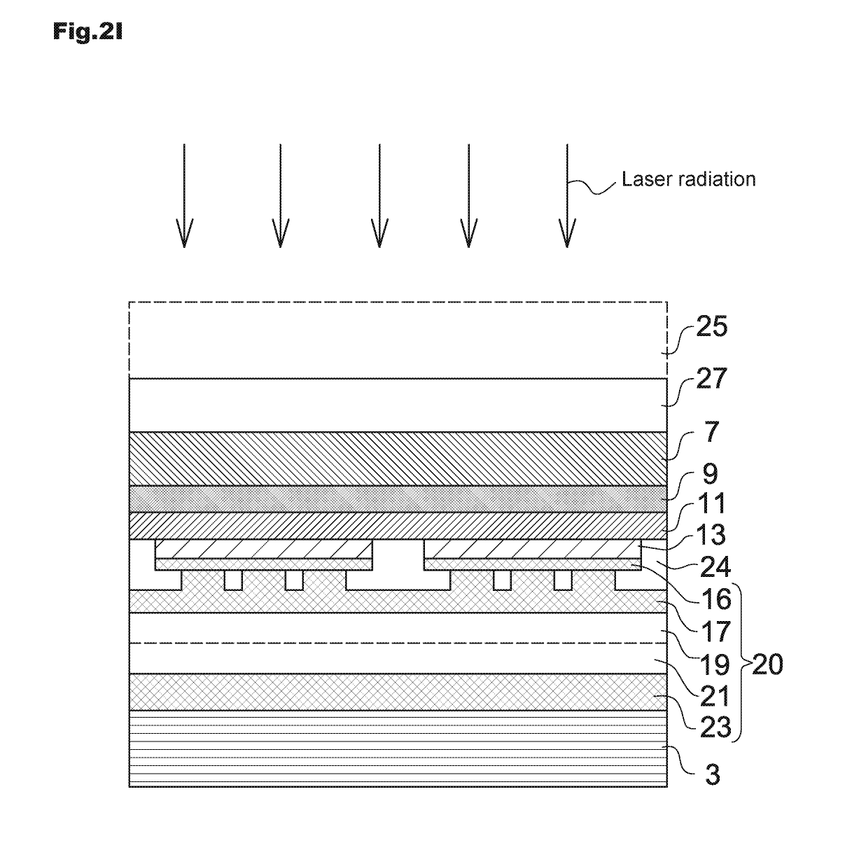

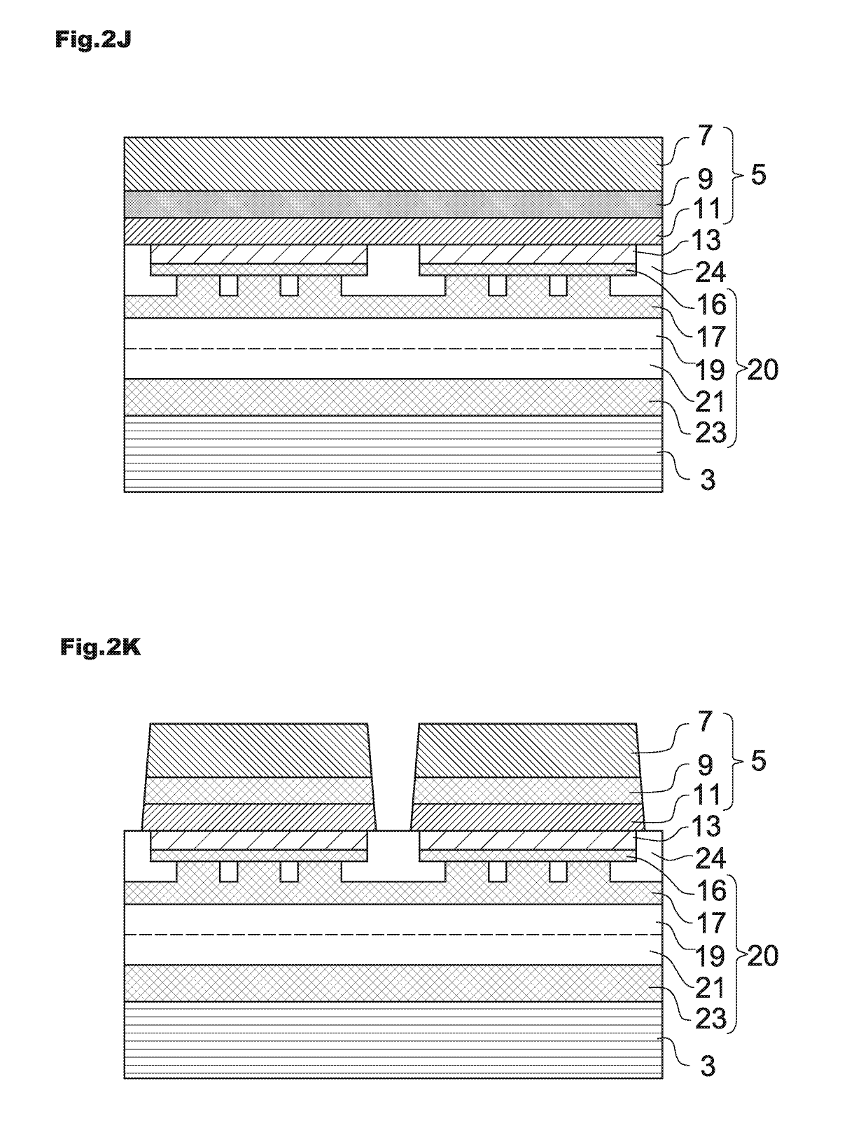

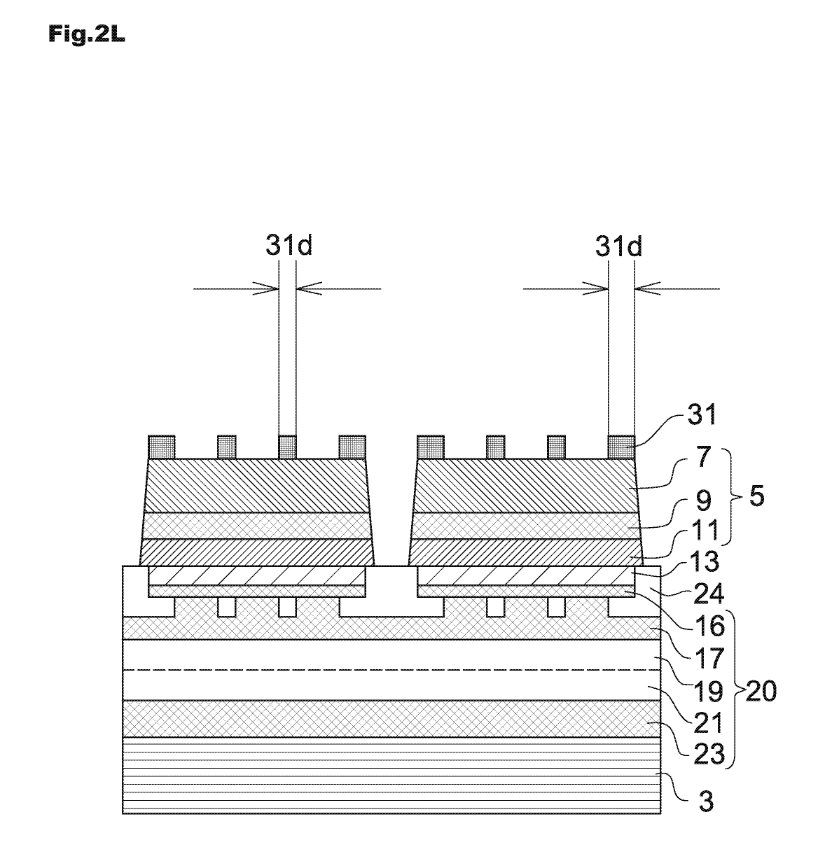

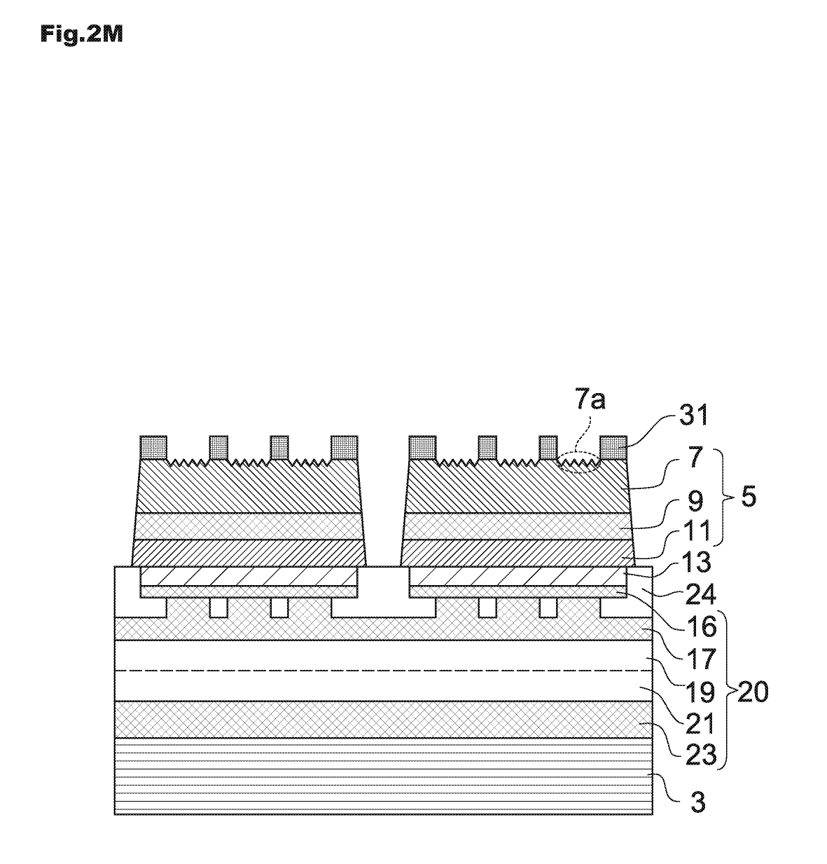

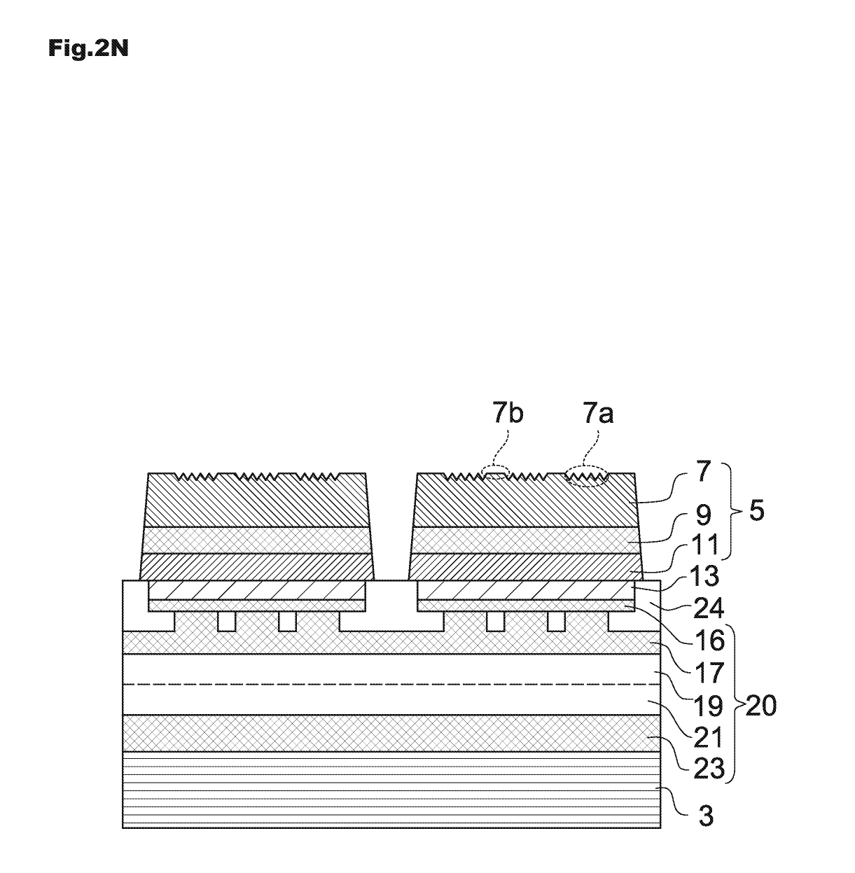

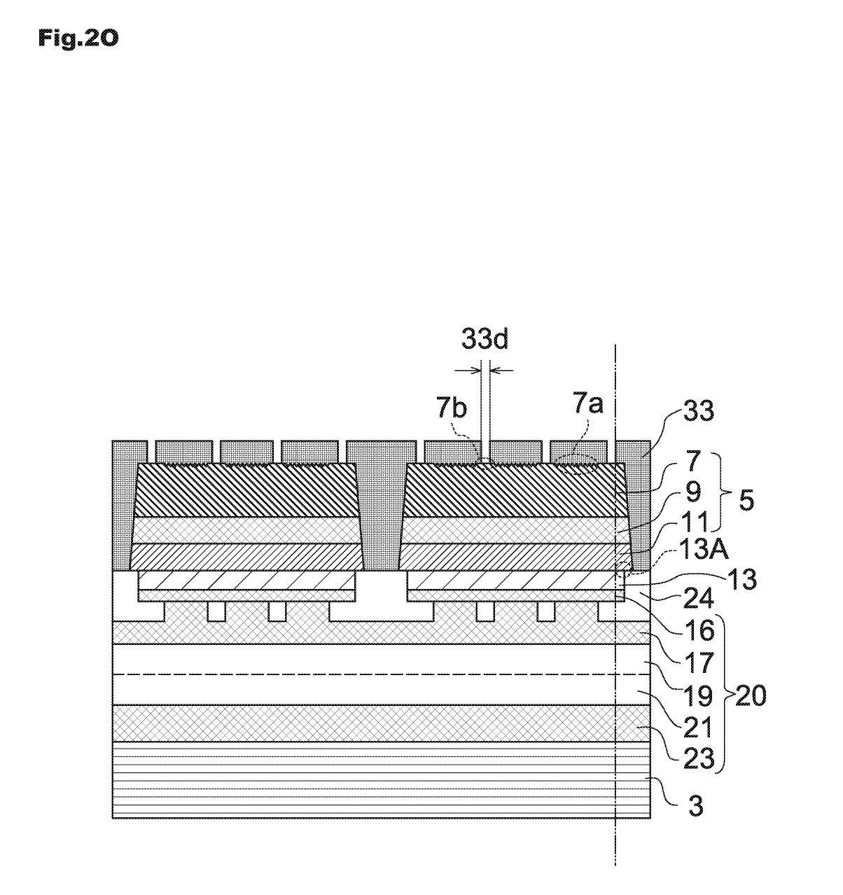

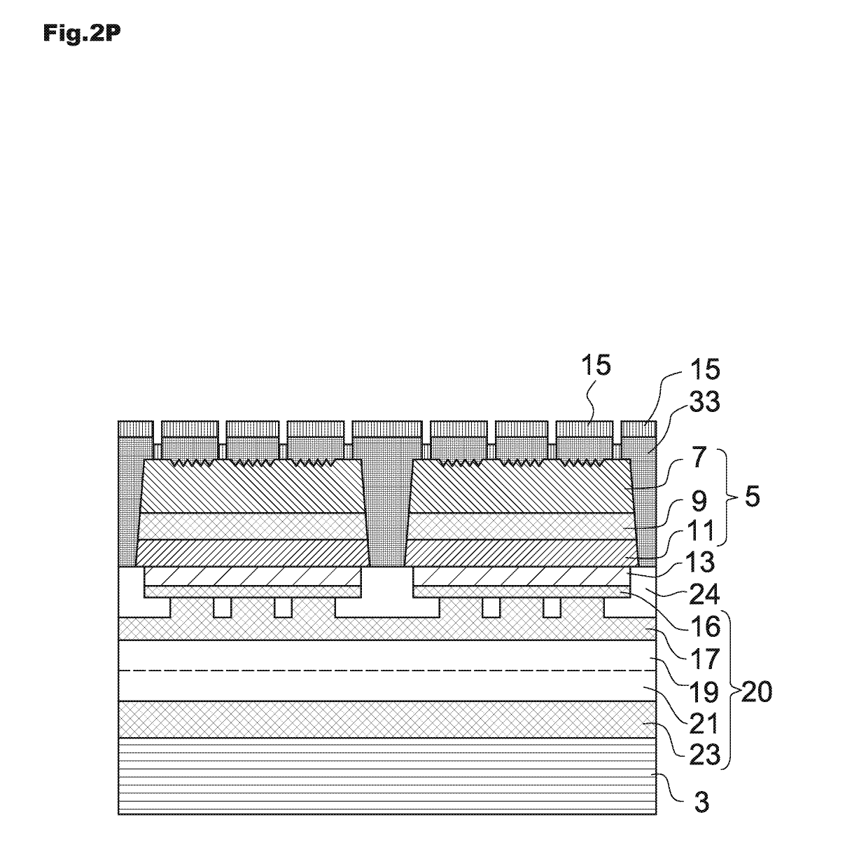

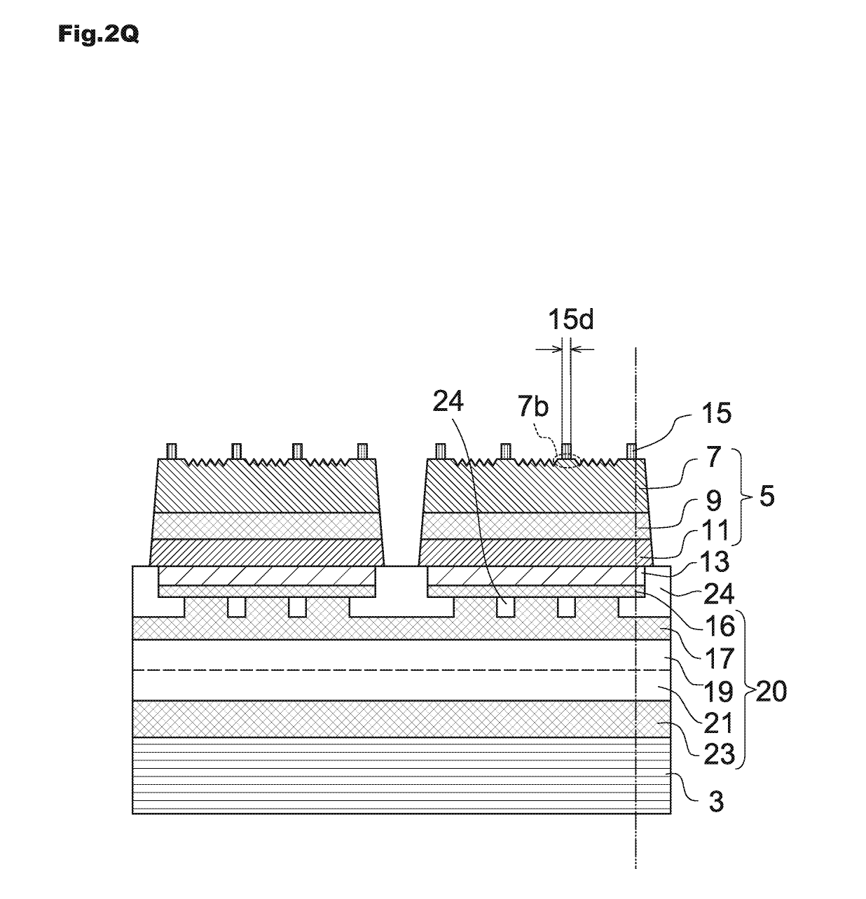

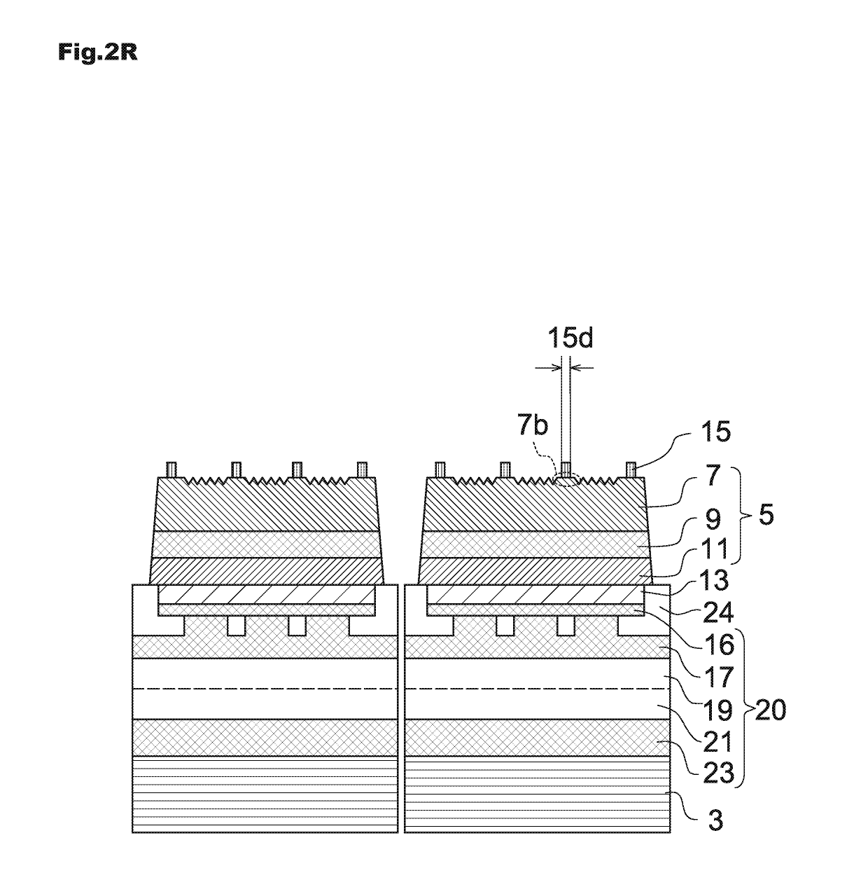

A method for manufacturing the light-emitting device 1 will be described with reference to FIGS. 2A to 2R. It will be understood that the manufacturing conditions and the dimensions such as the thicknesses shown below are by way of example only. Note that FIGS. 2A to 2R referred to below each correspond to a schematic cross-sectional view in the same direction as FIG. 1B.

(Step S1)

As shown in FIG. 2A, a growth substrate 25 is prepared. As an example, the growth substrate 25 may be a C-plane sapphire substrate.

The preparing step includes cleaning the growth substrate 25. A more specific example of the cleaning includes placing the growth substrate 25 in the treatment furnace of a metal organic chemical vapor deposition (MOCVD) system and raising the temperature in the furnace to, for example, 1,150° C. while allowing hydrogen gas to flow at a given rate into the treatment furnace.

The step S1 corresponds to the step (a).

(Step S2)

As shown in FIG. 2B, an underlying layer 27, an n-type semiconductor layer 7, an active layer 9, and a p-type semiconductor layer 11 are sequentially formed on the growth substrate 25. The step S2 is performed, for example, according to the procedures described below.

First, the pressure and temperature in the treatment furnace of the MOCVD system are set to 100 kPa and 480° C. Subsequently, while nitrogen gas and hydrogen gas are allowed to flow as carrier gases at a rate of 5 slm into the treatment furnace, trimethylgallium (TMG) and ammonia are supplied as raw material gases at flow rates of 50 μmol/min and 250,000 μmol/min, respectively, into the treatment furnace for 68 seconds. In this way, a 20-nm-thick, low-temperature buffer layer of GaN is formed on the surface of the growth substrate 25.

Subsequently, the temperature in the treatment furnace of the MOCVD system is raised to 1,150° C. Subsequently, while nitrogen gas and hydrogen gas are allowed to flow as carrier gases at rates of 20 slm and 15 slm, respectively, into the treatment furnace, TMG and ammonia are supplied as raw material gases at flow rates of 100 μmol/min and 250,000 μmol/min, respectively, into the treatment furnace for 30 minutes. In this way, a 1.7-μm-thick, buffer layer of GaN is formed on the surface of the low-temperature buffer layer. These buffer layers form the underlying layer 27.

Subsequently, an n-type semiconductor layer 7 is formed on the underlying layer 27. A specific method of forming the n-type semiconductor layer 7 is, for example, as follows.

First, while the temperature in the treatment furnace of the MOCVD system is still set at 1,150° C., the pressure in the treatment furnace is set to 30 kPa. Subsequently, while nitrogen gas and hydrogen gas are allowed to flow as carrier gases at rates of 20 slm and 15 slm, respectively, into the treatment furnace, TMG, trimethylaluminum (TMA), ammonia, and tetraethylsilane are supplied as raw material gases at flow rates of 94 μmol/min, 6 μmol/min, 250,000 μmol/min, and 0.013 μmol/min, respectively, into the treatment furnace for 60 minutes. In this way, for example, a 2-μm-thick, n-type semiconductor layer 7 with a composition of Al_{0.06}Ga_{0.94}N is formed on the underlying layer 27. When the n-type semiconductor layer 7 includes GaN or AlGaN, the Al content is preferably from 0% to 15%, more preferably from 2% to 11%, even more preferably from 5% to 9%.

Subsequently, an about 5-nm-thick, protective layer of n-type GaN may also be formed on the n-type AlGaN layer by supplying the raw material gases other than TMA for 6 seconds while stopping the supply of TMA, so that the resulting n-type semiconductor layer 7 has the protective layer. As mentioned above, the n-type semiconductor layer 7 preferably has a thickness of 4.5 μm or less, more preferably 4 μm or less, even more preferably 3.5 μm or less.

A case has been described where Si is used as the n-type impurity in the n-type semiconductor layer 7. Besides Si, the n-type impurity may be, for example, Ge, S, Se, Sn, or Te.

An active layer 9 is then formed on the n-type semiconductor layer 7. A specific method of forming the active layer 9 is, for example, as follows.

First, the pressure and temperature in the treatment furnace of the MOCVD system are set to 100 kPa and 830° C. Subsequently, while nitrogen gas and hydrogen gas are allowed to flow as carrier gases at rates of 15 slm and 1 slm, respectively, into the treatment furnace, TMG, trimethylindium (TMI), and ammonia are supplied as raw material gases at flow rates of 10 μmol/min, 12 μmol/min, and 300,000 μmol/min, respectively, into the treatment furnace for 48 seconds. Subsequently, TMG, TMA, tetraethylsilane, and ammonia are supplied at flow rates of 10 μmol/min, 1.6 μmol/min, 0.002 μmol/min, and 300,000 μmol/min, respectively, into the treatment furnace for 120 seconds. These two steps are then repeated to form an active layer 9 including 15 stacks of a 2-nm-thick light-emitting layer of InGaN and a 7-nm-thick barrier layer of n-type AlGaN alternately formed on the n-type semiconductor layer 7.

When the active layer 9 is designed to emit light with a wavelength of 400 nm or less, the In content of InGaN in the light-emitting layer is preferably 10% or less. In this case, the Al content of AlGaN or GaN in the barrier layer is preferably from 0% to 15%, more preferably from 2% to 13%, even more preferably from 5% to 10%.

A p-type semiconductor layer 11 is then formed on the active layer 9. A specific method of forming the p-type semiconductor layer 11 is, for example, as follows.

Specifically, with the pressure in the treatment furnace of the MOCVD system maintained at 100 kPa, the temperature in the treatment furnace is raised to 1,025° C. while nitrogen gas and hydrogen gas are allowed to flow as carrier gases at rates of 15 slm and 25 slm, respectively, into the treatment furnace. Subsequently, TMG, TMA, ammonia, and biscyclopentadienyl magnesium (Cp₂Mg) as a p-type impurity dopant are supplied as raw material gases at flow rates of 35 μmol/min, 20 μmol/min, 250,000 μmol/min, and 0.1 μmol/min, respectively, into the treatment furnace for 60 seconds. In this way, a 20-nm-thick, hole supply layer with a composition of Al_{0.3}Ga_{0.87}N is formed on the surface of the active layer 9. Subsequently, a 120-nm-thick, hole supply layer with a composition of Al_{0.13}Ga_{0.87}N is formed by supplying the raw material gases for 360 seconds, in which the flow rate of TMA is changed to 4 μmol/min. These hole supply layers form the p-type semiconductor layer 11.

After this step, an about 5-nm-thick, p-type GaN layer with a p-type impurity concentration of about 1×10²⁰/cm³ may be formed by supplying the raw material gases other than TMA for 20 seconds, in which the flow rate of Cp₂Mg is changed to 0.2 μmol/min, while stopping the supply of TMA, so that the resulting p-type semiconductor layer 11 has the p-type GaN layer.

A case has been described where Mg is used as the p-type impurity in the p-type semiconductor layer 11. Besides Mg, the p-type impurity may be, for example, Be, Zn, or C.

The step S2 corresponds to the step (b).

(Step S3)

The wafer obtained in the step S2 is subjected to an activation treatment. As a specific example, the activation treatment is performed for 15 minutes in a nitrogen atmosphere using a rapid thermal anneal (RTA) system.

(Step S4)

As shown in FIG. 2C, a second electrode 13 is then formed on a predetermined portion of the upper surface of the p-type semiconductor layer 11. A specific method of forming the second electrode 13 is, for example, as follows.

Using a sputtering system, a 0.7-nm-thick Ni film and a 150-nm-thick Ag film are deposited on a predetermined portion of the upper surface of the p-type semiconductor layer 11. Subsequently, the films are subjected to contact annealing at 400° C. for 2 minutes in a dry air atmosphere using the RTA system. The second electrode 13 may be made of, for example, a Ni—Ag alloy or an alloy of Cu, Pd, and Al, Rh, or Ag.

The step S4 corresponds to the step (c).

(Step S5)

As shown in FIG. 2C, a protective layer 16 is formed on the upper surface of the second electrode 13. For example, the protective layer 16 is formed by depositing an 80-nm-thick Ni film, a 100-nm-thick Ti film, and a 200-nm-thick Pt film using an electron beam vapor deposition system (EB system). Besides Ni/Ti/Pt, the protective layer 16 may be made of TiW/Pt or other materials. It is optional whether or not the step S5 is performed.

(Step S6)

As shown in FIG. 2D, a current blocking layer 24 is formed on the exposed upper surface of the p-type semiconductor layer 11 and on a predetermined region of the upper surface of the protective layer 16. The current blocking layer 24 is formed, for example, by depositing a film of SiO₂, SiN, Zr₂O₃, AlN, or Al₂O₃ by sputtering or other methods.

In the step S6, the current blocking layer 24 is formed at a position facing, in the Z direction, a region where the first electrode 15 is to be formed in a later step.

Optionally, as shown in FIG. 2E, the second electrode 13 may be formed to have a tapered shape 13B in the step S4. This shape makes it easy to form the current blocking layer 24 on the side and upper surfaces of the second electrode 13. This makes it possible to cover the side of the second electrode 13 with the current blocking layer 24 in intimate contact therewith.

(Step S7)

As shown in FIG. 2F, a protective layer 17 is formed over the upper surfaces of the protective layer 16 and the current blocking layer 24, and then, the bonding layer 19 is formed on the upper surface of the protective layer 17. The protective layer 17 is formed by the same method as that for the protective layer 16. For example, the protective layer 17 is formed as a multi-layered structure by alternately depositing Ti and Pt using an electron beam vapor deposition system (EB system). Subsequently, a bonding layer 19 is formed by vapor-depositing, on the upper surface of the protective layer 17, a 10-nm-thick Ti film and then a 3-μm-thick Au—Sn solder film composed of 80% Au and 20% Sn. Besides the Au—Sn solder, the bonding layer 19 may be made of Au—In, Au—Cu—Sn, Cu—Sn, Pd—Sn, Sn, or other solder materials. It is optional whether or not the protective layer 17 is provided.

(Step S8)

As shown in FIG. 2G, a protective layer 23 and a bonding layer 21 are formed on the upper surface of a substrate 3 (support substrate 3) prepared separately from the growth substrate 25. As mentioned above, the substrate 3 may be a conductive substrate such as CuW, W, or Mo or a semiconductor substrate such as Si. The protective layer 23 may be formed similarly to the protective layer 17, and the bonding layer 21 may be formed similarly to the bonding layer 19. It is optional whether or not the protective layer 23 is provided.

(Step S9)

As shown in FIG. 2H, the bonding layer 19 formed on the growth substrate 25 is bonded to the bonding layer 21 formed on the substrate 3, so that the growth substrate 25 is bonded to the substrate 3. As a specific example, the bonding is performed at a temperature of 280° C. under a pressure of 0.2 MPa.

In this step, the bonding layers 19 and 21 are melted and bonded together to form a structure in which the substrate 3 and the growth substrate 25 are bonded on the front and back sides. Therefore, after this step, the bonding layers 19 and 21 may be handled as an integrated part. The diffusion of the material in the bonding layer (19, 21) is suppressed by the protective layers 23 and 17 formed at the stage before the step S9 is performed.

The step S9 corresponds to the step (d).

(Step S10)

As shown in FIG. 2I, the growth substrate 25 is separated. More specifically, laser light is applied from the growth substrate 25 side. In this step, the applied laser light has a wavelength transmittable through the material in the growth substrate 25 (sapphire in this embodiment) and absorbable by the material in the underlying layer 27 (GaN in this embodiment). Thus, the laser light is absorbed by the underlying layer 27 to increase the temperature of the interface between the growth substrate 25 and the underlying layer 27, so that the decomposition of GaN occurs to cause the separation of the growth substrate 25.

Subsequently, after metallic Ga remaining on the wafer is removed using hydrochloric acid or the like, GaN (underlying layer 27) is removed by dry etching using an ICP system, so that the n-type semiconductor layer 7 is exposed. In the step S10, the underlying layer 27 is removed, and semiconductor layers 5 are left, which include the p-type semiconductor layer 11, the active layer 9, and the n-type semiconductor layer 7 stacked in this order from the substrate 3 side (see FIG. 2J).

The step S10 corresponds to the step (e).

(Step S11)

As shown in FIG. 2K, adjacent devices are separated from each other. Specifically, using the ICP system, the semiconductor layers 5 are etched at the boundary region between adjacent devices until the upper surface of the current blocking layer 24 is exposed. In this step, the current blocking layer 24 functions as an etching stopper layer. FIG. 2K shows that the semiconductor layers 5 have a side surface inclined with respect to the vertical direction. It will be understood that such a shape is merely an example and not intended to be limiting.

(Step S12)

As shown in FIG. 2L, a resist mask 31 is formed on a predetermined region of the upper surface of the n-type semiconductor layer 7. A photoresist may be used as the resist mask 31. Alternatively, a metal or insulator film that can be removed with acid may also be used as the resist mask 31.

In the step S12, the width 31d of the resist mask 31 is preferably designed to be wider than the width 15d (see FIG. 1C) of the first electrode 15 to be formed in a later step. However, if the photolithography step can be performed with very high precision, the width 31d of the resist mask 31 may be designed to be substantially equal to the width 15d of the first electrode 15.

(Step S13)

As shown in FIG. 2M, the exposed surface of the n-type semiconductor layer 7 is etched to form a roughened surface portion 7a. A specific example of the etching method includes immersing the wafer in a solution of an alkali such as KOH. In this step, the resist mask 31-covered region of the n-type semiconductor layer 7 maintains a smooth surface without being etched whereas the exposed region of the n-type semiconductor layer 7, not covered with the resist mask 31, is etched to form a roughened surface portion 7a.

Subsequently, as shown in FIG. 2N, the resist mask 31 is separated. In this way, the surface of the n-type semiconductor layer 7 is processed to form a roughened surface portion 7a and a smooth surface portion 7b. In order to improve the light extraction efficiency, the roughened surface portion 7a preferably has a valley depth of 0.3 μm to 3 μm, more preferably 0.4 μm to 2.5 μm.

The steps S12 and S13 correspond to the step (f).

(Step S14)

As shown in FIG. 2O, a resist mask 33 is formed on a predetermined region of the upper surface of the n-type semiconductor layer 7 and on the side surface of the semiconductor layers 5. In this step, the resist mask 33 is formed to cover the roughened surface portion 7a and a part of the smooth surface portion 7b, which are formed in the step S13. Therefore, the width 33d of the resist mask 33 is narrower than the width of the smooth surface portion 7b of the n-type semiconductor layer 7.

In addition, the resist mask 33 formed in the step S14 has openings provided inside the position (region 13A) where the outer edge of the second electrode 13 is in contact with the p-type semiconductor layer 11.

The step S14 corresponds to the steps (g1) to (g2).

(Step S15)

As shown in FIG. 2P, a material or materials for the first electrode 15 are deposited on the exposed upper surface of the n-type semiconductor layer 7 and on the upper surface of the resist mask 33. Specifically, for example, a stack of conductive materials Ni/Al/Ni/Ti/Au is formed, for example, with a thickness of about 3 μm by vapor deposition using an electron beam vapor deposition system.

As mentioned above, the opening width 33d of the resist mask 33 is narrower than the width of the smooth surface portion 7b of the n-type semiconductor layer 7. Therefore, the material used to form the first electrode 15 is prevented from flowing into the roughened surface portion 7a of the n-type semiconductor layer 7.

The step S15 corresponds to the step (g3).

(Step S16)

As shown in FIG. 2Q, the resist mask 33 is separated. This step allows the first electrode 15 to be formed on the smooth surface portion 7b of the n-type semiconductor layer 7. The first electrode 15 as formed has an outer edge in the shape of a frame as described above with reference to FIG. 1A.

The width 15d of the first electrode 15 formed through the steps S12 to S16 is narrower than the width of the smooth surface portion 7b of the n-type semiconductor layer 7. The first electrode 15 is also formed on the smooth surface portion 7b of the n-type semiconductor layer 7 in such a manner that the material used to form the first electrode 15 is prevented from flowing into the roughened surface portion 7a of the n-type semiconductor layer 7.

The first electrode 15 formed after the step S16 is located at a position facing the current blocking layer 24 in the Z direction (the direction perpendicular to the surface of the substrate 3). The upper surface of the n-type semiconductor layer 7 has a smooth surface portion 7b outside the outer edge of the first electrode 15. In addition, the second electrode 13 and the p-type semiconductor layer 11 are in contact with each other outside the outer edge of the first electrode 15 (at the region 13A shown in FIG. 1C described above).

The step S16 corresponds to the step (g4). The steps S14 to S16 correspond to the step (g).

(Step S17)

As shown in FIG. 2R, the wafer is divided into chip units. As a specific example, the devices are separated from one another using a laser dicer.

Subsequently, the back surface of the substrate 3 is bonded to a package, for example, with a Ag paste, and current supply wires 14 are connected to the current supply portions 15a. For example, current supply wires 14 of Au are connected to the current supply portions 15a of 100 μmφ by wire bonding under a load of 50 g. Thus, the light-emitting device 1 shown in FIGS. 1A to 1B is obtained.

[Verification]

Hereinafter, the invention will be described with reference to examples and reference examples. Note that all light-emitting devices below have a peak emission wavelength of 365 nm and the thickness of the semiconductor layers 5 (the thickness from the smooth surface portion 7b to the p-type semiconductor layer 11) is in the range of 2.6 μm to 2.9 μm.

### Example 1-1

The light-emitting device of Example 1-1 corresponding to the light-emitting device 1 described above was manufactured through the steps S1 to S17.

### Reference Example 1-1

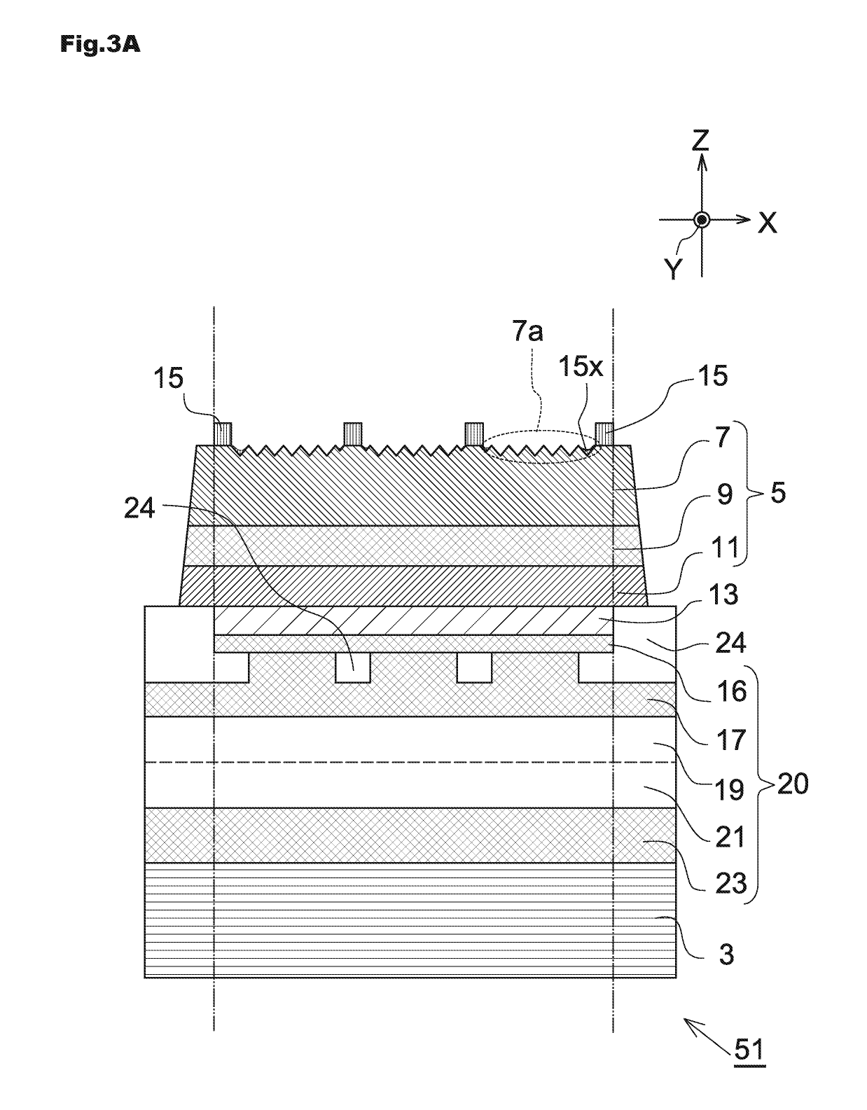

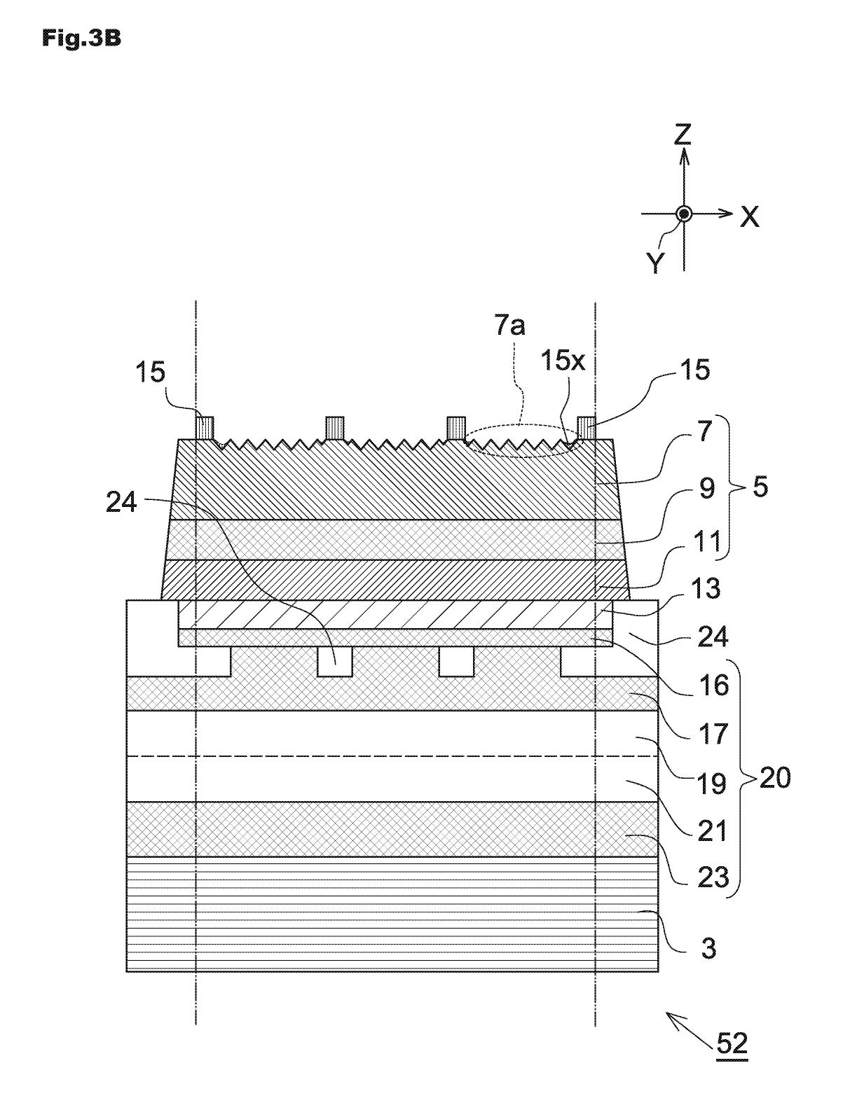

FIG. 3A is a schematic cross-sectional view showing the light-emitting device of Reference Example 1-1. The light-emitting device 51 of Reference Example 1-1 differs from the light-emitting device 1 of Example 1-1 in that the outer edge of the first electrode 15 is located to face the outer edge of the second electrode 13 in the Z direction. Additionally, in the light-emitting device 51 of Reference Example 1-1, the roughened surface portion 7a of the n-type semiconductor layer 7 extends to the vicinity of the end of the first electrode 15, so that the step S15 has allowed the material for the first electrode 15 to flow into a valley region (region 15x) of the roughened surface portion 7a.

FIG. 3B is a schematic cross-sectional view showing the light-emitting device of Reference Example 1-2. Similarly to the light-emitting device 51 of Reference Example 1-1, in the light-emitting device 52 of Reference Example 1-2, the roughened surface portion 7a of the n-type semiconductor layer 7 extends to the vicinity of the end of the first electrode 15, so that the step S15 has allowed the material for the first electrode 15 to flow into a valley region (region 15x) of the roughened surface portion 7a. Similarly to the light-emitting device 1 of Example 1-1, however, in the light-emitting device 52 of Reference Example 1-2, the outer edge of the second electrode 13 and the p-type semiconductor layer 11 are in contact with each other at a position outside the outer edge of the first electrode 15.

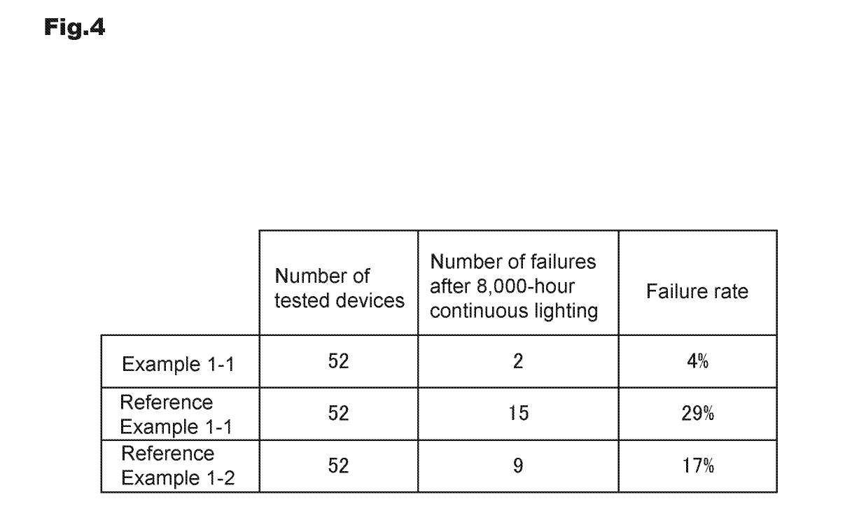

Each of the light-emitting devices of Example 1-1, Reference Example 1-1, and Reference Example 1-2 was subjected to a continuous lighting test at 25° C. to 35° C. while bonded to an aluminum board, on which each of their packages was mounted. FIG. 4 shows the results.

After the continuous lighting for 8,000 hours, the rate of occurrence of lighting failures (the failure rate) was as low as 4% for the light-emitting device of Example 1-1. In contrast, the failure rate was 29% for the light-emitting device of Reference Example 1-1 and 17% for the light-emitting device of Reference Example 1-2. The cross-sections of the burned-out light-emitting devices were subjected to observation with a scanning electron microscope (SEM) and analysis by energy dispersive X-ray spectrometry (EDS). As a result, the Ag material used to form the second electrode 13 was detected in the vicinity of the first electrode 15. It was also observed that in some of the burned-out light-emitting devices, the semiconductor layers 5 were cracked between the outer edge (end) of the second electrode 13 and the outer edge (end) of the first electrode 15.

The inventors have speculated that these phenomena may be caused by the fact that the electric field concentrates in the vicinity of the outer edges of the first and second electrodes 15 and 13 to cause local heating of these regions so that the material in the second electrode 13 undergoes diffusion (migration) to the first electrode 15 side through cracks or defects. It is conceivable that the temperature increase by heating would create an environment where the material in the second electrode 13 can easily diffuse, because the migration can proceed more smoothly at higher temperatures.

The failure rate for the light-emitting device 52 of Reference Example 1-2 is lower than that for the light-emitting device 51 of Reference Example 1-1. The reason for this would be that the distance in the X-Y plane direction between the outer edges of the first and second electrodes 15 and 13 is kept at a sufficient level in the light-emitting device 52 of Reference Example 1-2 so that the number of light-emitting devices in which the material in the second electrode 13 diffuses to reach the first electrode 15 becomes smaller in the case of Reference Example 1-2 than in the case of Reference Example 1-1.

The failure rate for the light-emitting device 1 of Example 1-1 is still lower than that for the light-emitting device 52 of Reference Example 1-2. The reason for this would be that the light-emitting device 1 of Example 1-1 is designed to prevent the material for the first electrode 15 from flowing into the roughened surface portion 7a of the n-type semiconductor layer 7, so that the distance in the Z direction between the second electrode 13 and the first electrode 15 is kept constant and as a result the number of light-emitting devices in which the material in the second electrode 13 diffuses to reach the first electrode 15 becomes smaller in the case of Example 1-1 than in the case of Reference Example 1-2.

[Other modes]

Hereinafter, other modes of the first embodiment will be described.

<1> Among the layers constituting the semiconductor layers 5 in the embodiment described above, the p-type semiconductor layer 11 is proximal to the substrate 3 whereas the n-type semiconductor layer 7 is distal to the substrate 3. Alternatively, these conductivity types may be reversed.

<2> In the embodiment described above, the light-emitting device 1 has the protective layer (16, 17). However, the protective layer (16, 17) is not an essential component. The protective layer (16, 17) can prevent the reduction of the reflectance of the first electrode 15. Therefore, the protective layer (16, 17) is preferably provided to maintain the light extraction efficiency at a high level.

<3> In the description described above, the light-emitting device 1 has the current blocking layer 24. However, the current blocking layer 24 is not an essential component. The current blocking layer 24 is preferably provided in order to allow the current flowing through the active layer 9 to propagate in directions parallel to the X-Y plane so that the luminous efficiency can be increased.

### Second Embodiment

A second embodiment of the invention will be described with reference to the drawings.

[Structure]

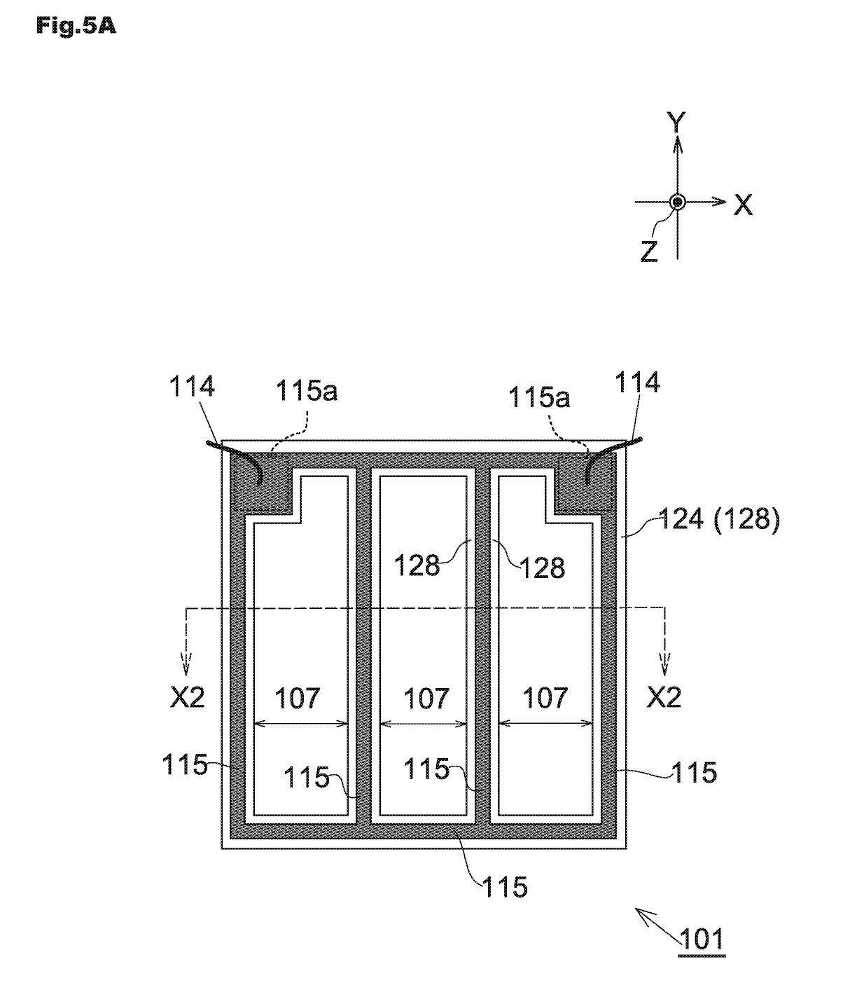

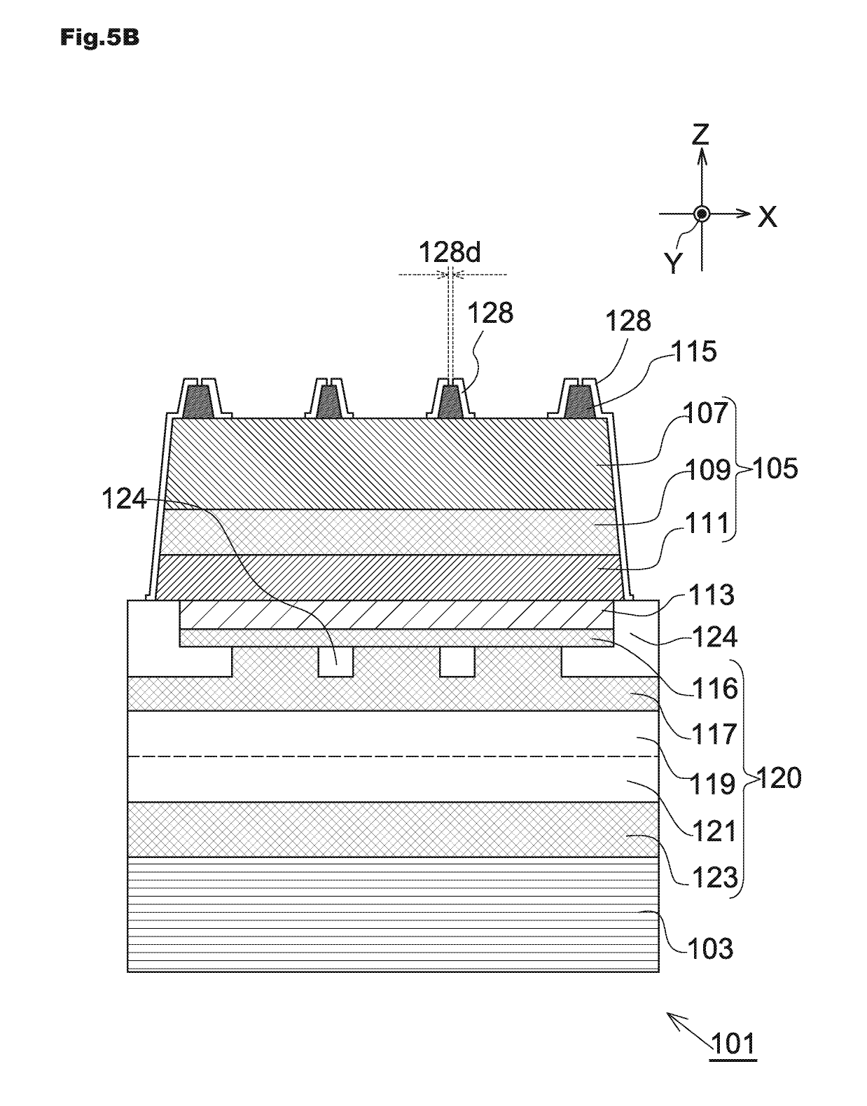

FIGS. 5A and 5B are views schematically showing the structure of a semiconductor light-emitting device according to a second embodiment of the invention. FIG. 5A corresponds to a plan view from the direction of light extraction. FIG. 5B is a cross-sectional view cut along the X2-X2 line in FIG. 5A. Hereinafter, the light extraction surface will be referred to as the X-Y plane, and the direction perpendicular to the X-Y plane will be referred to as the Z direction.

As shown in FIG. 5B, the semiconductor light-emitting device 101 includes a substrate 103, semiconductor layers 105 formed on the substrate 103, a first electrode 115, a second electrode 113, and a protective layer 128. Hereinafter, the semiconductor light-emitting device 101 will also be abbreviated simply as the “light-emitting device 101” as needed.

(Substrate 103)

The substrate 103 includes, for example, a conductive substrate such as CuW, W, or Mo or a semiconductor substrate such as Si.

(Semiconductor Layers 105)

In this embodiment, the semiconductor layers 105 include a p-type semiconductor layer 111, an active layer 109, and an n-type semiconductor layer 107, which are formed and stacked in this order from the side close to the substrate 103. In this embodiment, the n-type semiconductor layer 107 corresponds to a “first semiconductor layer,” and the p-type semiconductor layer 111 to a “second semiconductor layer.”

The p-type semiconductor layer 111 includes, for example, a nitride semiconductor layer doped with a p-type impurity such as Mg, Be, Zn, or C. The nitride semiconductor layer may include, for example, GaN, AlGaN, or AlInGaN.

The active layer 109 include semiconductor layers including, for example, a light-emitting layer including InGaN and a barrier layer including n-type AlGaN, which are periodically repeated. These layers may be undoped or p-type or n-type doped. The active layer 109 only has to include a stack of layers including at least two materials with different energy band gaps. The materials used to form the active layer 109 are appropriately selected depending on the wavelength of light to be generated. In the light-emitting device 101 of this embodiment, the active layer 109 generates light with a wavelength of 400 nm or less. For example, when the emission wavelength is 365 nm, the active layer 109 includes a stack of repeated In_{0.05}Ga_{0.95}N and Al_{0.09}Ga_{0.91}N.

The n-type semiconductor layer 107 includes, for example, a nitride semiconductor layer doped with an n-type impurity such as Si, Ge, S, Se, Sn, or Te. The nitride semiconductor layer may include, for example, GaN, AlGaN, or AlInGaN. The n-type semiconductor layer 107 may include a material of a composition different from that of the p-type semiconductor layer 111.

Particularly when the light-emitting device 101 is configured to emit light with a wavelength of 400 nm or less, the n-type semiconductor layer 107, which forms the light extraction surface, should preferably be made as thin as possible so that the absorption of light in the semiconductor layers 105, particularly in the n-type semiconductor layer 107 can be kept low. As an example, the thickness of the n-type semiconductor layer 107 is preferably 4.5 μm or less, more preferably 4 μm or less, even more preferably 3.5 μm or less. In this regard, the total thickness of the semiconductor layers 105 is preferably 5 μm or less, more preferably 4.5 μm or less, even more preferably 4 μm or less. In the semiconductor layers 105, the thickness of the n-type semiconductor layer 107 should be sufficiently larger than that of the p-type semiconductor layer 111 and the active layer 109.

(First Electrode 115)

The first electrode 115 is formed on the opposite surface of the n-type semiconductor layer 107 from the active layer 109. In this embodiment, the first electrode 115 forms an n-side electrode. The first electrode 115 may have, for example, a multilayer structure such as Ni/Al/Ni/Ti/Au, Cr/Au, Ti/Pt/Au, or Ti/Pt/Cr/Au/Cr/Pt/Au.

As shown in FIG. 5A, the first electrode 115 has a frame shape when viewed in the Z direction. More specifically, the first electrode 115 has an outer edge in the shape of a frame along the outer edge of the semiconductor layers 105 (n-type semiconductor layer 107). In addition, the light-emitting device 101 shown in FIG. 5A has two first electrodes 115 that extend in the Y direction and are provided at two positions located inside the outer edge of the first electrode 115 in the shape of a frame and apart in the X direction from the outer edge. However, the number of the first electrodes 115 extending inside the frame-shaped region is not limited to 2 and may be 1 or 3 or more. It will be understood that the shape of the first electrode 115 shown in FIG. 5A is only an example and may be freely changed depending on the design.

The first electrode 115 includes, as its parts, current supply portions 115a to which current supply wires 114 are connected. The current supply portions 115a are regions wider than the other regions of the first electrode 115. The current supply wires 114 include, for example, Au or Cu. The current supply wire 114 has one end connected to the current supply portion 115a and the opposite end connected to, for example, a patterned electric supply portion of a package substrate.

(Second Electrode 113)

As shown in FIG. 5B, the second electrode 113 is formed in contact with the p-type semiconductor layer 111, and forms an ohmic contact with the p-type semiconductor layer 111. In this embodiment, the second electrode 113 forms a p-side electrode.

When a voltage is applied between the first and second electrodes 115 and 113, a current flows in the active layer 109 to allow the active layer 109 to emit light.

The second electrode 113 preferably includes a conductive material with a high reflectance (e.g., 80% or more, more preferably 90% or more) to the light emitted from the active layer 109. More specifically, the second electrode 113 is made of a material including, for example, Ag, Al, or Rh. As mentioned above, the light-emitting device 101 is so designed that the light emitted from the active layer 109 is extracted to the n-type semiconductor layer 107 side. When the second electrode 113 includes a material with a high reflectance, the light emitted from the active layer 109 to the substrate 103 side is reflected to the n-type semiconductor layer 107 side so that the light extraction efficiency is increased.

(Conductive Layer 120)

A conductive layer 120 is formed on the substrate 103. In this embodiment, the conductive layer 120 has a multilayer structure including an anti-diffusion layer 123, a bonding layer 121, a bonding layer 119, an anti-diffusion layer 117, and an anti-diffusion layer 116.

The bonding layer 119 and the bonding layer 121 each include, for example, Au—Sn, Au—In, Au—Cu—Sn, Cu—Sn, Pd—Sn, or Sn. As described below, the bonding layers 119 and 121 are formed by a process including forming the bonding layer 121 on the substrate 103, forming the bonding layer 119 on another substrate (the growth substrate 125 described later), opposing the bonding layers 119 and 121 to each other, and then bonding them to each other. The bonding layers 119 and 121 may also be integrated into a single layer.

The anti-diffusion layers 116 and 117 each include, for example, a multilayer structure such as Ni/Ti/Pt or TiW/Pt, and are provided to prevent the material in the bonding layer (119, 121) from diffusing to the second electrode 113 side, which would otherwise reduce the reflectance of the second electrode 113. However, it is optional whether or not the light-emitting device 101 has the anti-diffusion layers 116 and 117.

The anti-diffusion layer 123 includes, for example, the same material as the anti-diffusion 117, and is provided to prevent the material in the bonding layer (119, 121) from diffusing to the substrate 103 side. However, it is optional whether or not the light-emitting device 101 has the anti-diffusion layer 123.

(Current Blocking Layer 124)

The current blocking layer 124 includes, for example, SiO₂, SiN, Zr₂O₃, AlN, or Al₂O₃. The current blocking layer 124 is formed at a position facing the first electrode 115 in the Z direction. The current blocking layer 124 plays a role in allowing the current through the active layer 109 to propagate in directions parallel to the X-Y plane. In addition, the current blocking layer 124 is also formed at a position outside the semiconductor layers 105 to function also as an etching stopper layer during device separation (step S31) as described below in the section of manufacturing method.

(Protective Layer 128)

As shown in FIG. 5B, the light-emitting device 101 of this embodiment has a protective layer 128 that is formed to cover the outside surface and a part of the upper surface of the first electrode 115. More specifically, the protective layer 128 is formed to extend from a first position on the upper surface of the n-type semiconductor layer 107 to a second position on the upper surface of the first electrode 115 through the outside surface of the first electrode 115, in which the first position is outside the region where the first electrode 115 is formed. The protective layer 128 is preferably made of a material transparent to the light emitted from the active layer 109, such as SiO₂, Al₂O₃, Y₂O₃, ZnO, or ZrO₂. These materials all have thermal expansion coefficients smaller than that of the first electrode 115. Additionally, an adhesion promoter layer may also be formed at the interface between the protective layer 128 and the first electrode 115 to facilitate the bonding between them. Such an adhesion promoter layer may be made of, for example, a material including Ti.

As described above with reference to FIG. 5A, the first electrode 115 in this embodiment is formed to extend in a predetermined direction. The protective layer 128 is formed to extend along the extending direction of the first electrode 115. Additionally, as shown in FIG. 5B, the upper surface of the first electrode 115 is not completely covered with the protective layer 128, and the protective layer 128 with which the upper surface of the first electrode 115 is covered has an opening 128d. In this embodiment, the opening 128d also extends along the extending direction of the first electrode 115. Thus, the exposed surface of the first electrode 115, which is exposed through the opening 128d, extends in the shape of a slit along the extending direction of the first electrode 115.

Hereinafter, a method for manufacturing the light-emitting device 101 will be described, and then the effects of the light-emitting device 101 will be described.

[Manufacturing Method]

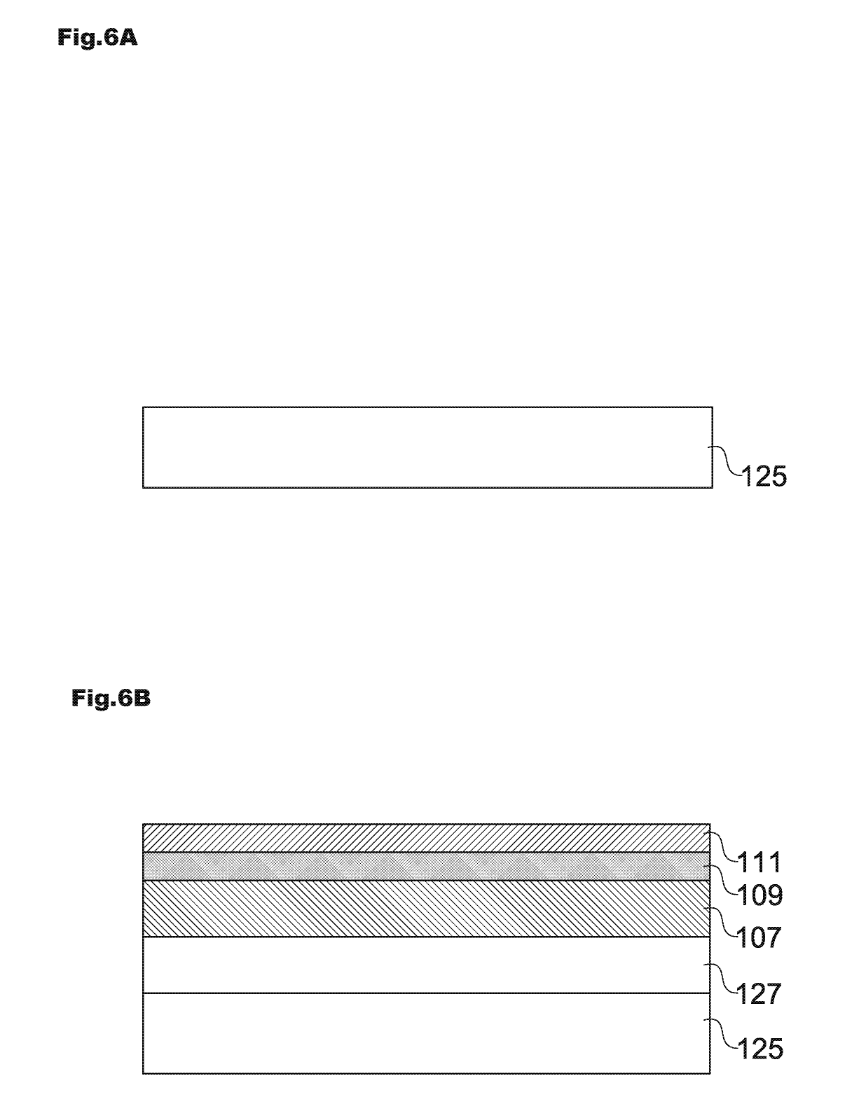

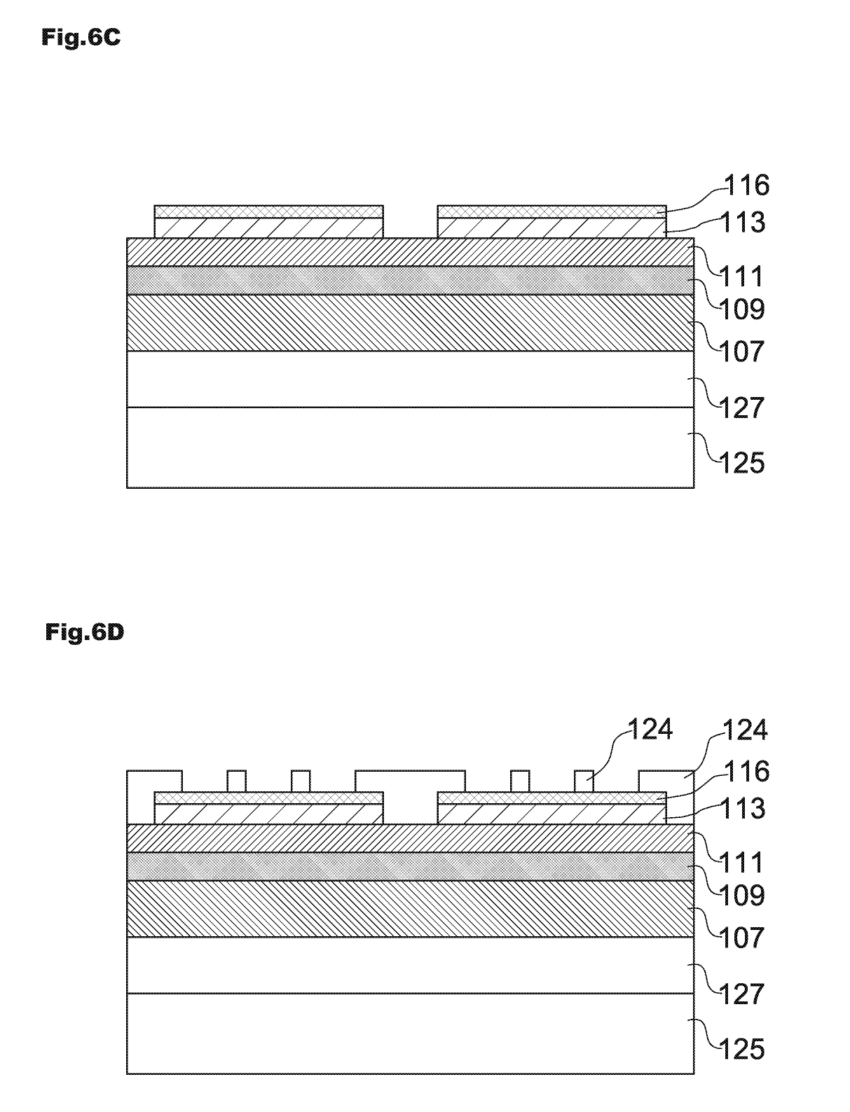

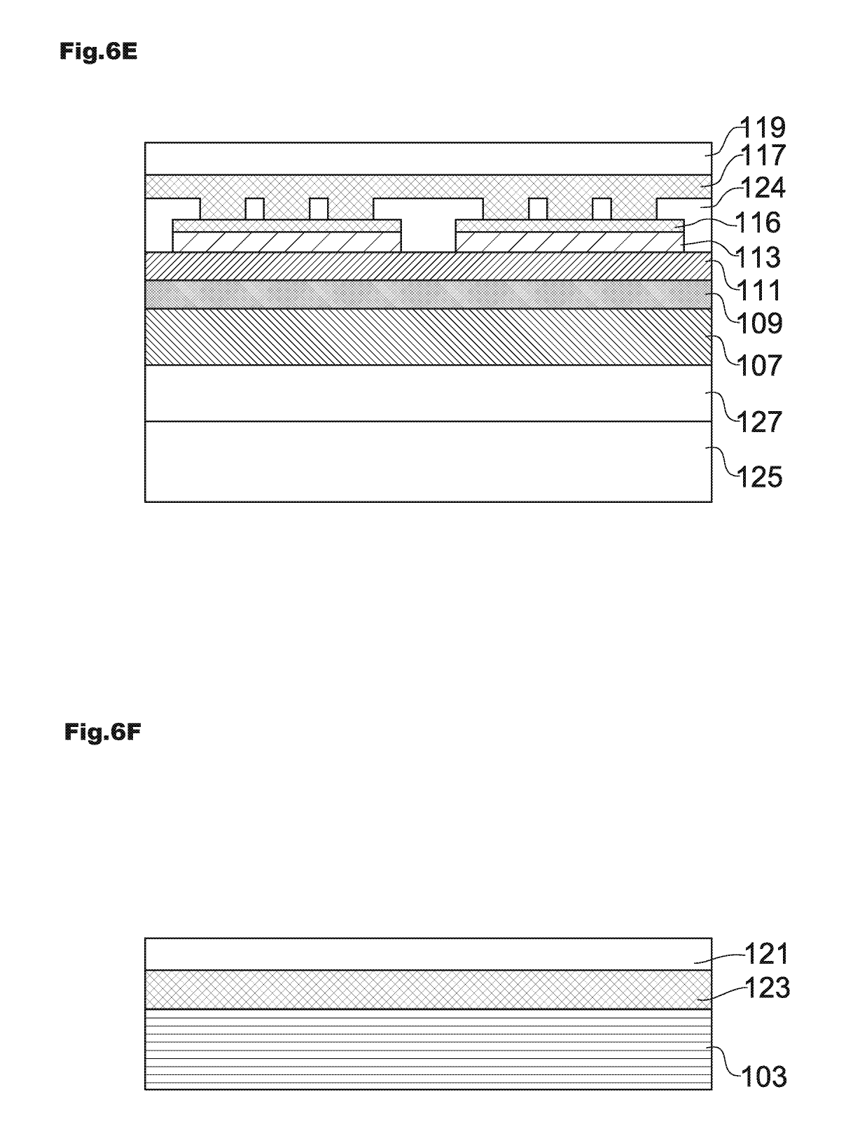

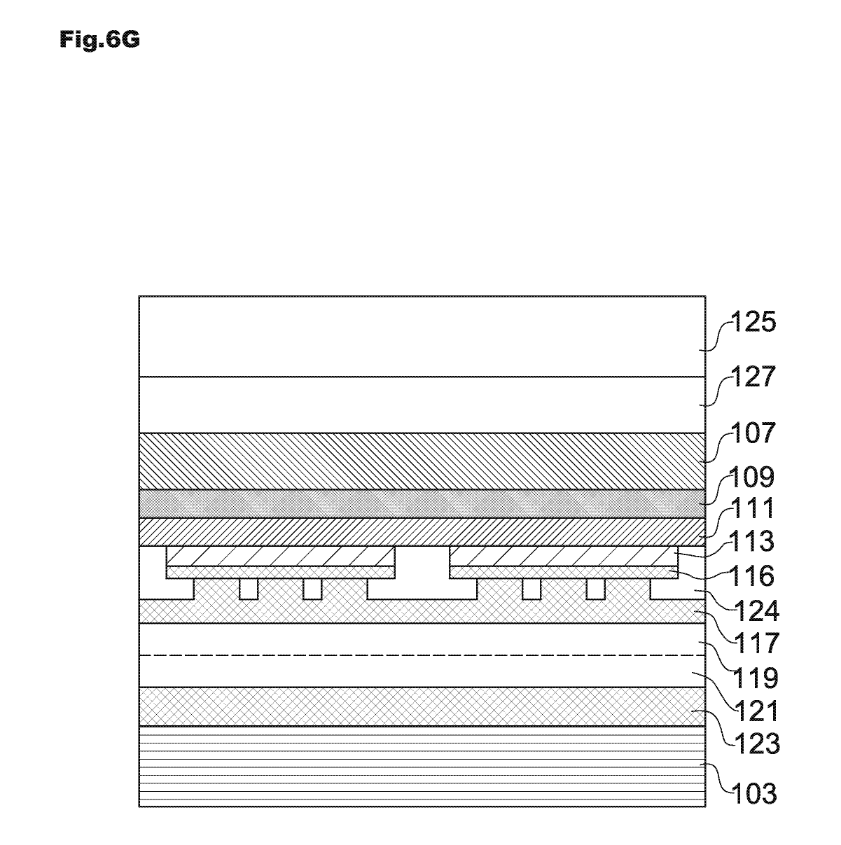

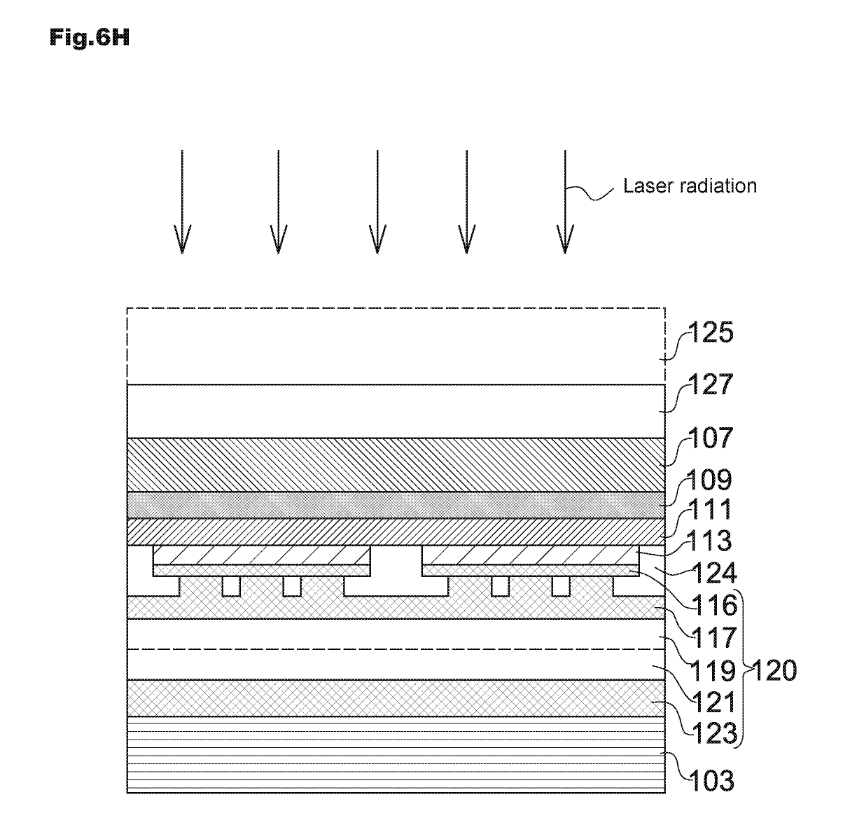

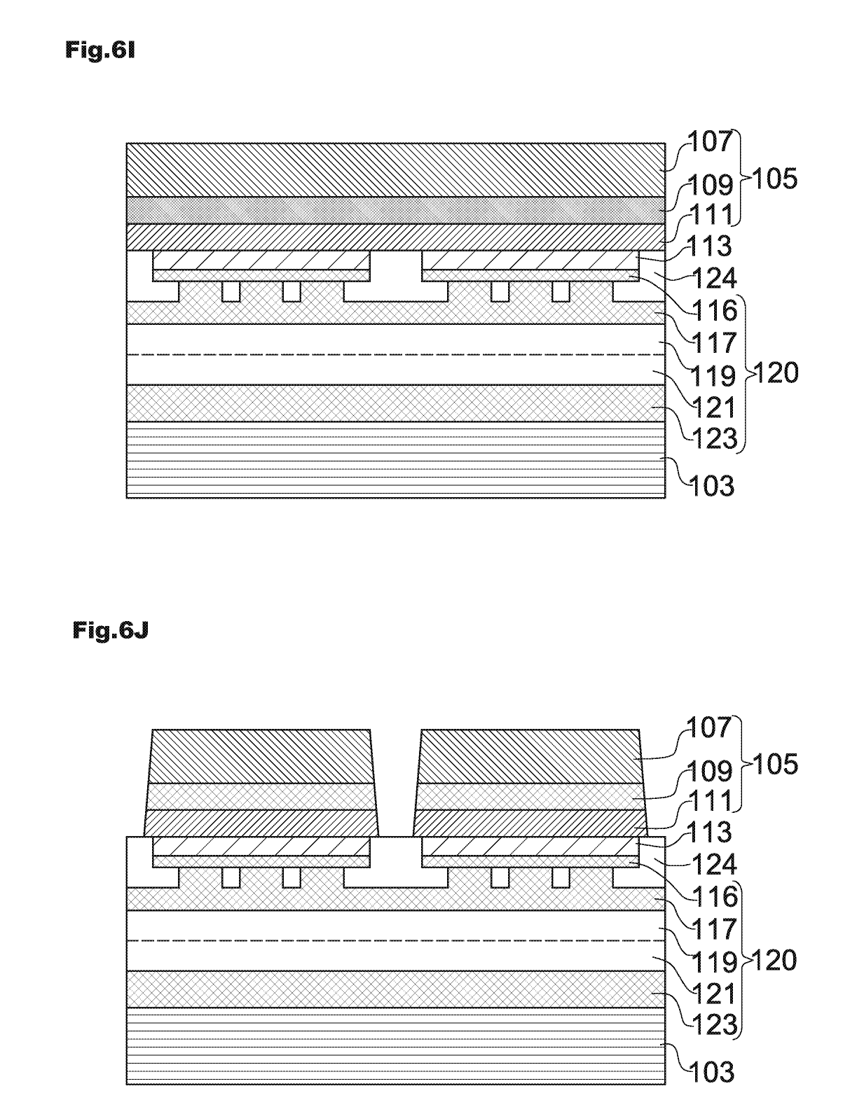

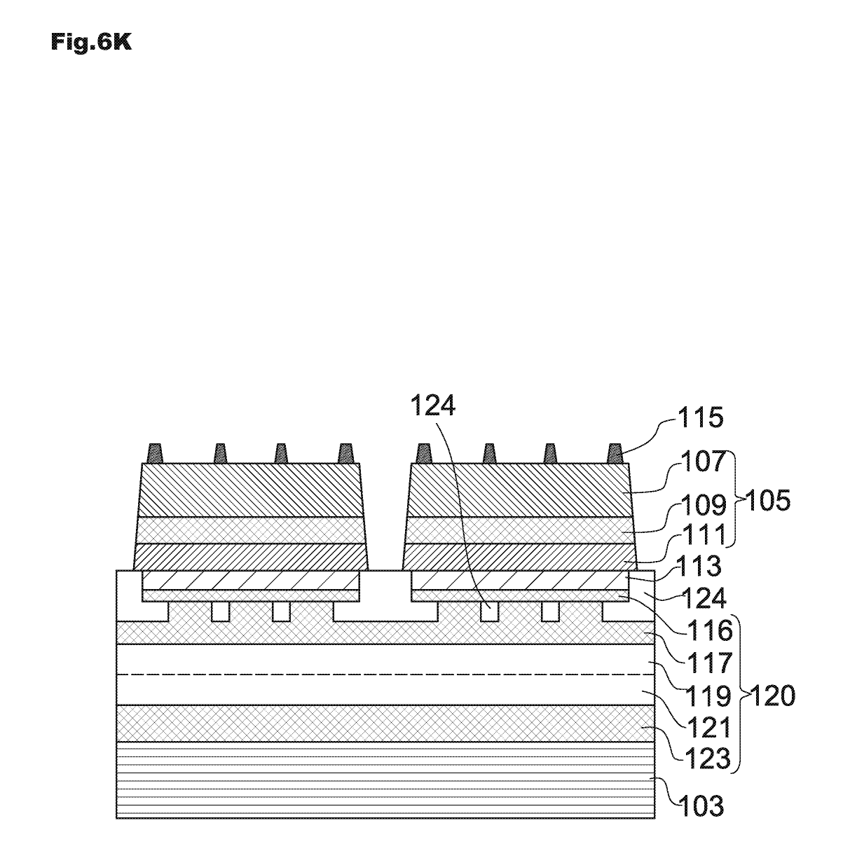

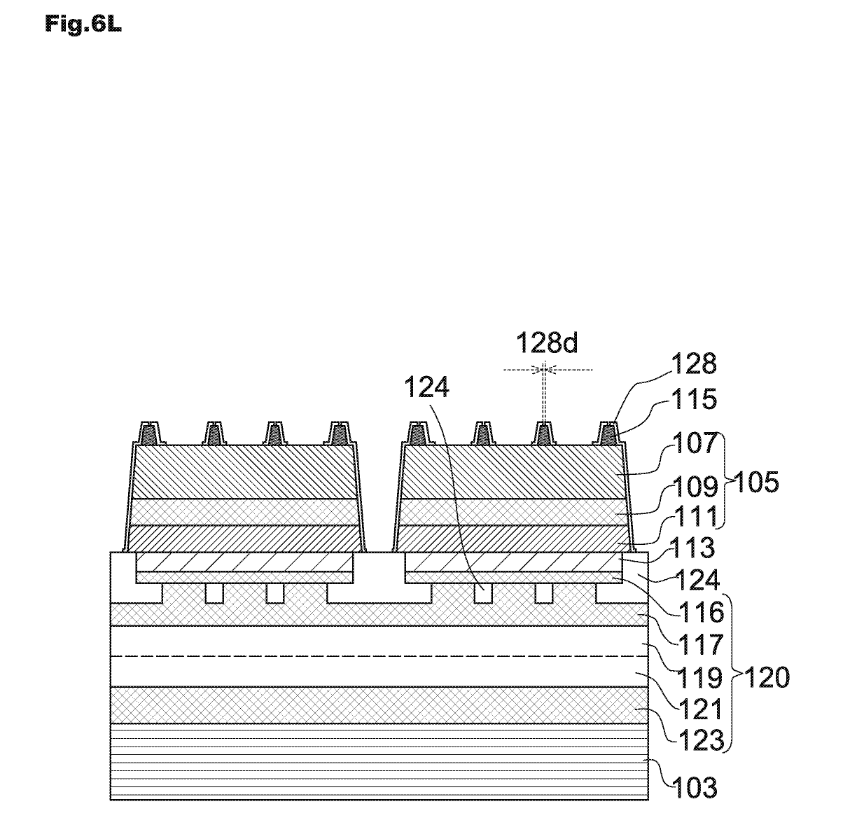

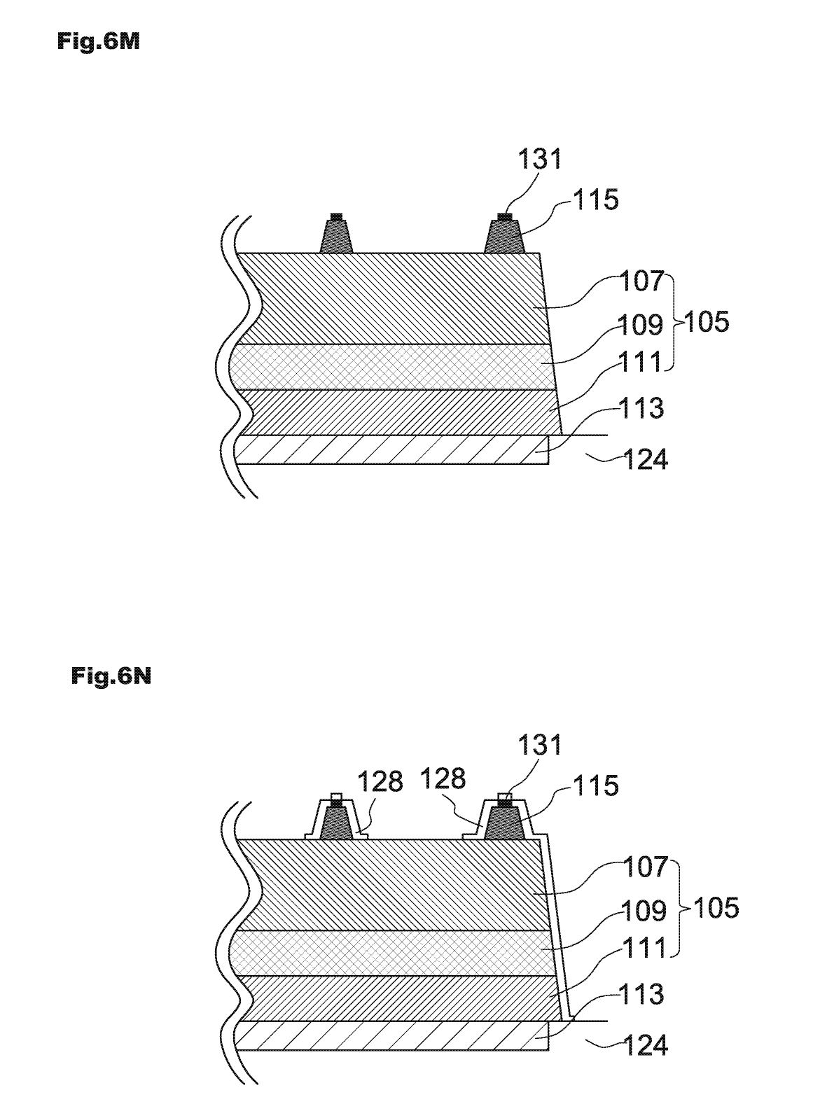

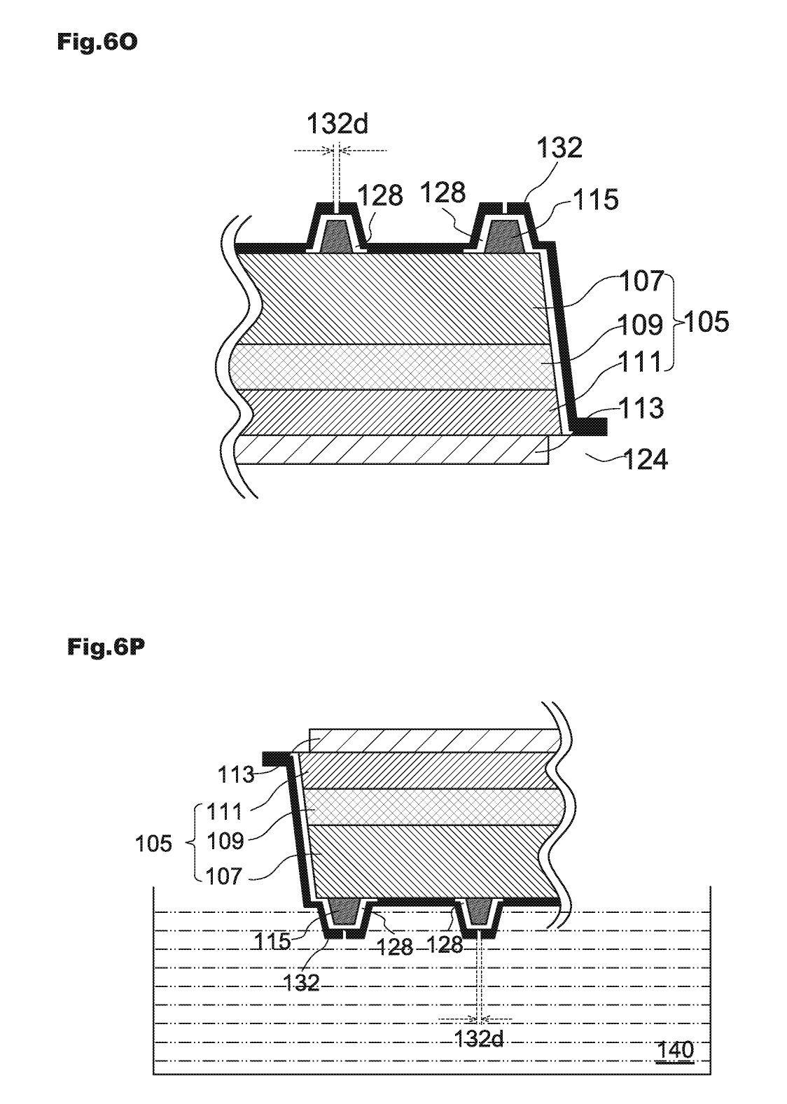

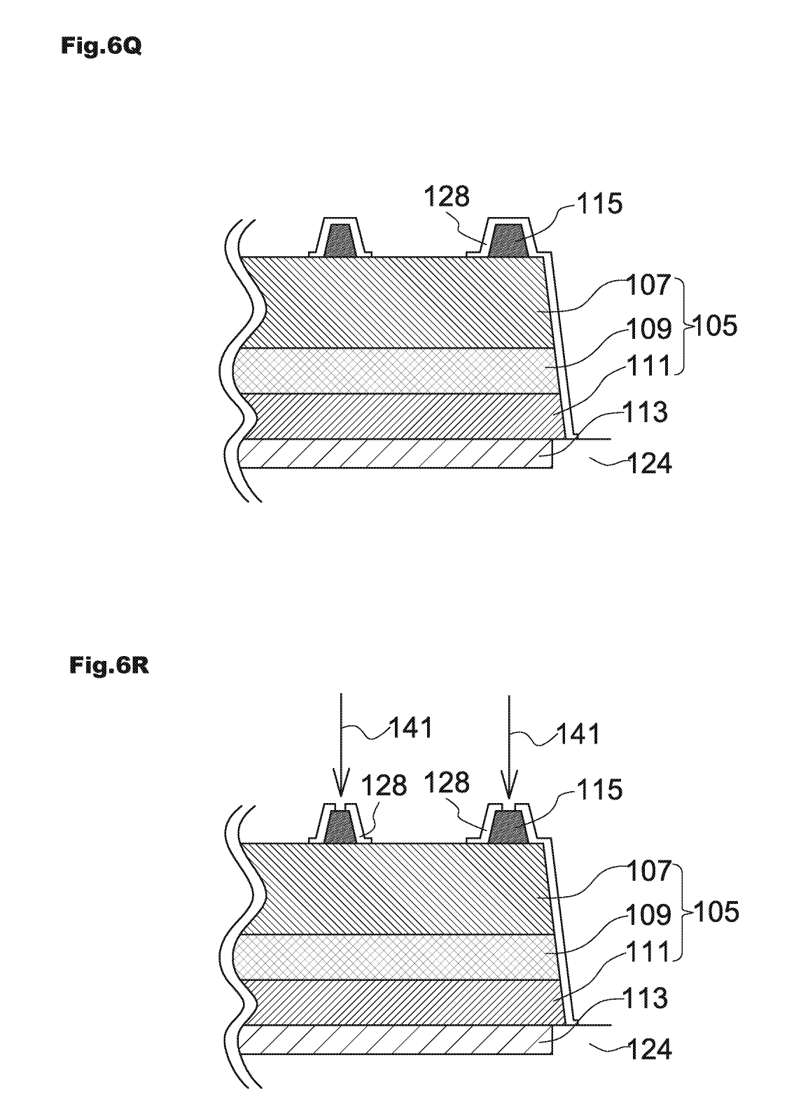

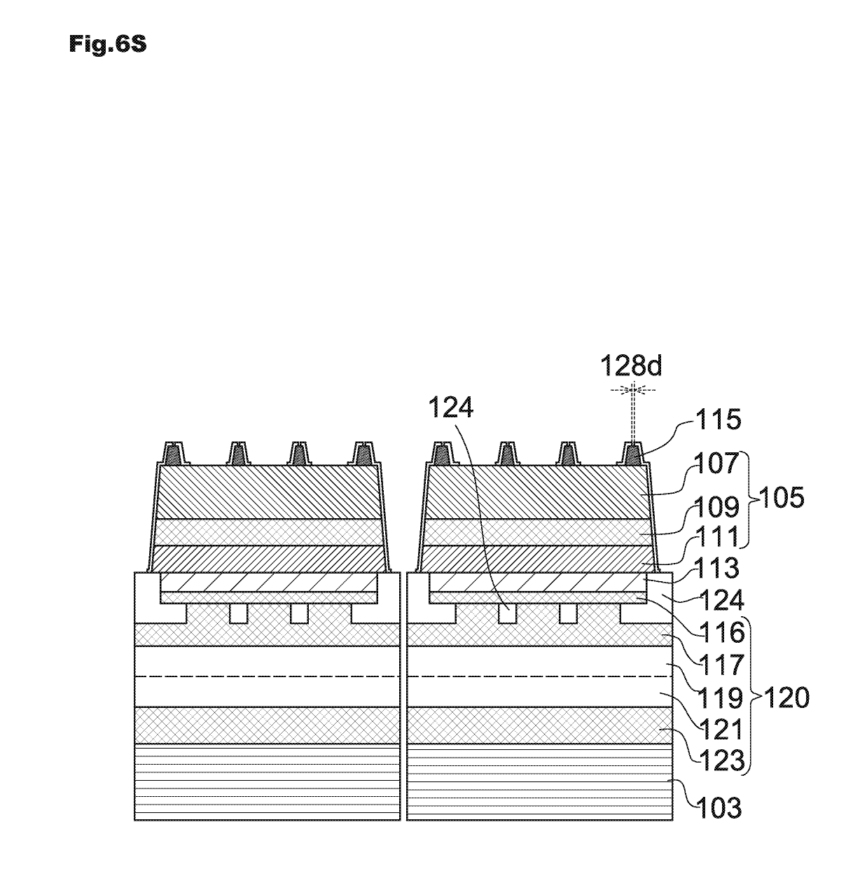

A method for manufacturing the light-emitting device 101 will be described with reference to FIGS. 6A to 6S. It will be understood that the manufacturing conditions and the dimensions such as the thicknesses shown below are by way of example only. Note that FIGS. 6A to 6S referred to below each correspond to a schematic cross-sectional view in the same direction as FIG. 5B.

(Step S21)

As shown in FIG. 6A, a growth substrate 125 is prepared. As an example, the growth substrate 125 may be a C-plane sapphire substrate.

The preparing step includes cleaning the growth substrate 125. A more specific example of the cleaning includes placing the growth substrate 125 in the treatment furnace of a metal organic chemical vapor deposition (MOCVD) system and raising the temperature in the furnace to, for example, 1,150° C. while allowing hydrogen gas to flow at a given rate into the treatment furnace.

The step S21 corresponds to the step (h).

(Step S22)

As shown in FIG. 6B, an underlying layer 127, an n-type semiconductor layer 107, an active layer 109, and a p-type semiconductor layer 111 are sequentially formed on the growth substrate 125. The step S22 is performed, for example, according to the procedures described below.

First, the pressure and temperature in the treatment furnace of the MOCVD system are set to 100 kPa and 480° C. Subsequently, while nitrogen gas and hydrogen gas are allowed to flow as carrier gases at a rate of 5 slm into the treatment furnace, trimethylgallium (TMG) and ammonia are supplied as raw material gases at flow rates of 50 μmol/min and 250,000 μmol/min, respectively, into the treatment furnace for 68 seconds. In this way, a 20-nm-thick, low-temperature buffer layer of GaN is formed on the surface of the growth substrate 125.

Subsequently, the temperature in the treatment furnace of the MOCVD system is raised to 1,150° C. Subsequently, while nitrogen gas and hydrogen gas are allowed to flow as carrier gases at rates of 20 slm and 15 slm, respectively, into the treatment furnace, TMG and ammonia are supplied as raw material gases at flow rates of 100 μmol/min and 250,000 μmol/min, respectively, into the treatment furnace for 30 minutes. In this way, a 1.7-μm-thick, buffer layer of GaN is formed on the surface of the low-temperature buffer layer. These buffer layers form the underlying layer 127.

Subsequently, an n-type semiconductor layer 107 is formed on the underlying layer 127. A specific method of forming the n-type semiconductor layer 107 is, for example, as follows.

First, while the temperature in the treatment furnace of the MOCVD system is still set at 1,150° C., the pressure in the treatment furnace is set to 30 kPa. Subsequently, while nitrogen gas and hydrogen gas are allowed to flow as carrier gases at rates of 20 slm and 15 slm, respectively, into the treatment furnace, TMG, trimethylaluminum (TMA), ammonia, and tetraethylsilane are supplied as raw material gases at flow rates of 94 μmol/min, 6 μmol/min, 250,000 μmol/min, and 0.013 μmol/min, respectively, into the treatment furnace for 60 minutes. In this way, for example, a 2-μm-thick, n-type semiconductor layer 107 with a composition of Al_{0.06}Ga_{0.94}N is formed on the underlying layer 127. When the n-type semiconductor layer 107 includes GaN or AlGaN, the Al content is preferably from 0% to 15%, more preferably from 2% to 11%, even more preferably from 5% to 9%.

Subsequently, an about 5-nm-thick, protective layer of n-type GaN may also be formed on the n-type AlGaN layer by supplying the raw material gases other than TMA for 6 seconds while stopping the supply of TMA, so that the resulting n-type semiconductor layer 107 has the protective layer. As mentioned above, the n-type semiconductor layer 107 preferably has a thickness of 4.5 μm or less, more preferably 4 μm or less, even more preferably 3.5 μm or less.

A case has been described where Si is used as the n-type impurity in the n-type semiconductor layer 107. Besides Si, the n-type impurity may be, for example, Ge, S, Se, Sn, or Te.

An active layer 109 is then formed on the n-type semiconductor layer 107. A specific method of forming the active layer 109 is, for example, as follows.

First, the pressure and temperature in the treatment furnace of the MOCVD system are set to 100 kPa and 830° C. Subsequently, while nitrogen gas and hydrogen gas are allowed to flow as carrier gases at rates of 15 slm and 1 slm, respectively, into the treatment furnace, TMG, trimethylindium (TMI), and ammonia are supplied as raw material gases at flow rates of 10 μmol/min, 12 μmol/min, and 300,000 μmol/min, respectively, into the treatment furnace for 48 seconds. Subsequently, TMG, TMA, tetraethylsilane, and ammonia are supplied at flow rates of 10 μmol/min, 1.6 μmol/min, 0.002 μmol/min, and 300,000 μmol/min, respectively, into the treatment furnace for 120 seconds. These two steps are then repeated to form an active layer 109 including 15 stacks of a 2-nm-thick light-emitting layer of InGaN and a 7-nm-thick barrier layer of n-type AlGaN alternately formed on the n-type semiconductor layer 107.

When the active layer 109 is designed to emit light with a wavelength of 400 nm or less, the In content of InGaN in the light-emitting layer is preferably 10% or less. In this case, the Al content of AlGaN or GaN in the barrier layer is preferably from 0% to 15%, more preferably from 2% to 13%, even more preferably from 5% to 10%.

A p-type semiconductor layer 111 is then formed on the active layer 109. A specific method of forming the p-type semiconductor layer 111 is, for example, as follows.

Specifically, with the pressure in the treatment furnace of the MOCVD system maintained at 100 kPa, the temperature in the treatment furnace is raised to 1,025° C. while nitrogen gas and hydrogen gas are allowed to flow as carrier gases at rates of 15 slm and 25 slm, respectively, into the treatment furnace. Subsequently, TMG, TMA, ammonia, and biscyclopentadienyl magnesium (Cp₂Mg) as a p-type impurity dopant are supplied as raw material gases at flow rates of 35 μmol/min, 20 μmol/min, 250,000 μmol/min, and 0.1 μmol/min, respectively, into the treatment furnace for 60 seconds. In this way, a 20-nm-thick, hole supply layer with a composition of Al_{0.3}Ga_{0.87}N is formed on the surface of the active layer 109. Subsequently, a 120-nm-thick, hole supply layer with a composition of Al_{0.13}Ga_{0.87}N is formed by supplying the raw material gases for 360 seconds, in which the flow rate of TMA is changed to 4 μmol/min. These hole supply layers form the p-type semiconductor layer 111.

After this step, an about 5-nm-thick, p-type GaN layer with a p-type impurity concentration of about 1×10²⁰/cm³ may be formed by supplying the raw material gases other than TMA for 20 seconds, in which the flow rate of Cp₂Mg is changed to 0.2 μmol/min, while stopping the supply of TMA, so that the resulting p-type semiconductor layer 111 has the p-type GaN layer.

A case has been described where Mg is used as the p-type impurity in the p-type semiconductor layer 111. Besides Mg, the p-type impurity may be, for example, Be, Zn, or C.

The step S22 corresponds to the step (i).

(Step S23)

The wafer obtained in the step S22 is subjected to an activation treatment. As a specific example, the activation treatment is performed for 15 minutes in a nitrogen atmosphere using a rapid thermal anneal (RTA) system.

(Step S24)

As shown in FIG. 6C, a second electrode 113 is then formed on a predetermined portion of the upper surface of the p-type semiconductor layer 111. A specific method of forming the second electrode 113 is, for example, as follows.

Using a sputtering system, a 0.7-nm-thick Ni film and a 150-nm-thick Ag film are deposited on a predetermined portion of the upper surface of the p-type semiconductor layer 111. Subsequently, the films are subjected to contact annealing at 400° C. for 2 minutes in a dry air atmosphere using the RTA system. The second electrode 113 may be made of, for example, a Ni—Ag alloy or an alloy of Cu, Pd, and Al, Rh, or Ag.

The step S24 corresponds to the step (j).

(Step S25)

As shown in FIG. 6C, an anti-diffusion layer 116 is formed on the upper surface of the second electrode 113. For example, the anti-diffusion layer 116 is formed by depositing an 80-nm-thick Ni film, a 100-nm-thick Ti film, and a 200-nm-thick Pt film using an electron beam vapor deposition system (EB system). Besides Ni/Ti/Pt, the anti-diffusion layer 116 may be made of TiW/Pt or other materials. It is optional whether or not the step S25 is performed.

(Step S6)

As shown in FIG. 6D, a current blocking layer 124 is formed on the exposed upper surface of the p-type semiconductor layer 11 and on a predetermined region of the upper surface of the anti-diffusion layer 116. The current blocking layer 124 is formed, for example, by depositing a film of SiO₂, SiN, Zr₂O₃, AlN, or Al₂O₃ by sputtering or other methods.

In the step S26, the current blocking layer 124 is formed at a position facing, in the Z direction, a region where the first electrode 115 is to be formed in a later step.

(Step S27)

As shown in FIG. 6E, an anti-diffusion layer 117 is formed over the upper surfaces of the anti-diffusion layer 116 and the current blocking layer 124, and then, the bonding layer 119 is formed on the upper surface of the anti-diffusion layer 117. The anti-diffusion layer 117 is formed by the same method as that for the anti-diffusion layer 116. For example, the anti-diffusion layer 117 is formed as a multi-layered structure by alternately depositing Ti and Pt using an electron beam vapor deposition system (EB system). Subsequently, a bonding layer 119 is formed by vapor-depositing, on the upper surface of the anti-diffusion layer 117, a 10-nm-thick Ti film and then a 3-μm-thick Au—Sn solder film composed of 80% Au and 20% Sn. Besides the Au—Sn solder, the bonding layer 19 may be made of Au—In, Au—Cu—Sn, Cu—Sn, Pd—Sn, Sn, or other solder materials. It is optional whether or not the anti-diffusion layer 117 is provided.

(Step S28)

As shown in FIG. 6F, an anti-diffusion layer 123 and a bonding layer 121 are formed on the upper surface of a substrate 103 (support substrate 103) prepared separately from the growth substrate 125. As mentioned above, the substrate 103 may be a conductive substrate such as CuW, W, or Mo or a semiconductor substrate such as Si. The anti-diffusion layer 123 may be formed similarly to the anti-diffusion layer 117, and the bonding layer 121 may be formed similarly to the bonding layer 119. It is optional whether or not the anti-diffusion layer 123 is provided.

(Step S29)

As shown in FIG. 6G, the bonding layer 119 formed on the growth substrate 125 is bonded to the bonding layer 121 formed on the substrate 103, so that the growth substrate 125 is bonded to the substrate 103. As a specific example, the bonding is performed at a temperature of 280° C. under a pressure of 0.2 MPa.

In this step, the bonding layers 119 and 121 are melted and bonded together to form a structure in which the substrate 103 and the growth substrate 125 are bonded on the front and back sides. Therefore, after this step, the bonding layers 119 and 121 may be handled as an integrated part. The diffusion of the material in the bonding layer (119, 121) is suppressed by the protective layers 123 and 117 formed at the stage before the step S29 is performed.

The step S29 corresponds to the step (k).

(Step S30)

As shown in FIG. 6H, the growth substrate 125 is separated. More specifically, laser light is applied from the growth substrate 125 side. In this step, the applied laser light has a wavelength transmittable through the material in the growth substrate 125 (sapphire in this embodiment) and absorbable by the material in the underlying layer 127 (GaN in this embodiment). Thus, the laser light is absorbed by the underlying layer 127 to increase the temperature of the interface between the growth substrate 125 and the underlying layer 127, so that the decomposition of GaN occurs to cause the separation of the growth substrate 125.

Subsequently, after metallic Ga remaining on the wafer is removed using hydrochloric acid or the like, GaN (underlying layer 127) is removed by dry etching using an ICP system, so that the n-type semiconductor layer 107 is exposed. In the step S30, the underlying layer 127 is removed, and semiconductor layers 105 are left, which include the p-type semiconductor layer 111, the active layer 109, and the n-type semiconductor layer 107 stacked in this order from the substrate 103 side (see FIG. 6I).

The step S30 corresponds to the step (1).

(Step S31)

As shown in FIG. 6J, adjacent devices are separated from each other. Specifically, using the ICP system, the semiconductor layers 105 are etched at the boundary region between adjacent devices until the upper surface of the current blocking layer 124 is exposed. In this step, the current blocking layer 124 functions as an etching stopper layer. FIG. 6J shows that the semiconductor layers 105 have a side surface inclined with respect to the vertical direction. It will be understood that such a shape is merely an example and not intended to be limiting.

(Step S32)

As shown in FIG. 6K, a conductive material is vapor-deposited on a predetermined region of the upper surface of the n-type semiconductor layer 107 to form a first electrode 115. In this step, the first electrode 115 is formed in a region being perpendicular along the Z direction (the direction perpendicular to the surface of the substrate 103) to the current blocking layer 124.

A specific method of forming the first electrode 115 is, for example, as follows.

First, a resist mask is formed on a predetermined region of the upper surface of the n-type semiconductor layer 107 and on the side surface of the semiconductor layers 105. The resist mask is provided with openings at regions where the first electrode 115 is to be formed. A material or materials for the first electrode 115 are then deposited on the upper surface of the resist mask and on the exposed portions of the upper surface of the n-type semiconductor layer 107, which are exposed through the openings of the resist mask. Specifically, for example, a stack of conductive materials Ni/Al/Ni/Ti/Au is formed, for example, with a thickness of about 3 μm by vapor deposition using an electron beam vapor deposition system. Subsequently, the resist mask is separated, so that the first electrode 115 is formed on the predetermined portion of the upper surface of the n-type semiconductor layer 107. As described above with reference to FIG. 5A, the first electrode 115 as formed has an outer edge in the shape of a frame.

The step S32 corresponds to the step (m).

(Step S33)

As shown in FIG. 6L, a protective layer 128 is formed to extend from a first position on the upper surface of the n-type semiconductor layer 107 to a second position on a part of the upper surface of the first electrode 115, in which the first position is outside the first electrode 115. In this step, the protective layer 128 is formed to have openings 128d through which the upper surface of the first electrode 115 is partially exposed. The step S33 corresponds to the step (n). In this step, an adhesion promoter layer including Ti or other materials may be formed on the side and upper surfaces of the first electrode 115 before the protective layer 128 is formed.

This step may be performed using any of various methods.

(First Method)

As shown in FIG. 6M, a resist mask 131 is formed on regions of the upper surface of the first electrode 115, in which the regions correspond to the openings 128d to be formed. As shown in FIG. 6N, the protective layer 128 is then formed on regions including the upper surface of the resist mask 131. Subsequently, the resist mask 131 is separated so that the structure shown in FIG. 6L is obtained.

(Second Method)

As shown in FIG. 6O, the protective layer 128 is formed on regions including the entire upper surface of the first electrode 115. A resist mask 132 having openings 132d is then formed on the upper surface of the protective layer 128, in which the openings 132d correspond to the regions where the openings 128d (see FIG. 6L) are to be formed.

As shown in FIG. 6P, the wafer is then immersed in a solution 140 capable of dissolving the material of the protective layer 128. For example, when the protective layer 128 is made of SiO₂, a hydrogen fluoride aqueous solution, an ammonium fluoride aqueous solution, or the like may be used as the solution 140. In this step, the regions not covered with the resist mask 132, namely, the exposed portions of the protective layer 128 through the openings 132d are only removed. Subsequently, the resist mask 132 is separated so that the structure shown in FIG. 6L is obtained.

(Third Method)

Similarly to the second method, as shown in FIG. 6Q, the protective layer 128 is formed on regions including the entire upper surface of the first electrode 115. Subsequently, regions of the protective layer 128, where the openings 128d (see FIG. 6L) are to be formed, are removed by a laser ablation technique in which laser light 141, for example, with a wavelength of 266 nm, 193 nm, or 157 nm is applied to the regions (see FIG. 6R). This results in the structure shown in FIG. 6L.

(Step S34)

As shown in FIG. 6S, the wafer is divided into chip units. As a specific example, the devices are separated from one another using a laser dicer.

Subsequently, the back surface of the substrate 103 is bonded to a package, for example, with a Ag paste, and current supply wires 114 are connected to the current supply portions 115a. For example, current supply wires 114 of Au are connected to the current supply portions 115a of 100 μmφ by wire bonding under a load of 50 g. Thus, the light-emitting device 1 shown in FIGS. 5A to 5B is obtained.

[Verification]

Hereinafter, the invention will be described with reference to examples and reference examples. Note that all light-emitting devices below have a peak emission wavelength of 365 nm and the upper surface of the first electrode 115 (the surface opposite to the n-type semiconductor layer 107) has a width of 20 μm.

### EXAMPLES

The light-emitting device of each example corresponding to the light-emitting device 101 described above was manufactured through the steps S21 to S34. Examples 2-1 to 2-5 differ in the width of the openings 128d of the protective layer 128 formed in the step S33. Specifically, they differ as follows.

Example 2-1: Openings 128d with a width of 14 to 16 μm
Example 2-2: Openings 128d with a width of 10 to 12 μm
Example 2-3: Openings 128d with a width of 6 to 8 μm
Example 2-4: Openings 128d with a width of 2 to 4 μm
Example 2-5: Openings 128d with a width of 1 to 2 μm

### Reference Example 2-1

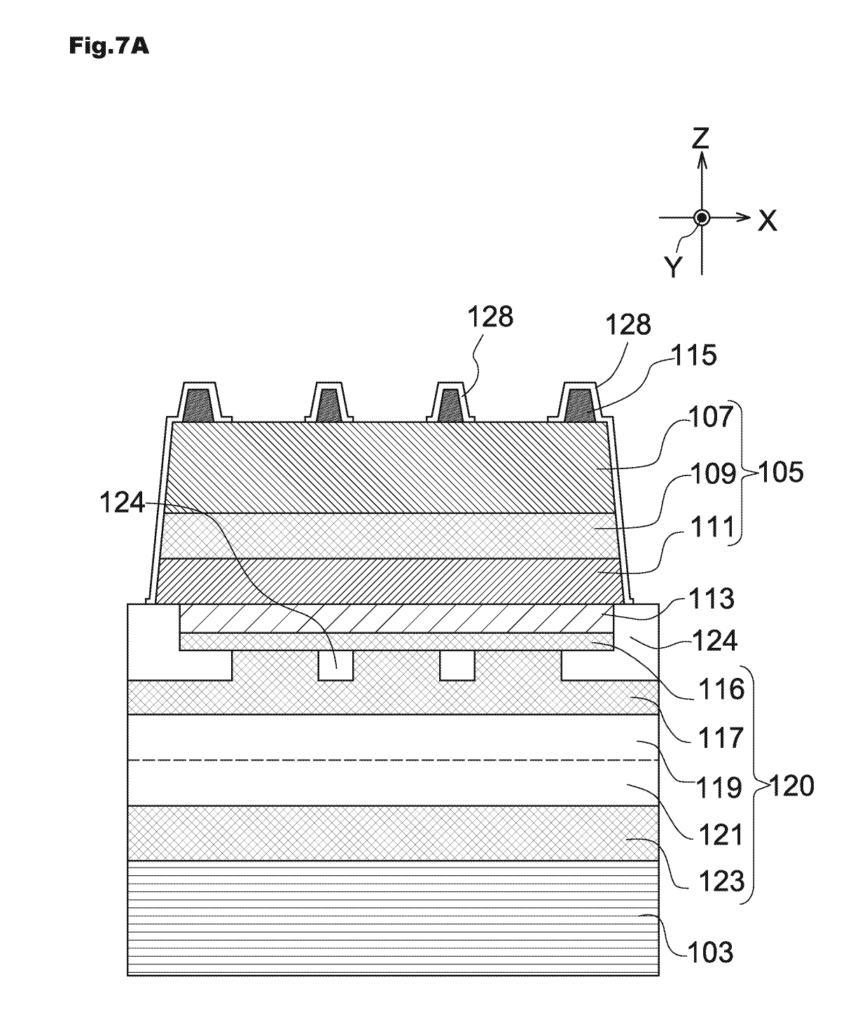

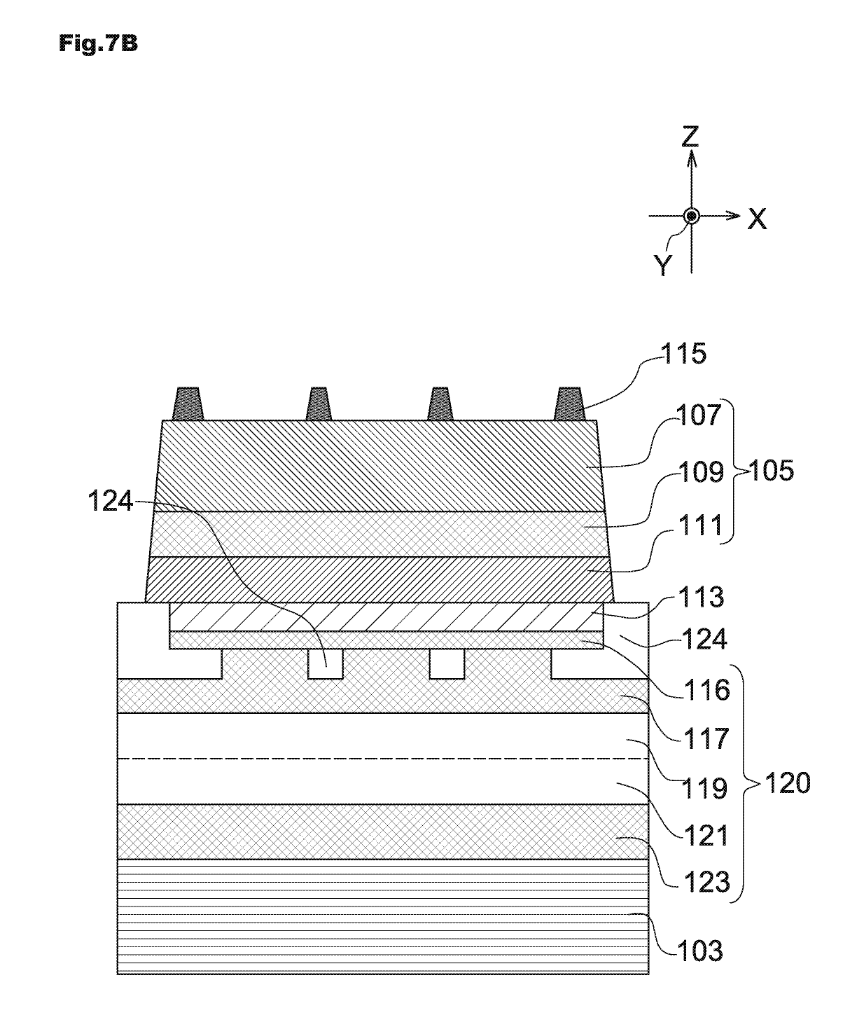

The light-emitting device of Reference Example 2-1 was manufactured using the same process, except that the protective layer 128 was formed without the openings 128d in the step S33. FIG. 7A is a schematic cross-sectional view showing the light-emitting device of Reference Example 2-1.

### Reference Example 2-2

The light-emitting device of Reference Example 2-2 was manufactured using the same process, except that the step S33 was not performed. FIG. 7B is a schematic cross-sectional view showing the light-emitting device of Reference Example 2-2.

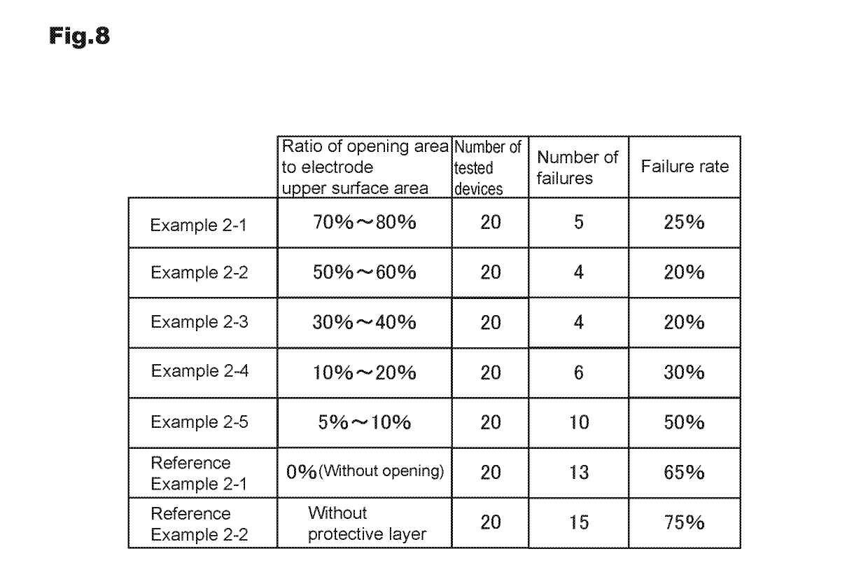

Each of the light-emitting devices of Examples 2-1 to 2-5 and Reference Examples 2-1 to 2-2 with their packages each mounted on an aluminum board was subjected to an intermittent lighting test in which each light-emitting device was repeatedly turned on for 2 hours at a current of 0.7 A and off for 1 hour in an environment at a temperature of 85° C. and a relative humidity of 85%. FIG. 8 shows the results obtained after a total lighting time of 1,000 hours.

FIG. 8 shows that the failure rate is the highest for Reference Example 2-2 in which the protective layer 128 is not formed. It is also apparent that even with the protective layer 128, light-emitting devices without the openings 128d, such as the light-emitting device of Reference Example 2-1, show a failure rate higher than that for those of Examples 2-1 to 2-5. The cross-sections of the burned-out light-emitting devices were subjected to observation with a scanning electron microscope (SEM) and analysis by energy dispersive X-ray spectrometry (EDS). As a result, the Ag material used to form the second electrode 113 was detected in the vicinity of the first electrode 115.

The results shown in FIG. 8 indicate that migration is most likely to occur in light-emitting devices without the protective layer 128, such as the light-emitting device of Reference Example 2-2, as compared with other devices with the protective layer 128. In some burned-out light emitting devices of Reference Example 2-1, cracks were observed in the protective layer 128. This suggests that water and oxygen could flow into the semiconductor layers 105 from the air through cracks to facilitate the migration.

In contrast, the failure rate for the light-emitting device of each example is lower than that for the light-emitting device of Reference Example 2-1. This suggests that the openings 128d provided in the protective layer 128 should be effective in suppressing the cracking of the protective layer 128. It can be speculated that when the first electrode 115 is completely covered with the protective layer 128, repeated turning on and off can cause a large stress on the protective layer 128 due to the difference in thermal expansion coefficient between the first electrode 115 and the protective layer 128, so that the protective layer 128 can crack eventually. It can also be speculated that in contrast, when the openings 128d are provided in the protective layer 128, as in the light-emitting device of each example, the stress can be released between the protective layer 128 and the first electrode 115, so that the light-emitting device of each example can have better life characteristics than the device of Reference Example 2-2.

In addition, the results in FIG. 8 indicate that the ratio of the width of the openings 128d to the width of the upper surface of the first electrode 115 is preferably 10% or more, more preferably from 30% to 80%, even more preferably from 30% to 60%. It can be speculated that this is because if the width of the openings 128d is too narrow, the stress would not be so effectively released, and contrarily, if the width of the openings 128d is too wide, water can easily flow into the electrode from the air to interfere with the sufficient functioning of the protective layer 128.

[Other Modes]

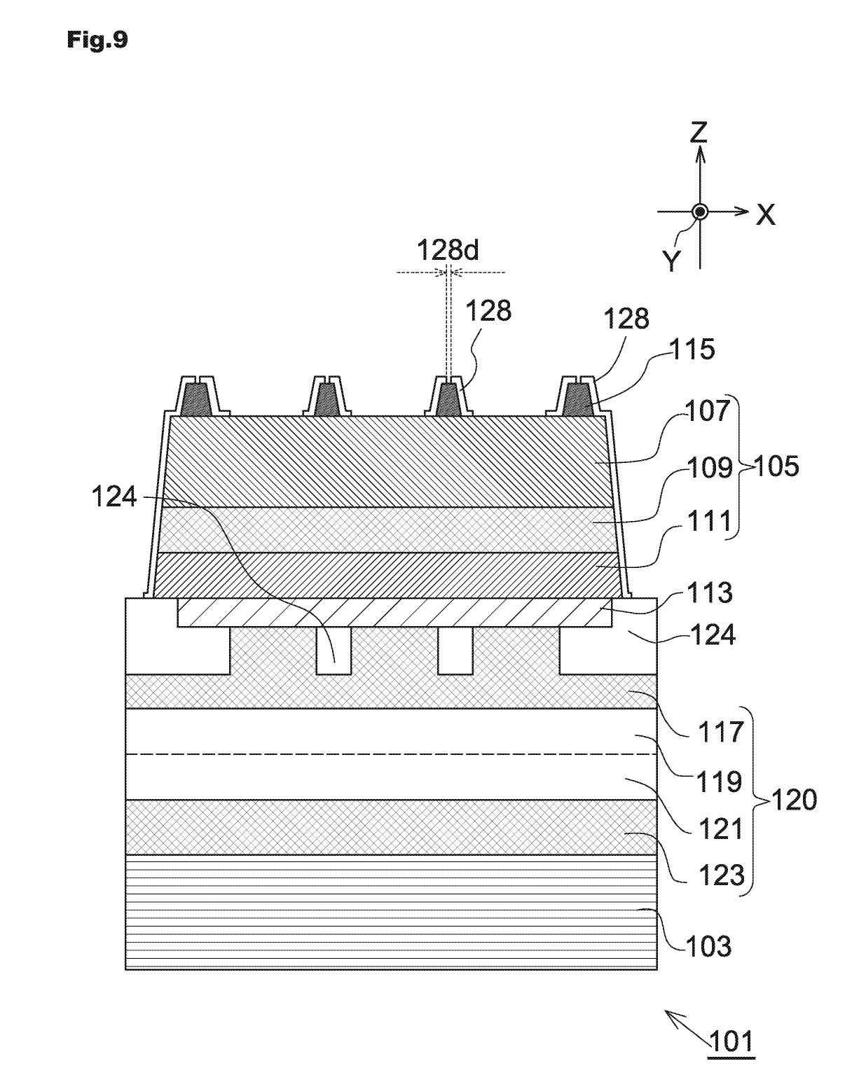

Hereinafter, other modes of the second embodiment will be described.

<1> As mentioned above, it is optional whether or not the light-emitting device 101 has the anti-diffusion layer 116. FIG. 9 is a cross-sectional view schematically showing the light-emitting device 101 without the anti-diffusion layer 116. In this case, the current blocking layer 124 is in direct contact with the opposite surface of the second electrode 113 from the p-type semiconductor layer 111.

The light-emitting device 101 may also be configured to work without the anti-diffusion layer 117. However, the anti-diffusion layer (116, 117) can prevent the reduction of the reflectance of the second electrode 113. To maintain the light extraction efficiency at a high level, therefore, the light-emitting device 101 should preferably have the anti-diffusion layer (116, 117).

<2> In the embodiment described above, the current blocking layer 124 is provided on the opposite surface of the second electrode 113 from the p-type semiconductor layer 111, and located at a position facing the first electrode 115 in a direction perpendicular to the Z direction. Alternatively, the current blocking layer 124 may be provided on the p-type semiconductor layer 111-side surface of the second electrode 113. In this case, the current blocking layer 124 may include an insulating layer made of a specific material, or may include the same material as the second electrode 113 and form a Schottky contact at the interface with the p-type semiconductor layer 111.

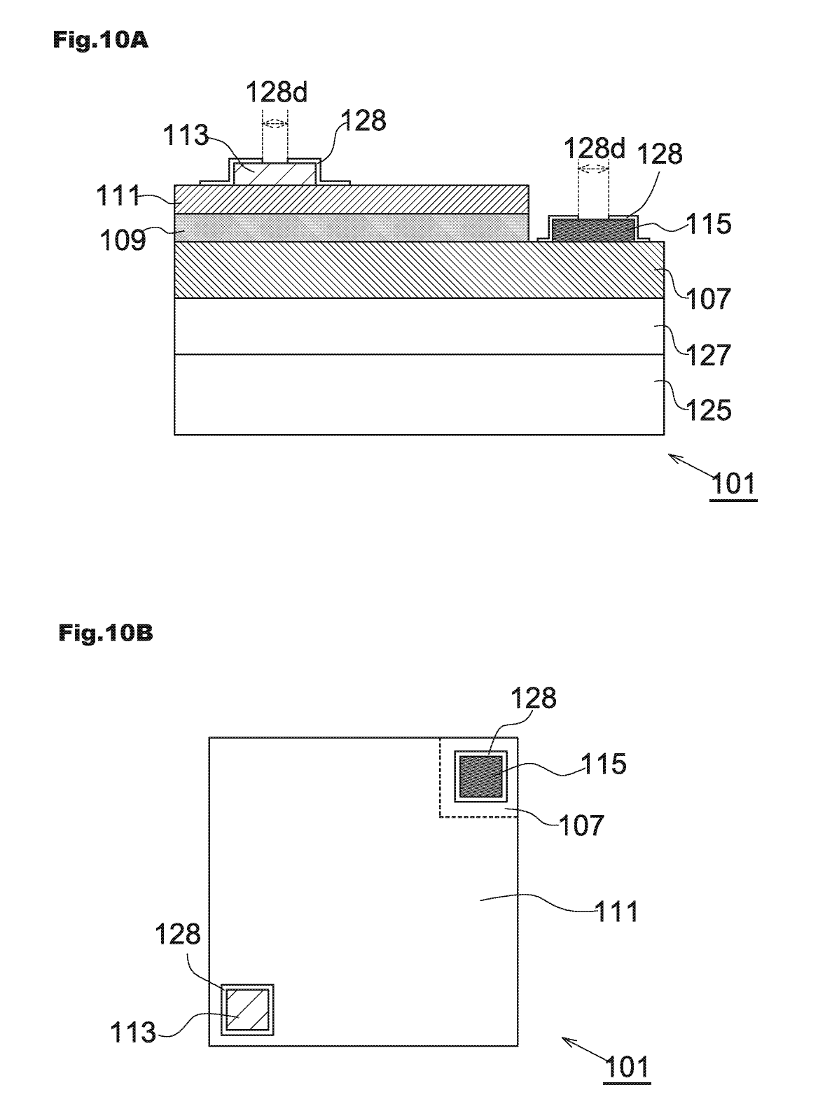

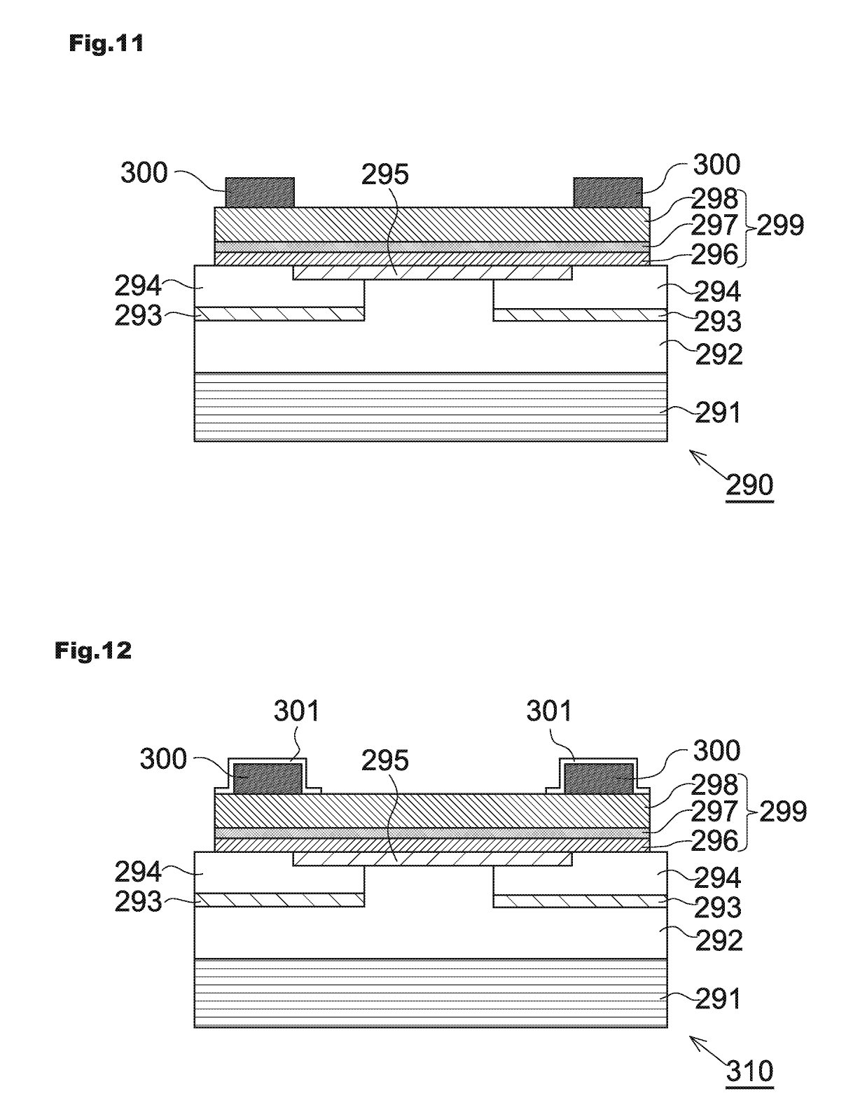

Moreover, the light-emitting device 101 does not necessarily have the current blocking layer 124. Preferably, however, the current blocking layer 124 should be provided in order to allow the current flowing through the active layer 109 to propagate in directions parallel to the X-Y plane so that the luminance efficiency can be increased.

<3> In the light-emitting device 101 shown in FIG. 5B, the upper surface of the n-type semiconductor layer 107 may have a roughened portion. Such a feature helps to further increase the light extraction efficiency.

<4> Among the layers constituting the semiconductor layers 105 in the embodiment described above, the p-type semiconductor layer 111 is proximal to the substrate 103 whereas the n-type semiconductor layer 107 is distal to the substrate 103. Alternatively, these conductivity types may be reversed.

<5> In the embodiment described above, the light-emitting device 101 has what is called a vertical structure, in which the first and second electrodes 115 and 113 are formed in such a positional relationship that they are opposed in the Z direction to each other with the active layer 109 in between them. Alternatively, the light-emitting device 101 may have what is called a horizontal structure in which the first and second electrodes 115 and 113 are formed on the same side with respect to the active layer 109. FIGS. 10A and 10B are views schematically showing another structure of the semiconductor light-emitting device 101. FIG. 10A corresponds to a cross-sectional view, and FIG. 10B corresponds to a plan view. Also in this device, a protective layer 128 is formed to extend from a first position on the upper surface of the n-type semiconductor layer 107 to a second position on the outside surface of the first electrode 115, in which the first position is outside the first electrode 115. In this device, another protective layer 128 is also formed to extend from a first position on the upper surface of the p-type semiconductor layer 111 to a second position on the outside surface of the second electrode 113, in which the first position is outside the second electrode 113. Each protective layer 128 also has an opening 128d. Alternatively, the protective layer 128 may be provided only on the n- or p-side.

To form this structure, the steps described below should be performed after the steps S21 to S23.

(Step S41)

The p-type semiconductor layer 111 formed on a partial region and the active layer 109 are etched until the upper surface of the n-type semiconductor layer 107 is exposed.

(Step S42)

The second electrode 113 is formed on a predetermined region of the upper surface of the p-type semiconductor layer 111, and the first electrode 115 is formed on a predetermined region of the exposed upper surface of the n-type semiconductor layer 107. In this structure, the second electrode 113 may be made of the same material as the first electrode 115.

Subsequently, using the same method as in the step S33, the protective layer 128 is formed to extend from a first position on the upper surface of n-type semiconductor layer 107 to a second position on a part of the upper surface of the first electrode 115, in which the first position is outside the first electrode 115. When the device with the structure shown in FIG. 10A is manufactured, the protective layer 128 may also be formed to extend from a first position on the upper surface of p-type semiconductor layer 111 to a second position on a part of the upper surface of the second electrode 113, in which the first position is outside the second electrode 113. In this process, the openings 128d may also be formed using any one of the first, second, and third methods described above for the step S33.

### DESCRIPTION OF REFERENCE SIGNS

1: semiconductor light-emitting device according to a first embodiment
3: substrate
5: semiconductor layer
7: n-type semiconductor layer
7a: roughened surface portion
7b: smooth surface portion
9: active layer
11: p-type semiconductor layer
13: second electrode
13B: tapered shape
14: current supply wire
15: first electrode
15a: current supply portion
15d: width of the first electrode
16: protective layer
17: protective layer
19: bonding layer
20: conductive layer
21: bonding layer
23: protective layer
24: current blocking layer
25: growth substrate
27: underlying layer
31: resist mask
31d: width of the resist mask 31
33: resist mask
33d: width of the resist mask 33
51: light-emitting device of Reference Example 1-1
52: light-emitting device of Reference Example 1-2
101: semiconductor light-emitting device according to a second embodiment
103: substrate
105: semiconductor layer
107: n-type semiconductor layer
109: active layer
111: p-type semiconductor layer
113: second electrode
114: current supply wire
115: first electrode
115a: current supply portion
116: anti-diffusion layer
117: anti-diffusion layer
119: bonding layer
120: conductive layer
121: bonding layer
123: anti-diffusion layer
124: current blocking layer
125: growth substrate
127: underlying layer
128: protective layer
128d: opening of protective layer 128
131: resist mask
132: resist mask
132d: opening of resist mask 132
140: solution
141: laser light
290: conventional semiconductor light-emitting device
291: substrate
292: conductive layer
293: reflective film
294: insulating layer
295: reflective electrode
296: p-type semiconductor layer
297: active layer
298: n-type semiconductor layer
299: semiconductor layers
300: n-side electrode
301: protective layer
310: light-emitting device

What is claimed is:

1. A semiconductor light-emitting device comprising:
a substrate;
semiconductor layers formed on the substrate and including an n-type or p-type first semiconductor layer, an active layer, and a second semiconductor layer of a conductivity type different from that of the first semiconductor layer;
a first electrode formed in contact with an opposite surface of the first semiconductor layer from the active layer; and
a second electrode that is in contact with an opposite surface of the second semiconductor layer from the active layer and formed in a region including a position facing the first electrode in a direction perpendicular to a surface of the substrate, wherein
the opposite surface of the first semiconductor layer from the active layer comprises a smooth surface portion and a roughened surface portion,
the smooth surface portion is provided in a region where the first electrode is formed,
the roughened surface portion is provided at least in a part of a region where the first electrode is not formed, and
the second semiconductor layer and the second electrode are in contact with each other at a position outside an outer edge of the first electrode.

2. The semiconductor light-emitting device according to claim 1, wherein one of surfaces of the second electrode is entirely in contact with the second semiconductor layer.

3. The semiconductor light-emitting device according to claim 1, wherein the opposite surface of the first semiconductor layer from the active layer has a smooth surface portion in a region outside an outer edge of the first electrode.

4. The semiconductor light-emitting device according to claim 1, wherein the second electrode has an outer edge located outside the outer edge of the first electrode and inside an outer edge of the semiconductor layers.

5. The semiconductor light-emitting device according to claim 1, wherein the second electrode has an outer edge in a knife edge shape.

6. The semiconductor light-emitting device according to claim 1, further comprising a current blocking layer formed at a position facing the first electrode in a direction perpendicular to the surface of the substrate,
the current blocking layer being in direct contact with an opposite surface of the second electrode from the second semiconductor layer or being attached to the opposite surface of the second electrode with another conductive layer interposed between the current blocking layer and the second electrode.

7. The semiconductor light-emitting device according to claim 1, wherein the outer edge of the first electrode has a frame shape when viewed in a direction perpendicular to the surface of the substrate.

8. The semiconductor light-emitting device according to claim 1, wherein the active layer comprises a nitride semiconductor capable of emitting light with a peak wavelength of 400 nm or less.

9. The semiconductor light-emitting device according to claim 1, wherein the semiconductor layers have a thickness of 5 μm or less.

10. A method for manufacturing the semiconductor light-emitting device according to claim 1, the method comprising the steps of:
(a) preparing a growth substrate;
(b) forming semiconductor layers on the growth substrate, the semiconductor layers including an n-type or p-type first semiconductor layer, an active layer, and a second semiconductor layer of a conductivity type different from that of the first semiconductor layer;
(c) forming a second electrode on an upper surface of the second semiconductor layer;
(d) bonding a support substrate to an upper part of the second electrode with a bonding layer interposed between the support substrate and the second electrode, wherein the support substrate is independent of the growth substrate;
(e) separating the growth substrate to expose the first semiconductor layer;
(f) processing an exposed surface of the first semiconductor layer to form a roughened surface portion and a smooth surface portion;
(g) forming a first electrode on a part of the smooth surface portion of the surface of the first semiconductor layer, wherein
in the step (g), the first electrode is formed in such a manner that a material used to form the first electrode is prevented from flowing into the roughened surface portion.

11. The method according to claim 10, wherein the step (g) comprises the steps:
(g1) preparing a resist mask having an opening region with an opening area smaller than the area of the smooth surface portion;
(g2) forming the resist mask on an upper surface of the first semiconductor layer while a partial region of the smooth surface portion is exposed through the opening region;
(g3) depositing a conductive material on an upper surface of the resist mask and on an upper surface of the first semiconductor layer exposed through the opening region, wherein the conductive material is for forming the first electrode; and
(g4) removing the resist mask to form the first electrode on a part of the smooth surface portion.

12. The method according to claim 10, wherein in the step (c), the second electrode is formed in such a manner that the second electrode and an upper surface of the second semiconductor layer are in contact with each other at a position inside an outer edge of the second semiconductor layer.

13. The method according to claim 12, wherein in the step (f), the surface is processed in such a manner that the exposed surface of the first semiconductor layer has the smooth surface portion at least in a region adjacent to an outer edge of the first semiconductor layer.

14. The method according to claim 12, wherein in the step (g), the first electrode is formed at a position inside a position where the second semiconductor layer is in contact with the second electrode.

15. The method according to claim 12, wherein in the step (c), the second electrode is formed to have an outer edge in a knife edge shape.

16. The method according to claim 12, wherein in the step (g), the first electrode is formed to have an outer edge in a frame shape when viewed in a direction perpendicular to a surface of the support substrate.

17. The method according to claim 10, wherein the active layer formed in the step (b) comprises a nitride semiconductor capable of emitting light with a peak wavelength of 400 nm or less.

18. The method according to claim 10, wherein in the step (b), the semiconductor layers are formed to have a thickness of 5 μm or less.

19. A semiconductor light-emitting device comprising:
a substrate;
semiconductor layers formed on the substrate and including an n-type or p-type first semiconductor layer, an active layer, and a second semiconductor layer of a conductivity type different from that of the first semiconductor layer;
a first electrode formed in contact with an opposite surface of the first semiconductor layer from the active layer; and
a protective layer comprising a material with a thermal expansion coefficient lower than that of the first electrode and formed in contact with an outside surface of the first electrode, wherein
the protective layer is formed on an outside surface of the first electrode, the outside surface including an end where the first electrode is in contact with the first semiconductor layer, and
at least a part of an upper surface of the first electrode is not covered with the protective layer.

20. The semiconductor light-emitting device according to claim 19, wherein the protective layer is formed to reach a part of an upper surface of the first electrode through the outside surface of the first electrode.

21. The semiconductor light-emitting device according to claim 19, wherein
the first electrode is formed to extend in a predetermined direction on a surface of the first semiconductor layer, and
the protective layer is formed along the predetermined direction and in contact with the outside surface of the first electrode.

22. The semiconductor light-emitting device according to claim 21, wherein
the protective layer covers a part of the upper surface of the first electrode, and
the first electrode has an exposed surface not covered with the protective layer, the exposed surface having a slit shape along the predetermined direction.

23. The semiconductor light-emitting device according to claim 22, wherein the slit-shaped, exposed surface of the first electrode has a width that is 10% or more of the width of the first electrode extending along the predetermined direction.

24. The semiconductor light-emitting device according to claim 19, wherein the first electrode comprises a material including Au.

25. The semiconductor light-emitting device according to claim 19, further comprising:
a second electrode formed in contact with an opposite surface of the second semiconductor layer from the active layer; and
a current blocking layer formed at a position facing the first electrode in a direction perpendicular to a surface of the substrate, the current blocking layer being in direct contact with an opposite surface of the second electrode from the second semiconductor layer or being attached to the opposite surface of the second electrode with another conductive layer interposed between the current blocking layer and the second electrode, wherein
one of surfaces of the second electrode is entirely in contact with the second semiconductor layer.

26. The semiconductor light-emitting device according to claim 25, wherein the active layer comprises a nitride semiconductor capable of emitting light with a peak wavelength of 400 nm or less.

27. The semiconductor light-emitting device according to claim 19, further comprising an adhesion promoter layer formed at an interface between the first electrode and the protective layer and comprising a material including Ti.

28. The semiconductor light-emitting device according to claim 19, wherein the protective layer comprises a material transparent to light emitted from the active layer.

29. The semiconductor light-emitting device according to claim 28, wherein the protective layer comprises SiO₂.

30. A method for manufacturing the semiconductor light-emitting device according to claim 19, the method comprising the steps of:
(h) preparing a growth substrate;
(i) forming semiconductor layers on the growth substrate, the semiconductor layers including an n-type or p-type first semiconductor layer, an active layer, and a second semiconductor layer of a conductivity type different from that of the first semiconductor layer;
(j) forming a second electrode on an upper surface of the second semiconductor layer;
(k) bonding a support substrate to an upper part of the second electrode with a bonding layer interposed between the support substrate and the second electrode, wherein the support substrate is independent of the growth substrate;
(l) separating the growth substrate to expose the first semiconductor layer;
(m) forming a first electrode on a predetermined region of a surface of the first semiconductor layer; and
(n) forming a protective layer on an outside surface of the first electrode, wherein the outside surface includes an end in contact with the first semiconductor layer, and the protective layer comprises a material with a thermal expansion coefficient lower than that of the first electrode.

31. The method according to claim 30, wherein
in the step (m), the first electrode is formed to extend in a predetermined direction on the surface of the first semiconductor layer,
in the step (n), the protective layer is formed to reach a part of an upper surface of the first electrode through the outside surface of the first electrode, and
after the step (n), the first electrode has an exposed surface in a slit shape extending in the predetermined direction.
